(19) United States
(12) Patent Application Publication
(10) Pub. No.: US 2006/0072367 A1
(43) Pub. Date: Apr. 6, 2006

(54) Information management device

(76) Inventor: Akiko Asami, Shizuoka (JP)

Correspondence Address: BELL, BOYD & LLOYD, LLC, P. O. BOX 1135, CHICAGO, IL, 60690-1135, US

(21) Appl. No.: 10/517,400

(22) PCT Filed: May 29, 2003
(86) PCT No.: PCT/JP03/06727

§ 371 Date: Jun. 10, 2005

(30) Foreign Application Priority Data
May 30, 2002 (JP) 2002-157930

(51) Int. Cl. G11C 8/02

(52) U.S. Cl. 365/232

(57) ABSTRACT

An information management device and method, an information processing device and method, a recording medium, and a program that allow the provision of optimum content to each individual user are provided. In a Pochara service server 9, a matching is executed between the feature information of music selection Pochara and the feature information of the user of a personal computer 22 updated in response to the replies to questions asked by a music selection Pochara, thereby selecting a music selection Pochara which is optimum to the feelings of the user of the personal computer 22 at that time. On the personal computer 22, the image of the selected music selection Pochara is displayed and music content is selected by this music selection Pochara. The present invention is applicable to various kinds of devices such as personal computers that have a communication capability and a display capability.

### CROSS REFERENCES TO RELATED APPLICATIONS

The present application claims priority to Japanese Patent Document No. P2002-157930 filed on May 30, 2002, the disclosure of which is herein incorporated by reference.

### BACKGROUND OF THE INVENTION

The present invention relates generally to an information management device and method, an information processing device and method, a recording medium, and a program and, more particularly, to an information management device and method, an information processing device and method, a recording medium, and a program that allow the provision of optimum content to each individual user.

Recently, various broadband communication environments have been coming into being, starting, in full scale, the provision of service content such as English language schools and banking businesses and the distribution of content such as video data and music data for example.

For example, in the use of music content distribution services, each user can access a service providing server by operating a device such as a personal computer and only selecting desired music content from a menu, thereby using the content via the Internet without going to record stores and the like.

However, as the amount of music content delivered by servers increases, the above-mentioned manner in which each user selects desired music content from menus presents a problem that the job of selection becomes increasingly complicated. This problem would become more and more serious as the music distribution via the Internet and the like becomes more widespread, thereby pushing up the amount of content to be handled.

The related-art technologies of music content distribution involves another problem that the job itself of accessing service servers by operating a device such as a personal computer to select desired music content is cumbersome. If it is supposed that desired content can be automatically delivered via a network by executing simple operations without user's executing such a cumbersome operation, the number of users who will use content distribution services via networks would significantly increase, thereby further activating the industry.

### SUMMARY OF THE INVENTION

The present invention relates generally to an information management device and method, an information processing device and method, a recording medium, and a program and, more particularly, to an information management device and method, an information processing device and method, a recording medium, and a program that allow the provision of optimum content to each individual user.

The present invention provides in an embodiment optimum content to each individual user with merely simple operations.

In carrying out the invention and according to one embodiment thereof, there is provided an information management device including storage means for storing image data for displaying an image of a character and character feature information indicative of the character; character selection means for selecting the character from among characters of which image data is stored in the storage means on the basis of user feature information indicative of a user of the information processing device and the character feature information; image data transmission means for transmitting, to the information processing device, the image data of the character selected by the character selection means; and content transmission means for transmitting content associated with the character selected by the character selection means to the information processing device.

The above-mentioned information management device further includes content selection means for selecting the content associated with the character selected by the character selection means on the basis of the user feature information.

The above-mentioned information management device still further includes evaluation information acquisition means for acquiring evaluation information indicative of an evaluation of the content used on the information processing device. In the above-mentioned information management device, the character selection means updates the user feature information in accordance with the evaluation information acquired by the evaluation information acquisition means, thereby selecting the character on the basis of the updated user feature information and the character feature information.

The above-mentioned information management device yet further includes charging means for charging, to the information processing device, a fee of the content transmitted by the content transmission means.

The above-mentioned information management device further includes identification information reception means for receiving, from the information processing device, identification information held in an object read by the information processing device. In the above-mentioned information management device, the character selection means selects a character which is represented by an image in accordance with an external shape of the object on the basis of the identification information received by the identification information reception means.

The above-mentioned information management device still further includes transmission management means for managing the transmission of the content to the information processing device by transmitting information about access to another information processing device to which the content is provided and identification information of the content to the information processing device.

The above-mentioned information management device yet further includes user feature information extraction means for extracting the user feature information on the basis of an input by the user of the information processing device, the input being transmitted from the information processing device.

The above-mentioned information management device further includes input information acquisition means for acquiring input information of the user including the user feature information indicative of a feature of a user for selecting the character or the content.

In carrying out the invention and according to another embodiment thereof, there is provided an information managing method including the steps of: storing image data for displaying an image of a character and character feature information indicative of the character; selecting the character from among characters of which image data is stored in the storage step on the basis of user feature information indicative of a user of the information processing device and the character feature information; transmitting, to the information processing device, the image data of the character selected by the character selection step; and transmitting content associated with the character selected by the character selection step to the information processing device.

In carrying out the invention and according to still another embodiment thereof, there are provided a program recorded in a first recording medium and a first program each including the steps of controlling storage of image data for displaying an image of a character and character feature information indicative of the character; selecting the character from among characters of which image data is stored in the storage control step on the basis of user feature information indicative of a user of the information processing device and the character feature information; controlling transmission of, to the information processing device, the image data of the character selected by the character selection step; and controlling transmission of content associated with the character selected by the character selection step to the information processing device.

In carrying out the invention and according to yet another embodiment thereof, there is provided an information processing device including: image data reception means for receiving image data of a predetermined character transmitted from the information management device; display means for displaying the predetermined character on the basis of the image data received by the image data reception means; content acquisition means for acquiring content associated with the predetermined character displayed by the display means; and output means for outputting the content acquired by the content acquisition means.

The above-mentioned information processing device further includes evaluation information transmission means for accepting input of an evaluation associated with the content outputted by the output means and transmitting evaluation information indicative of the evaluation to the information management device.

The above-mentioned information processing device still further includes read means for reading identification information from an object in which the identification information is held and identification information transmission means for transmitting the identification information read by the read means to the information management device. In the above-mentioned information processing device, the image data reception means receives image data for displaying an image corresponding to an external shape of the object selected by the information management device on the basis of the identification information.

In the above-mentioned information processing device, on the basis of information about access to another information processing device to which the content is provided and identification information of the content, the information being transmitted from the information management device, the content acquisition means acquires the content from that another information processing device.

In carrying out the invention and according to a different aspect thereof, there is provided an information processing method including the steps of receiving image data of a predetermined character transmitted from the information management device; displaying the predetermined character on the basis of the image data received by the image data reception step; acquiring content associated with the predetermined character displayed by the display step; and outputting the content acquired by the content acquisition step.

In carrying out the invention and according to a still different aspect thereof, there are provided a program recorded in a second recording medium and a second program each including the steps of controlling reception of image data of a predetermined character transmitted from the information management device; controlling display of the predetermined character on the basis of the image data received by the image data reception control step; controlling acquisition of content associated with the predetermined character displayed by the display control step; and controlling output of the content acquired by the content acquisition control step.

In the information management device and method and program according to the invention, image data for displaying images of characters and character feature information indicative of the features of the characters are stored and a character is selected from among the characters of which image data are stored, on the basis of user feature information indicative of the feature of the user of the information processing device and the character feature information. The image data of the selected character is transmitted to the information processing device and the content associated with the selected character is transmitted to the information processing device.

In the information processing device and method and program according to the invention, image data of a predetermined character transmitted from the information management device is received and a predetermined character is displayed on the basis of the received image data. In addition, when content associated with the predetermined character is acquired, the acquired content is outputted.

The above-mentioned network denotes a system to which at least two devices are connected to transmit information from one device to another. This network may be configured based on not only wireless or wired communication, but also the coexistence of wireless and wired communications.

Additional features and advantages of the present invention are described in, and will be apparent from, the following Detailed Description of the Invention and the figures.

### BRIEF DESCRIPTION OF THE FIGURES

FIG. 1 is a block diagram illustrating an exemplary configuration of an information processing system to which the present invention is applied according to an embodiment.

FIG. 2 is a block diagram illustrating an exemplary configuration of a Pochara service server shown in FIG. 1.

FIG. 3 is a block diagram illustrating an exemplary configuration of a personal computer shown in FIG. 1.

FIG. 4 shows an exemplary friend Pochara figure.

FIG. 5 is a block diagram illustrating an internal configuration of the friend Pochara figure.

FIG. 6 shows the information stored in an IC chip shown in FIG. 5.

FIG. 7 is a flowchart indicative of the processing by the user for getting a friend Pochara figure.

FIGS. 8A-8F show exemplary friend Pochara figures.

FIG. 9 is a flowchart indicative of the friend Pochara sale processing by the Pochara service server shown in FIG. 1.

FIG. 10 shows an exemplary sale Pochara figure.

FIG. 11 shows exemplary information stored in the IC chip of each sale Pochara figure.

FIG. 12 is a flowchart indicative of the Pochara processing by the personal computer shown in FIG. 1.

FIG. 13 is another flowchart indicative of the Pochara processing by the personal computer shown in FIG. 1.

FIG. 14 is still another flowchart indicative of the Pochara processing by the personal computer shown in FIG. 1.

FIG. 15 is yet another flowchart indicative of the Pochara processing by the personal computer shown in FIG. 1.

FIG. 16 is a different flowchart indicative of the Pochara processing by the personal computer shown in FIG. 1.

FIG. 17 shows the bag information of a friend Pochara.

FIG. 18 shows the bag information of a sale Pochara.

FIG. 19 shows an exemplary display of Pochara.

FIG. 20 shows an exemplary display of Pochara.

FIG. 21 shows an exemplary display of Pochara which is displayed when a mail function is selected.

FIG. 22 shows another exemplary display of Pochara which is displayed when the mail function is selected.

FIG. 23 shows an exemplary display of Pochara which is displayed when a schedule function is selected.

FIG. 24 shows another exemplary display of Pochara which is displayed when the schedule function is selected.

FIG. 25 shows an exemplary display of Pochara which is displayed when a change cloths function is selected.

FIG. 26 shows another exemplary display of Pochara.

FIG. 27 shows still another exemplary display of Pochara.

FIG. 28 is a flowchart indicative of the processing by the Pochara service server shown in FIG. 1.

FIG. 29 is another flowchart indicative of the processing by the Pochara service server shown in FIG. 1.

FIG. 30 shows exemplary user information registered with a Pochara database shown in FIG. 1.

FIG. 31 shows exemplary Pochara information of friend Pochara registered with the Pochara database shown in FIG. 1.

FIG. 32 shows exemplary Pochara information of sale Pochara registered with the Pochara database shown in FIG. 1.

FIG. 33 is a flowchart indicative of the processing by a content server shown in FIG. 1.

FIG. 34 is a flowchart indicative of the content reception processing by the personal computer shown in FIG. 1.

FIG. 35 is a flowchart indicative of the content provision processing by the content server shown in FIG. 1.

FIG. 36 is a flowchart indicative of the processing by the Pochara service server shown in FIG. 1.

FIG. 37 is a flowchart indicative of the license acquisition processing by the personal computer shown in FIG. 1.

FIG. 38 is a flowchart indicative of the processing by the Pochara service server shown in FIG. 1.

FIG. 39 is a flowchart indicative of the processing by a license server shown in FIG. 1.

FIG. 40 is a flowchart indicative of the content reproduction processing by the personal computer shown in FIG. 1.

FIG. 41 is a flowchart indicative of the content reproduction processing by the Pochara service server shown in FIG. 1.

FIG. 42 is a flowchart indicative of the prepaid amount update processing by the personal computer shown in FIG. 1.

FIG. 43 is a flowchart indicative of the prepaid amount update processing by the Pochara service server shown in FIG. 1.

FIG. 44 is a flowchart indicative of the processing of reproducing the content stored in a terminal.

FIG. 45 is a flowchart indicative of the processing by the Pochara service server when reproducing the content stored in a terminal.

FIG. 46 is a flowchart indicative of the reproduction processing by a terminal to which content is provided from another terminal.

FIG. 47 is a flowchart indicative of the content provision processing by a terminal.

FIG. 48 is a flowchart indicative of the processing by the Pochara service server when reproducing the content stored in a terminal.

FIG. 49 is a flowchart indicative of the processing of copying encrypted content.

FIG. 50 is a flowchart indicative of the processing by the copy source.

FIG. 51 is a flowchart indicative of the processing by the copy destination.

FIG. 52 is a flowchart indicative of music selection Pochara provision processing by the music selection Pochara provider device.

FIG. 53 is a flowchart indicative of music selection Pochara registration processing by the Pochara service server.

FIG. 54 shows an exemplary feature of music selection Pochara.

FIG. 55 is a flowchart indicative of music selection Pochara call processing by the personal computer show in FIG. 1.

FIG. 56 shows an exemplary display of on the personal computer.

FIG. 57 shows another exemplary display on the personal computer.

FIG. 58 shows still another exemplary display on the personal computer.

FIG. 59 is a flowchart indicative of music selection Pochara select processing by the Pochara service server shown in FIG. 1.

FIG. 60 shows an exemplary matching.

FIG. 61 is a flowchart indicative of music reproduction processing by the personal computer shown in FIG. 1.

FIG. 62 is a flowchart continued from the flowchart shown in FIG. 61 which indicates music reproduction processing by the personal computer shown in FIG. 1.

FIG. 63 shows an exemplary display on the personal computer.

FIG. 64 shows another exemplary display on the personal computer.

FIG. 65 shows still another exemplary display on the personal computer.

FIG. 66 is a flowchart indicative of music selection processing by the Pochara service server shown in FIG. 1.

FIG. 67 shows an exemplary feature update processing.

### DETAILED DESCRIPTION OF THE INVENTION

The present invention relates generally to an information management device and method, an information processing device and method, a recording medium, and a program and, more particularly, to an information management device and method, an information processing device and method, a recording medium, and a program that allow the provision of optimum content to each individual user.

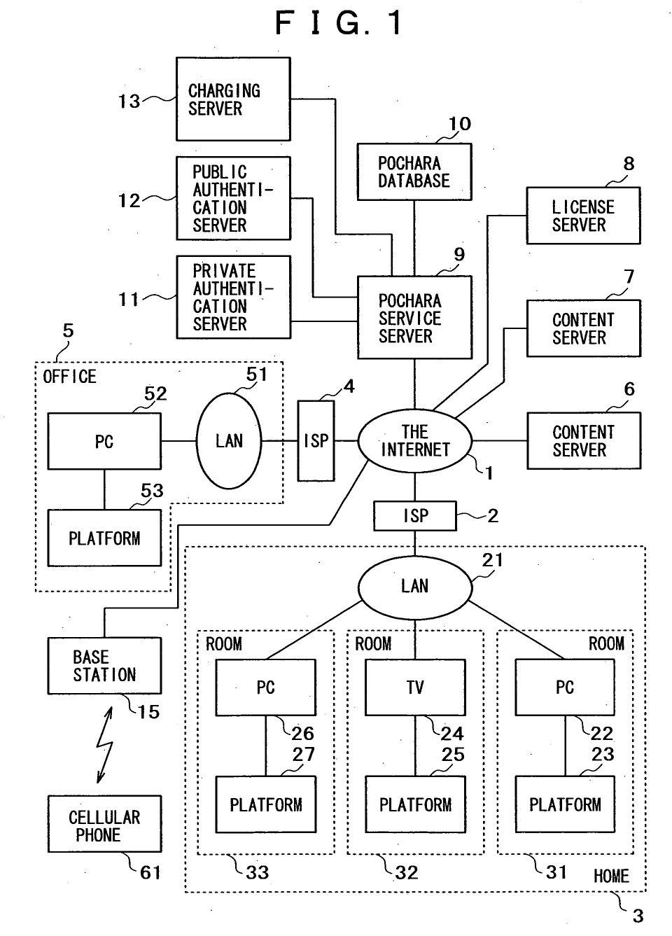

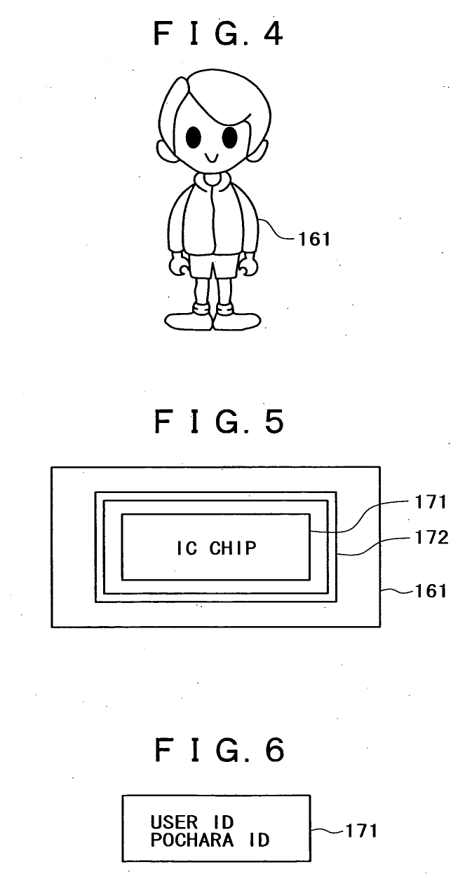

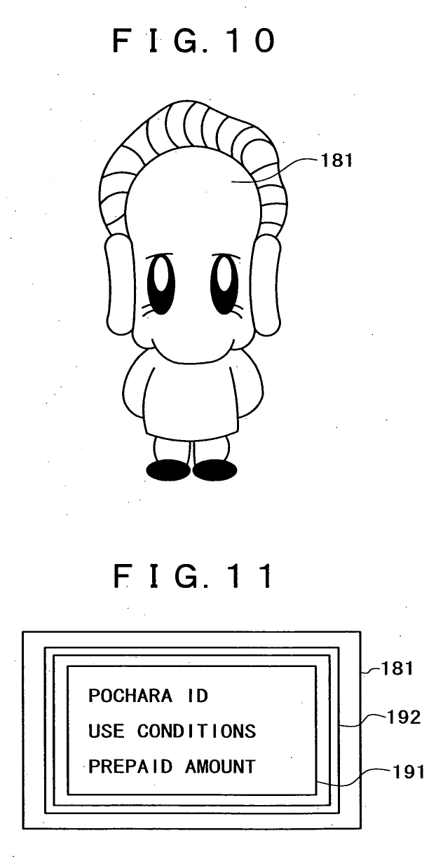

Now, referring to FIG. 1, there is shown an exemplary configuration of an information processing system practiced to which the present invention is applied. In this exemplary configuration, a LAN (Local Area Network) 21 of a home 3 is connected to the Internet 1 via an Internet service provider (ISP) 2. Devices in a room 31 through a room 33 are connected to the LAN 21. In this example, a personal computer (PC) 22 is connected to the LAN 21 in the room 31 and platform 23 on which a friend Pochara (trademark) figure 161 (FIG. 4) or a sale Pochara (trademark) figure 181 (FIG. 10) is mounted is connected to the personal computer 22.

It should be noted that the LAN 21 is configured by the user or the wireless communication. In the wireless configuration, a scheme specified by IEEE (Institute of Electrical and Electronic Engineers) 802.11a, b, or g, UWB (Ultra Wide Band), or Bluetooth, for example may be used. In the wired configuration, a scheme specified by USB (Universal Serial Bus) or other standards may be used.

In the room 32, a television receiver (TV) 24 is connected to the LAN 21 and a platform 25 is connected to the television receiver 24. In the room 33, a personal computer 26 is connected to the LAN 21 and a platform 27 is connected to the personal computer 26.

A LAN 51 of an office 5 is also connected to the Internet 1. A personal computer 52 is connected to the LAN 51 and a platform 53 is connected to the personal computer 52.

A content server 6 for providing the content data corresponding to a sale Pochara figure 181 (FIG. 10) is also connected to the Internet 1. A content server 7 connected to the Internet 1 provides the content data corresponding to a friend Pochara figure 161 (FIG. 4). A license server 8 connected to the Internet 1 provides the license corresponding to the content supplied from the content server 7.

Further, a Pochara (trademark) service server 9 is connected to the Internet 1. The Pochara service server 9 provides various services corresponding to the friend Pochara figure 161 or the sale Pochara figure 181.

A Pochara database 10 storing various kinds of information associated with Pochara is connected to the Pochara service server 9. The Pochara service server 9 is also connected with a private authentication server 11 for authenticating the friend Pochara figure 161 and a public authentication server 12 for authenticating the sale Pochara figure 181 as well as an charging server 13 for executing various kinds of charging processing. One or more of the Pochara database 10, the private authentication server 11, the public authentication server 12, and the charging server 13 may be integrated with the Pochara service server 9 on an as required basis.

Moreover, in the system shown in FIG. 1, a cellular phone 61 is connected to the Internet 1 via a nearby base station 15.

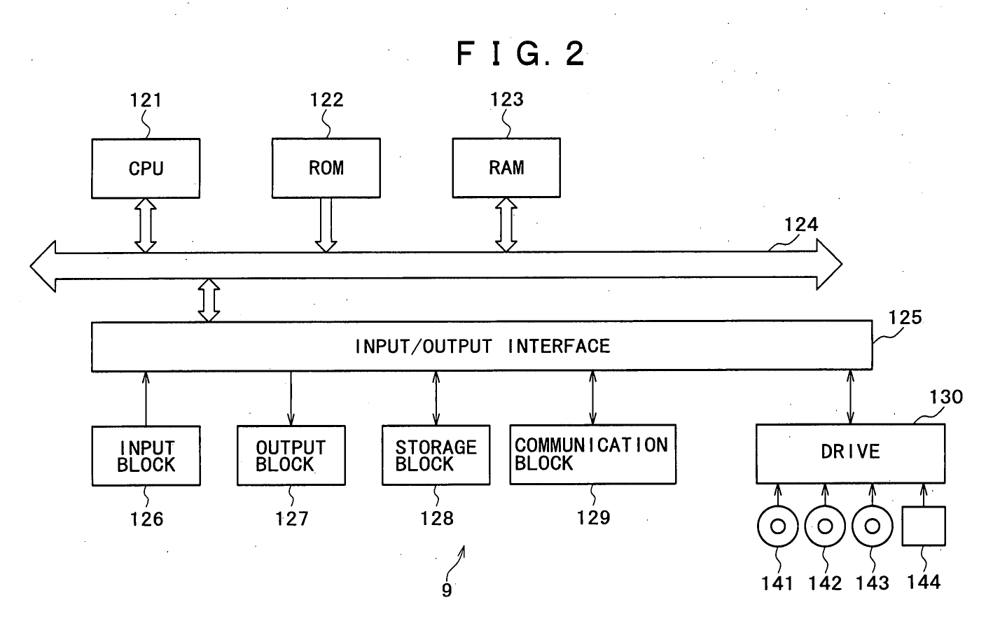

The Pochara service server 9 is configured as shown in FIG. 2, for example.

Referring to FIG. 2, a CPU (Central Processing Unit) 121 executes various kinds of processing as instructed by programs stored in a ROM (Read Only Memory) 122 or programs loaded from a storage block 128 into a RAM (Random Access Memory) 123. The RAM 123 also stores, from time to time, data which is necessary for the CPU 121 to execute various kinds of processing.

The CPU 121, the ROM 122, and the RAM 123 are interconnected via a bus 124. The bus 124 is also connected with an input/output interface 125.

The input/output interface 125 is connected with an input block 126 based on a keyboard and a mouse for example, a display (display block) based on a CRT (Cathode Ray Tube) or LCD (Liquid Crystal Display) for example, and an output block 127 based on a speaker for example, the storage block 128 based on a hard disk drive, and a communication block 129 based on a modem or a terminal adapter for example. The communication block 129 executes communication processing via networks including the Internet 1.

The input/output interface 125 is also connected with a drive 130 on which a magnetic disk 141, an optical disk 142, a magneto-optical disk 143, or a semiconductor memory 144 is loaded as required. Further computer programs read from these recording media are installed in the storage block 128 as required.

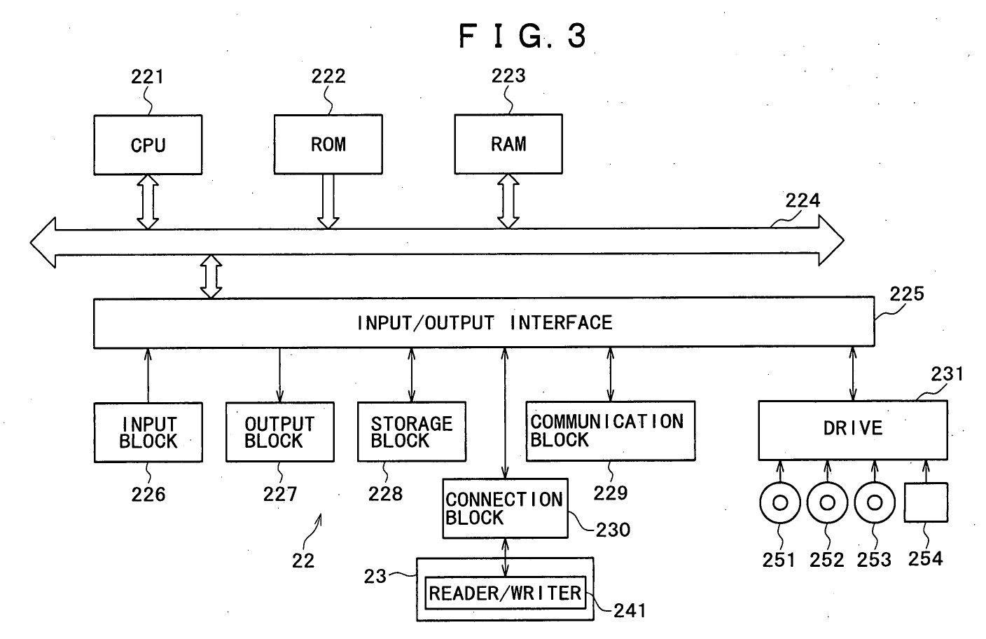

The personal computer 22 is configured as shown in FIG. 3 for example. The basic configuration is the same as that of the Pochara service server 9 shown in FIG. 2. Namely, components CPU 221 through communication block 229 of the personal computer 22 have basically the same functions as those of the components CPU 121 through communication block 129 of the Pochara service server 9 respectively.

An input/output interface 225 of the personal computer 22 shown in FIG. 3 is connected with a connection block 230 to which the platform 23 is connected. As shown in FIG. 3, the a reader/writer 241 is incorporated in the platform 23 to read information from a Pochara figure mounted on the platform 23, in an electromagnetic induction, non-contact manner.

The input/output interface 225 is connected with a drive 231 as required, on which a magnetic disk 251, an optical disk 252, a magneto-optical disk 253, or a semiconductor memory 254 is loaded as required. Computer programs read from these recording media are installed in a storage block 228 as required.

In this information processing system (the information providing system), each user purchases the friend Pochara figure 161 as shown in FIG. 4 in advance in order to authenticate himself/herself. The friend Pochara figure 161 incorporates an IC chip 171 having an antenna 172. The IC chip 171 stores a user ID which is user identification information for identifying the user owning the friend Pochara figure 161 and a Pochara ID which is Pochara figure identification information for identifying the friend Pochara figure 161.

It should be noted that the user ID may integrate the Pochara ID.

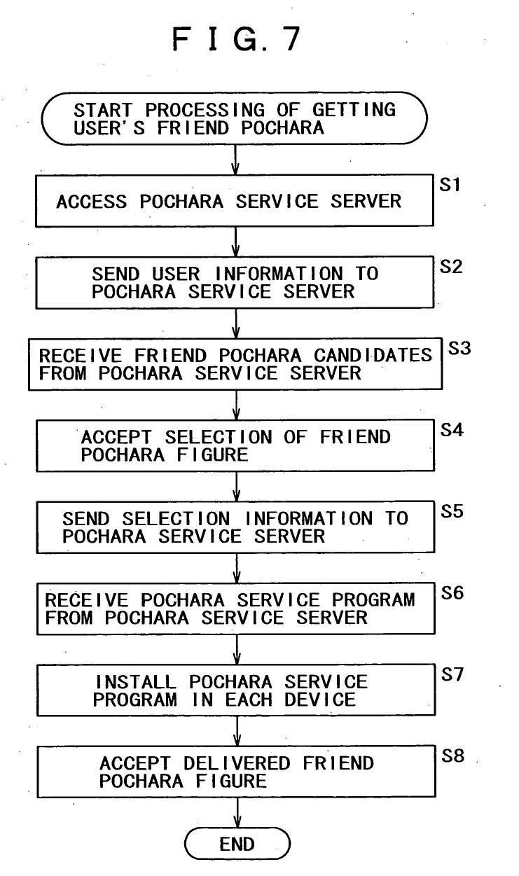

The following describes the processing by the user for getting the friend Pochara figure 161 with reference to the flowchart shown in FIG. 7.

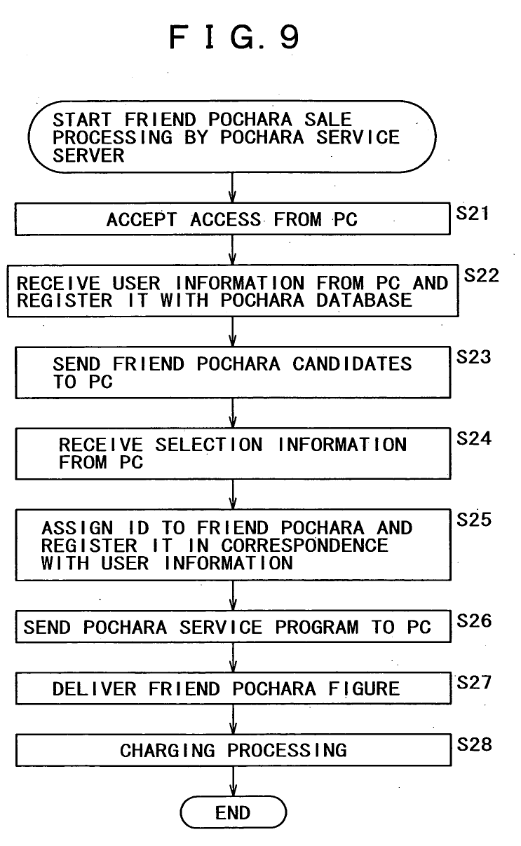

The user of the personal computer 22 operates the input block 226 to instruct the CPU 221 to access the Pochara service server 9. Upon receiving the access instruction, the CPU 221 controls the communication block 229 to access the Pochara service server 9 via the LAN 21, the ISP 2, and the Internet 1 in step S1. The Pochara service server 9 provides a GUI (Graphical User Interface) which is used to enter user information to the accessing personal computer 22 via the Internet 1 (step S21 shown in FIG. 9 to be described later). In response, the user enters user's name, address, birthday, gender, telephone number, facsimile number, mail address, credit card number, bank account number, and other personal information through the input block 226. In step S2, the CPU 221 sends the entered user information to the Pochara service server 9 from the communication block 229 via the Internet 1. It should be noted that the communication between the personal computer 22 (and other terminals) and the Pochara service server 9 is encrypted as required.

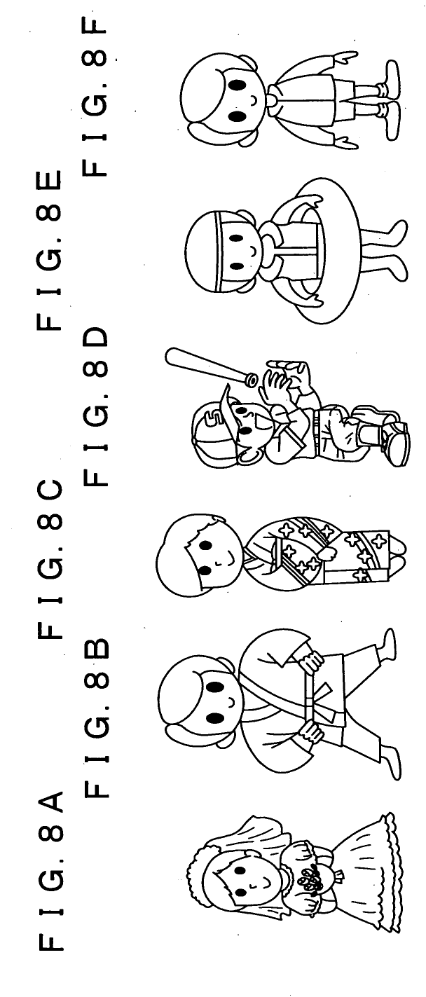

At this moment, the Pochara service server 9 sends candidates (a list) of friend Pochara figures to the personal computer 22 (step S23 shown in FIG. 9). In response, receiving the candidates of friend Pochara figures from the Pochara service server 9 via the communication block 229, the CPU 221 outputs the candidates to the display block of an output block 227 in step S3. Consequently, the candidates of friend Pochara figures as shown in FIG. 8 for example are displayed. FIG. 8 shows six kinds of friend Pochara figures A through F. The friend Pochara figure 161 shown in FIG. 4 corresponds to FIG. 8F.

The user selects through the input block 226 a desired friend Pochara figure from among those displayed. In step S4, the CPU 221 accepts the selection of the specified friend Pochara figure.

In step S5, the CPU 221 sends the selection information of the friend Pochara figure accepted in step S4 to the Pochara service server 9.

Receiving the selection information from the personal computer 22, the Pochara service server 9 a computer program for executing Pochara services including the data of the friend Pochara corresponding to the selected friend Pochara figure (step S26 shown in FIG. 9).

In step S6, the CPU 221 of the personal computer 22 receives the computer program from the Pochara service server 9 and stores the received computer program into the storage block 228. This program includes the data (the data about the friend Pochara) necessary for displaying the friend Pochara (a virtual figure displayed in animation corresponding to the real friend Pochara figure, hereafter also referred to as a character) corresponding to the selected friend Pochara figure onto the display block of the output block 227.

This friend Pochara character is represented in the same image as the corresponding friend Pochara figure. In other words, the friend Pochara figure has the same shape (including colors and other attributes) as the friend Pochara which is a virtual figure displayed on the display block of the output block 227.

For example, the friend Pochara figure 161 shown in FIG. 4 corresponds to the friend Pochara character shown in FIG. 8F.

The user installs the program received in the process of step S6 into other devices which use the services provided by the Pochara service server 9. In the example shown in FIG. 1, this program is installed in the television receiver 24 and the personal computer 26. This program is also installed in the personal computer 52 of the office 5.

The television receiver 24 has a loading block on which a semiconductor memory typified by the Memory Stick (trademark) for example is loaded. By storing the program in a Memory Stick through the personal computer 22 for example and loading this Memory Stick on the television receiver 24, the user can install the program in the television receiver 24.

Then, the Pochara service server 9 delivers the friend Pochara figure selected by the user in step S4 (step S27 shown in FIG. 9), so that the user receives the figure from the Pochara service server 9 in step S8.

In response to the above-mentioned processing by the personal computer 22 shown in FIG. 7, the Pochara service server 9 executes the processing indicated by the flowchart shown in FIG. 9.

To be more specific, in step S21, the CPU 121 of the Pochara service server 9 accepts, through the communication block 129, the access by the user of the personal computer 22 via the Internet 1 and then provides a GUI for user information entry to the accessing personal computer 22 via the Internet 1.

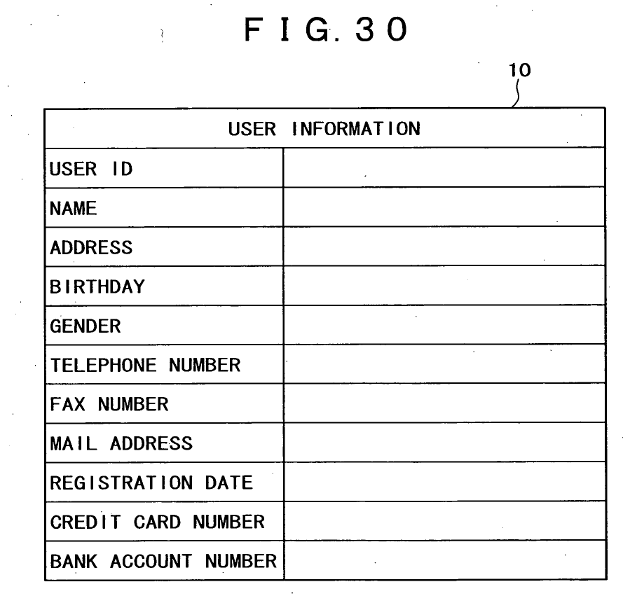

As described above, the user sends the user information on the basis of this GUI (step S2 shown in FIG. 7). In step S22, the CPU 121 of the Pochara service server 9 receives the user information from the personal computer 22 and supplies the received user information to the Pochara database 10 via the communication block 129, registering the user information thereon. Consequently, the user information is registered on the Pochara database 10 (details thereof will be described later with reference to FIG. 30).

Next, in step S23, the CPU 121 reads the candidates of the friend Pochara figure from the storage block 128 and sends them to the personal computer 22. Consequently, the friend Pochara figure candidates as shown in FIG. 8 are sent to the personal computer 22.

As described above, the user selects one of the received friend Pochara figure candidates and sends the selection information thereof (step S5 shown in FIG. 7).

In step S25, the CPU 121 allocates, to the user, a user ID which is the identification information for identifying the user. Also, the CPU 121 allocates a Pochara ID to the friend Pochara figure selected by the user and registers the allocated Pochara ID on the Pochara database 10 as the Pochara information in correspondence with the user information. In addition to the Pochara ID, this Pochara information includes a flag indicative whether this Pochara is a friend Pochara (a friend Pochara flag) or a parameter of this Pochara. This parameter represents a cloth of this Pochara or a function of this Pochara. It should be noted that the friend Pochara flag may be included in the Pochara ID to be allocated to the friend Pochara figure 161.

Next, in step S26, the CPU 121 reads the program from the storage block 128 for the user to accept the Pochara service and sends the program to the personal computer 22 via the Internet 1. At this moment, the CPU 121 sends the user ID and the Pochara information necessary for displaying the character of this friend Pochara as included in the program. In addition to the Pochara ID, this Pochara information includes the Pochara data including various parameters on which Pochara images are based. This program is received by the personal computer 22 (step S6 shown in FIG. 7).

In step S27, the CPU 121 executes the processing for delivering the friend Pochara figure corresponding to the selection information received in step S24. To be more specific, the CPU 121 outputs the information (the Pochara ID) for identifying the friend Pochara figure selected by the user and the address and name for example of that user from a printer which is a component of the output block 127. On the basis of the output of the printer, the manager of the Pochara service server 9 executes procedures for delivering a predetermined friend Pochara image to the user.

In step S28, the CPU 121 executes the charging processing for the value of the friend Pochara figure delivered to the user.

To be more specific, the CPU 121 requests the charging server 13 for the settlement of the price corresponding to the value of the friend Pochara figure on the basis of the credit card number included in the user information. Alternatively, the CPU 121 requests the charging server 13 to charge the price to the bank account, the account number included in the user information. In response to this request, the charging server 13 requests the credit card company or the bank of the user to execute the processing of charging the price of the friend Pochara figure.

The user gets the friend Pochara figure 161 as described above. It is also practicable for the user to get the friend Pochara figure 161 at a store managed by the manager of the Pochara service server 9. In this case, the user information is directly entered by the user at the store.

In the above-mentioned configuration, the user first accesses the Pochara service server 9 from the personal computer 22, sends the necessary user information, and then receives a desired friend Pochara figure; in other words, the user gets a desired friend Pochara figure after making user registration. It is also practicable for the user to make user registration via a network after purchasing a desired friend Pochara figure which stores on the Pochara ID. The friend Pochara figure thus purchased will then function as an agent for the user.

In addition to the friend Pochara figure 161, the above-mentioned store sells a sale Pochara figure 181 as shown in FIG. 10. The user can purchase the sale Pochara figure 181 at various stores as required. The sale Pochara figure 181 also incorporates an IC chip 191. The IC chip 191 stores the information about the functions of the sale Pochara figure 181.

FIG. 11 shows an example of the information stored in the IC chip 191 when the sale Pochara figure 181 has the function of providing content data. In this example, the Pochara ID and the use condition specifying the use of content are stored in the IC chip 191 having an antenna 192. This use condition includes the number of times content can be reproduced and the period in which content can be reproduced.

In addition, the IC chip 191 stores, as required, a prepaid amount corresponding to the amount (the purchase amount) paid by the user for the use of content.

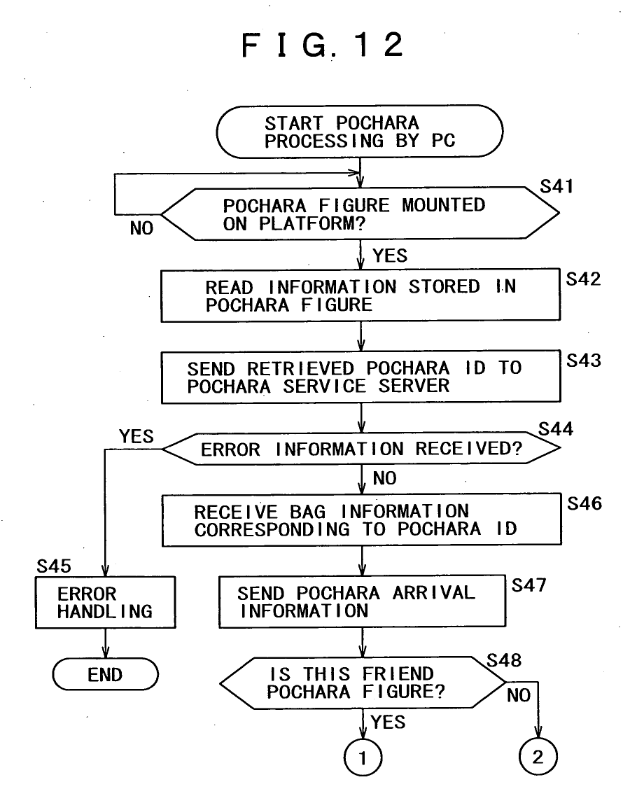

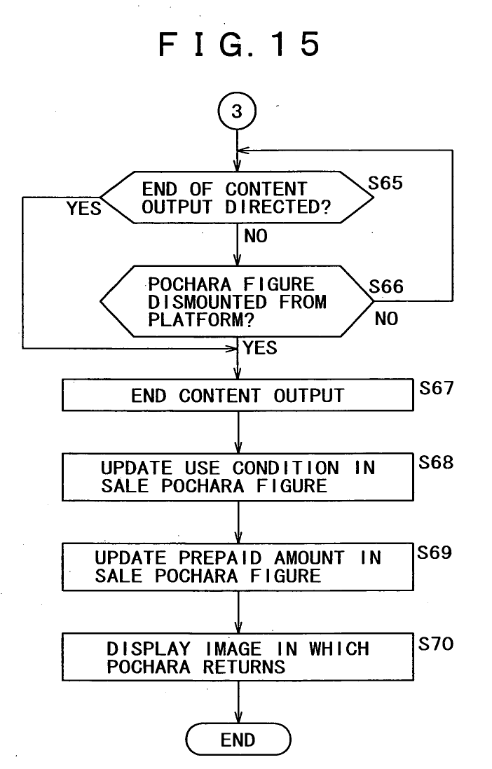

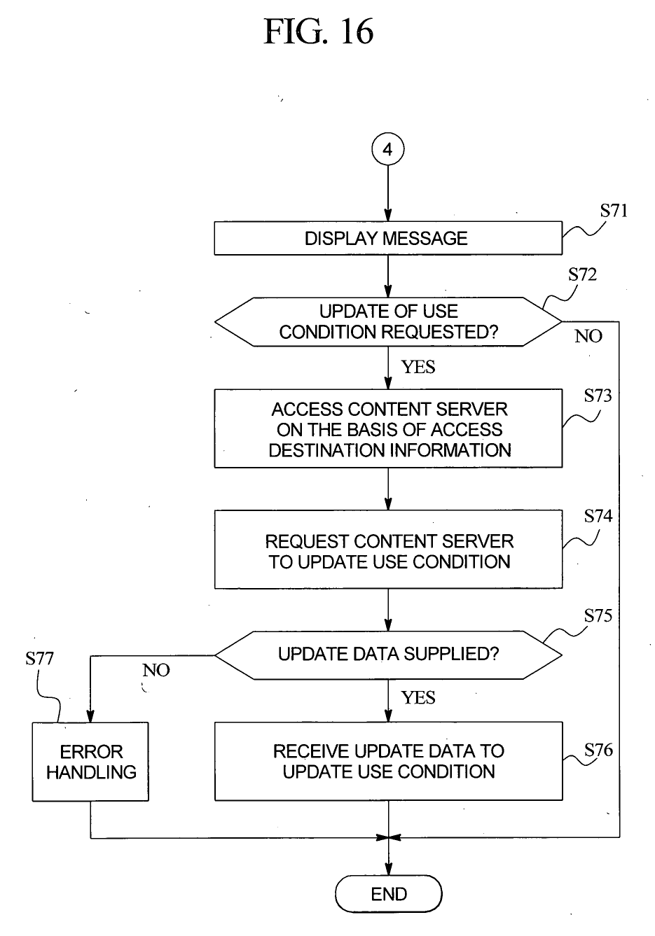

The user gets the friend Pochara figure 161 or the sale Pochara figure 181 as described above and, if user wants to get the provision of content, mounts the friend Pochara figure 161 or the sale Pochara figure 181 on the platform corresponding to a device to be used. For example, if the personal computer 22 is used, the user mounts the friend Pochara figure 161 or the sale Pochara figure 181 on the platform 23 connected to the personal computer 22. In this case, the personal computer 22 executes the processing indicated by the flowcharts shown in FIGS. 12 through 16.

In step S41, the CPU 221 of the personal computer 22 determines whether the Pochara figure has been mounted on the platform 23. If the Pochara figure is found not mounted, the CPU 221 waits until the Pochara figure is mounted.

When the Pochara figure is mounted, the information stored in the IC chip 171 (or 191) is read by a reader/writer 241 to be sent to the CPU 221 via the connection block 230. At this moment, the CPU 221 repeats the process of step s41 until this information arrives.

If the Pochara figure is found mounted on the platform 23, then the procedure goes to step S42, in which the CPU 221 reads the information from the IC chip 171 (or 191) of the mounted Pochara figure. No matter which of the friend Pochara figure 161 or the sale Pochara figure 181 has been mounted, the Pochara ID is stored in the IC chip 171 or 191 (FIG. 6 and FIG. 11). In step S43, the CPU 221 controls the communication block 229 to send the Pochara ID to the Pochara service server 9. The Pochara ID sent at this time is used for identifying the user (or the Pochara figure) in the Pochara service server 9. Namely, the Pochara ID at this moment is used for user identification, so that, if the user ID is stored, the user ID may be sent. Alternatively, both the Pochara ID and the user ID may be sent.

Namely, the read Pochara ID is sent to the Pochara service server 9 via the LAN 21, the ISP 2, and the Internet 1. In other words, if the friend Pochara figure 161 is mounted on the platform 23, the CPU 221 executes the login processing (the connection processing) on the Pochara service server 9 in step S43.

Thus, the user need not enter his ID through a keyboard for example, so that it is easy for the user to access the Pochara service server 9 and entry errors are prevented. Consequently, this novel configuration allows children, females, and elderly people who are not familiar with keyboard operation to easily access the Pochara service server 9.

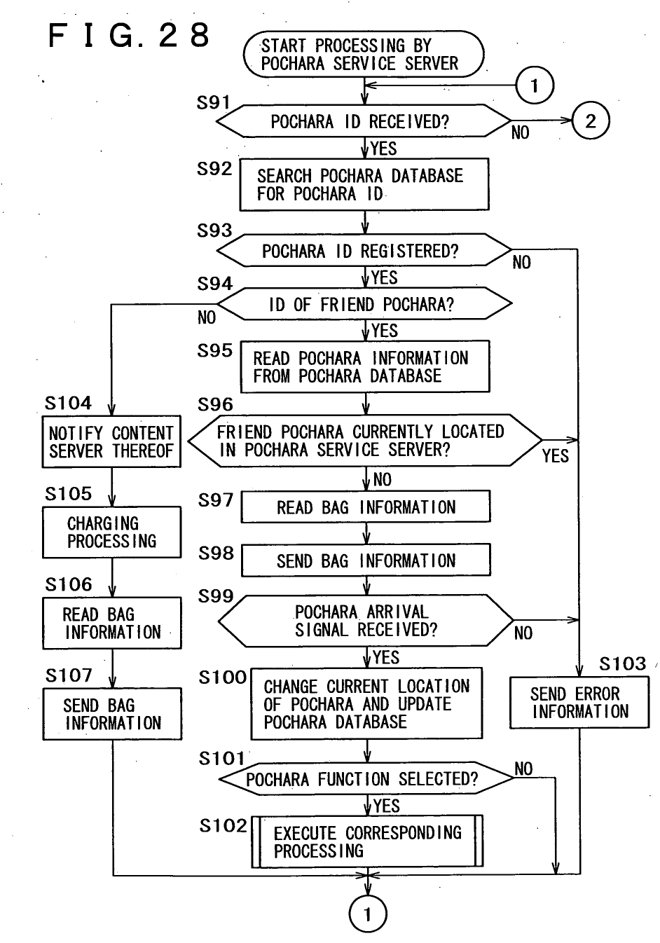

Receiving the Pochara ID, the Pochara service server 9 determines whether the received Pochara ID is registered on the Pochara database 10 (step S93 shown in FIG. 28 to be described later). It should be noted that the Pochara database 10 also registers the sale Pochara ID, in addition to the friend Pochara ID. If the Pochara ID that has been read is found registered, the Pochara service server 9 reads bag information from the Pochara database 10 and sends it (steps S98 and S107 shown in FIG. 28).

If the Pochara ID is found not registered on the Pochara database 10, then the Pochara service server 9 sends error information (step S103 shown in FIG. 28).

In step S44, the CPU 221 of the personal computer 22 determines whether the error information has been received from the Pochara service server 9. If the error information (the information sent in the process of step S103 shown in FIG. 28) is found received in step S44, then the procedure goes to step S45, in which the CPU 221 executes error handling. Namely, in this case, because the Pochara ID is not registered on the Pochara database 10, the user cannot use the services based on Pochara.

On the other hand, if the error information is found not received in step S44 (if the received information is found to be the bag information send in the processes of steps S98 and S107 shown in FIG. 28), then the procedure goes to step S46, in which the CPU 221 receives the bag information supplied from the Pochara service server 9. In step S47, the CPU 221 sends Pochara arrival information to the Pochara service server 9. This Pochara arrival information is received by the Pochara service server 9 in step S99 shown in FIG. 28 to be described later.

In step S48, the CPU 221 determines whether the Pochara figure mounted on the platform 23 is the friend Pochara figure 161. Namely, the bag information supplied from the Pochara service server 9 includes the friend Pochara flag indicative of whether the Pochara ID sent to the Pochara service server 9 is the ID of the friend Pochara. On the basis of this friend Pochara flag, the CPU 221 executes the determination processing of step S48.

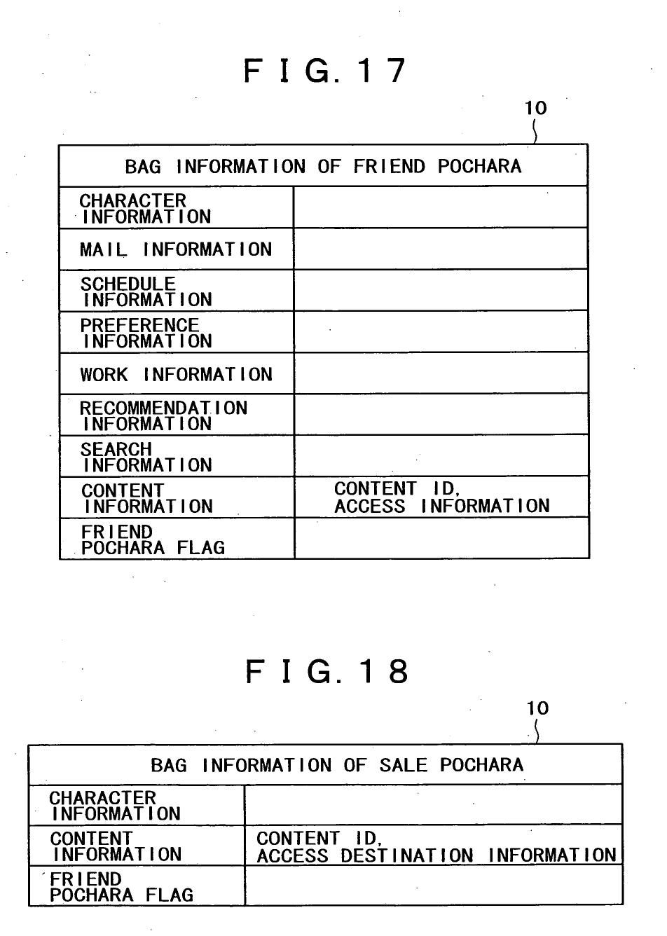

The friend Pochara bag information includes character information, mail information, schedule information, preference information, work information, recommendation information, search information, content information, and friend Pochara flag, for example, as shown in FIG. 17.

As shown in FIG. 18, the sale Pochara bag information includes character information, content information, and friend Pochara flag as shown in FIG. 18.

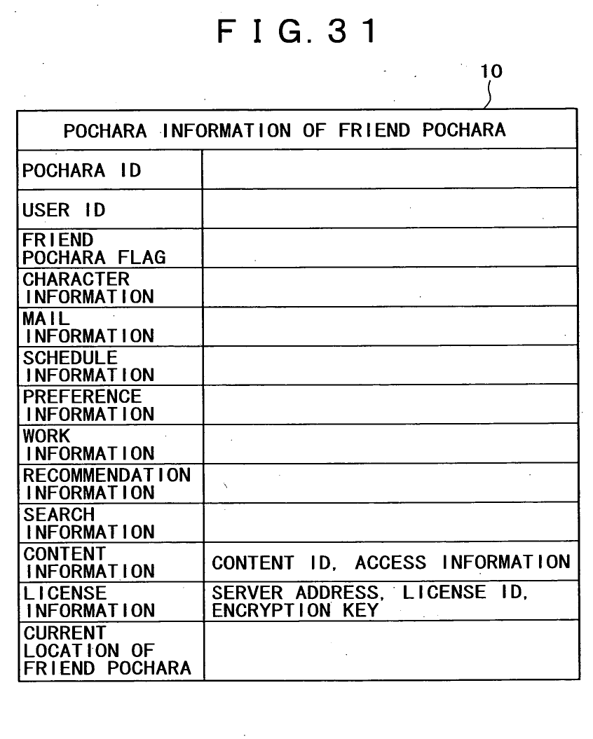

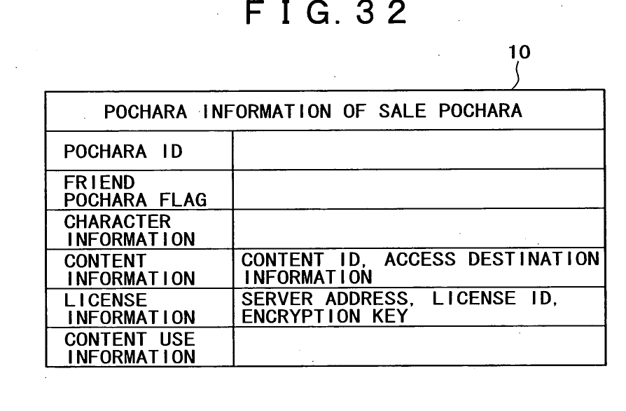

These pieces of information are sent as the bag information which are included in the Pochara information of the friend Pochara shown in FIG. 31 to be described later or the Pochara information of the sale Pochara shown in FIG. 32 to be described later. The details of these pieces of information will be described later with reference to FIGS. 31 and 32.

It should be noted that the bag information of friend Pochara or sale Pochara may also include a server address, license ID, and license information including crypto key, as required.

It is also practicable to store character information and image data of content in a terminal such as IC chip or personal computer, thereby updating these information and image data when a change occurs in them. This makes it advantageous to use lines having narrow bands or lines in which charging is made in accordance with data amount.

If the Pochara figure mounted on the platform 23 is found to be the friend Pochara figure 161, then the processing associated with the user is executed. In this case, the procedure goes to step S49, in which the CPU 221 generates Pochara image data on the basis of the bag information received in step S46, displaying the generated Pochara character on the display block of the output block 227.

Namely, the storage block 228 of the personal computer 22 stores the Pochara information received from the Pochara service server 9 in step S6 shown in FIG. 7. The CPU 221 reads the character information of friend Pochara in the Pochara information corresponding to the Pochara ID included in the bag information, sets a specific value included in the bag information to the parameter, generates the image data of friend Pochara, and outputs the generated image data to the display block of the output block 227, thereby displaying the friend Pochara (the character of the virtual friend Pochara). This character of friend Pochara has the image which corresponds to the friend Pochara figure 161 mounted on the platform 23.

In other words, the friend Pochara figure 161 has a shape which corresponds to this image (or character). Therefore, looking at the character of friend Pochara displayed on the display block of the output block 227, the user can intuitively recognize that this character corresponds to the friend Pochara figure 161 mounted on the platform 23.

Thus, the character of friend Pochara that looks the same as the figure is displayed, so that the user can easily identify the service to be used.

It should be noted that, in the above-mentioned configuration, the Pochara information for displaying the character of virtual friend Pochara is supplied from the Pochara service server 9 to the personal computer 22. Alternatively, this Pochara information may be stored in the friend Pochara figure 161. This speeds up the display of the friend Pochara character.

Also, it is practicable that the Pochara information received from the Pochara service server 9, especially the Pochara image data including parameters necessary for displaying characters such as chara polygon, texture, and motion is stored in the friend Pochara figure 161 (or the personal computer 22) when this information is received from the Pochara service server 9. In this case, every time access is made to the Pochara service server 9, it is determined whether the Pochara image data have been updated. If the Pochara image data is found not updated, then the already stored Pochara image data is used; if the Pochara image data is found updated, new Pochara image data is received from the Pochara service server 9 to be stored.

In addition, Pochara information may include the contents of the header of electronic mail (the information necessary for the selection of mail such as date of reception and a title of mail). In this case, access is made to the ISP 2 as the mail server when the user selects the electronic mail function, upon which the body of electronic mail is downloaded.

Next, in step S50, on the basis of the bag information of the friend Pochara, the CPU 221 displays a list of friend Pochara's functions as icons around friend Pochara.

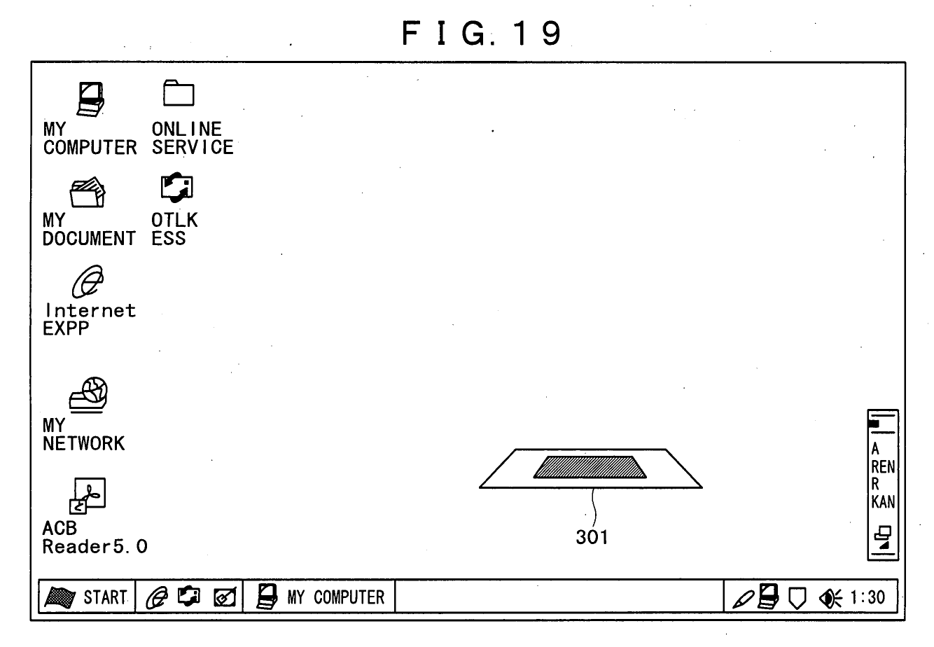

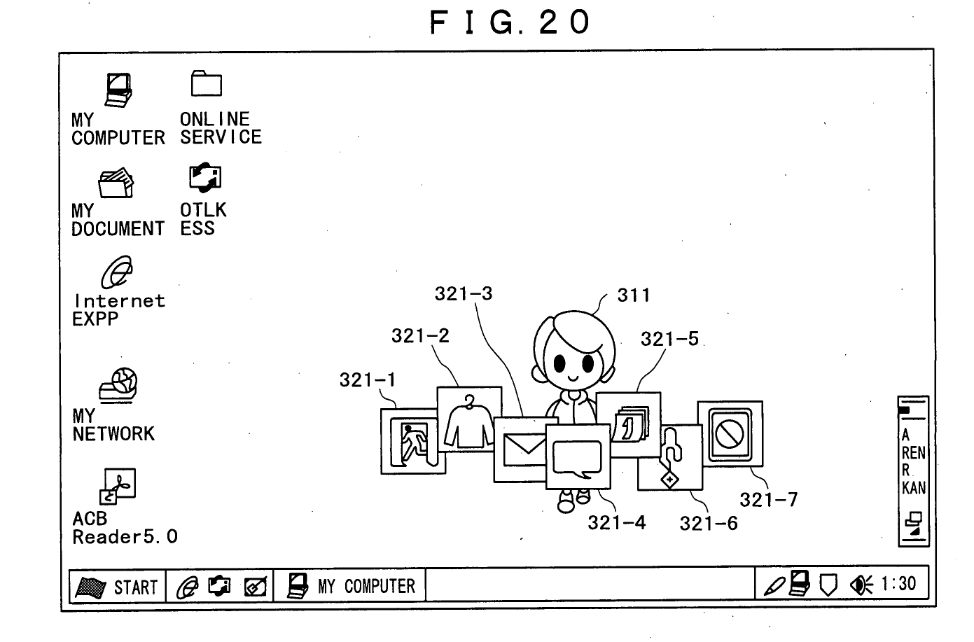

FIGS. 19 and 20 show the exemplary displays as results of the processes of steps S49 and S50.

First, as shown in FIG. 19, an appearance port 301 is displayed. Then, as shown in FIG. 20, an animation image in which a friend Pochara character 311 corresponding to the friend Pochara figure 161 appears from the appearance port 301 is displayed. As described above, this friend Pochara character 311 has an image that corresponds to the friend Pochara figure 161.

Around the friend Pochara character 311, icons 321-1 through 321-7 which correspond to the functions of the friend Pochara character 311 (or its user) are displayed. In a display example shown in FIG. 20, the number of icons is seven, but not exclusively.

It should be noted that the friend Pochara character 311 may have a bag that the user clicks to display the icons contained in that bag.

By operating the mouse for example which constitutes the input block 226, the user selects a predetermined icon from among the icons corresponding to the displayed functions.

In step S51, the CPU 221 waits until one function is selected. When one function is selected, then the procedure goes to step S52, in which the CPU 221 executes the processing corresponding to the selected function.

For example, of the seven icons, if the icon 321-3 corresponding to the mail function is selected, the CPU 221 executes the processing corresponding to the mail function. To be more specific, the CPU 221 controls the communication block 229 to request the Pochara service server 9 for reading mail information.

When the Pochara service server 9 is requested by the personal computer 22 for the retrieval of main information or at certain time intervals, the Pochara service server 9 accesses the ISP 2 (having a mail server function) to read the mail information of the user and registers the mail information on the Pochara database 10. The Pochara service server 9 reads the mail information from the Pochara database 10 and sends it to the personal computer 22 via the Internet 1, the ISP 2, and the LAN 21.

The CPU 221 displays the image corresponding to the received mail information onto the display block of the output block 227.

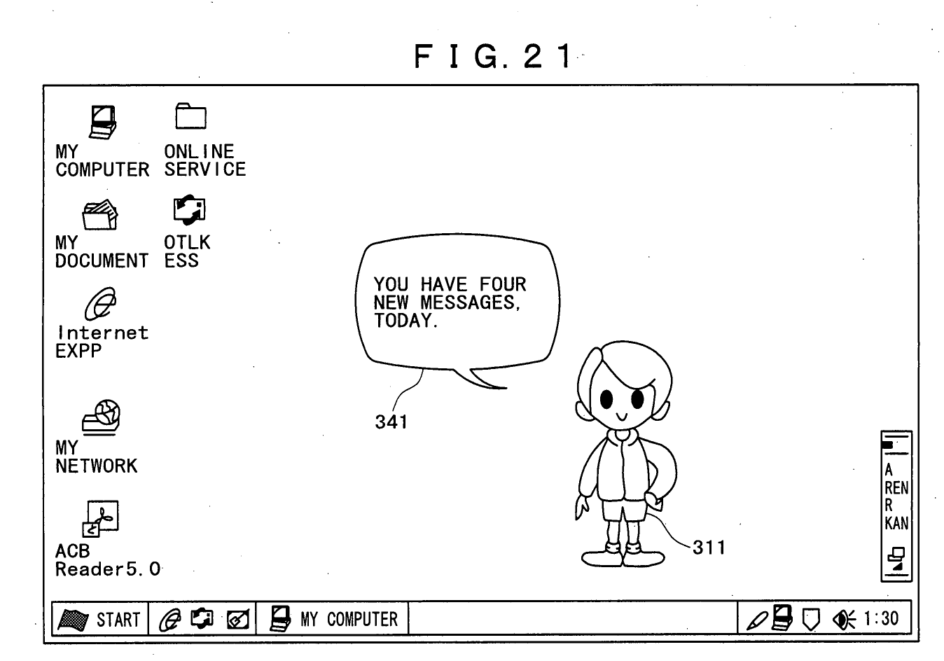

FIG. 21 shows a display example of this case. In the display example shown in FIG. 21, a balloon 341 is shown on the upper left of the friend Pochara character 311, in which a message “You have four new messages, today.” is displayed. By this display, the user can know that four new messages have arrived at his in-box.

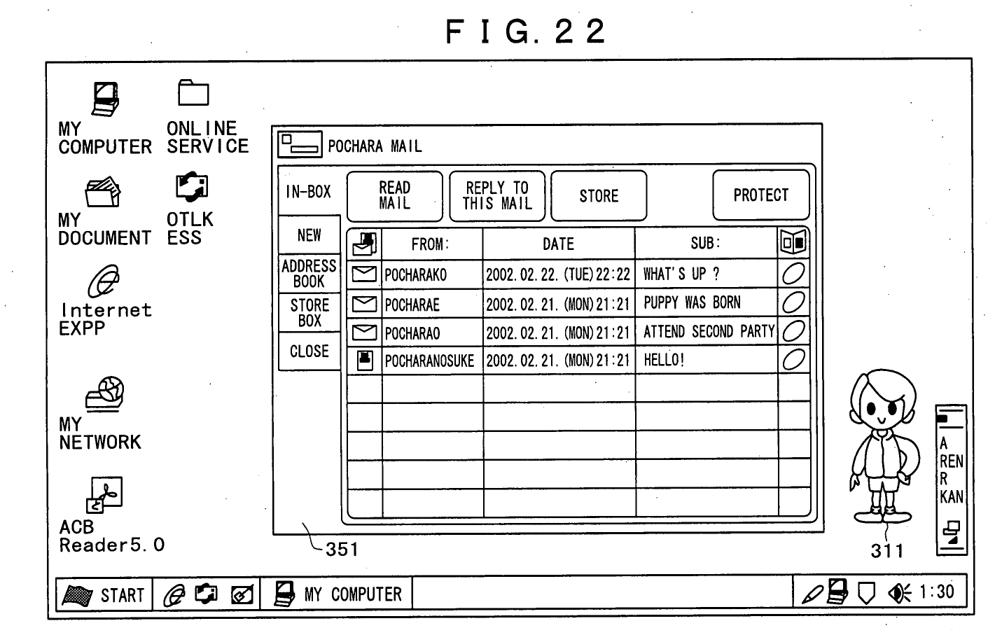

When the user gives a command to read mail by operating the mouse of the input block 226, the CPU 221 reads the mail from the ISP 2 and displays the mail title information held in the Pochara database 10 onto a window 351 as shown in FIG. 22 for example. By selecting a desired mail message from the mail messages thus displayed, the user can display the contents of the selected mail message.

When the user selects a scheduler icon 321-5 from the seven icons, then the CPU 221 accesses the Pochara service server 9 to request for reading the schedule information of the user of the friend Pochara from the Pochara database 10 and sending the schedule information to the personal computer 22.

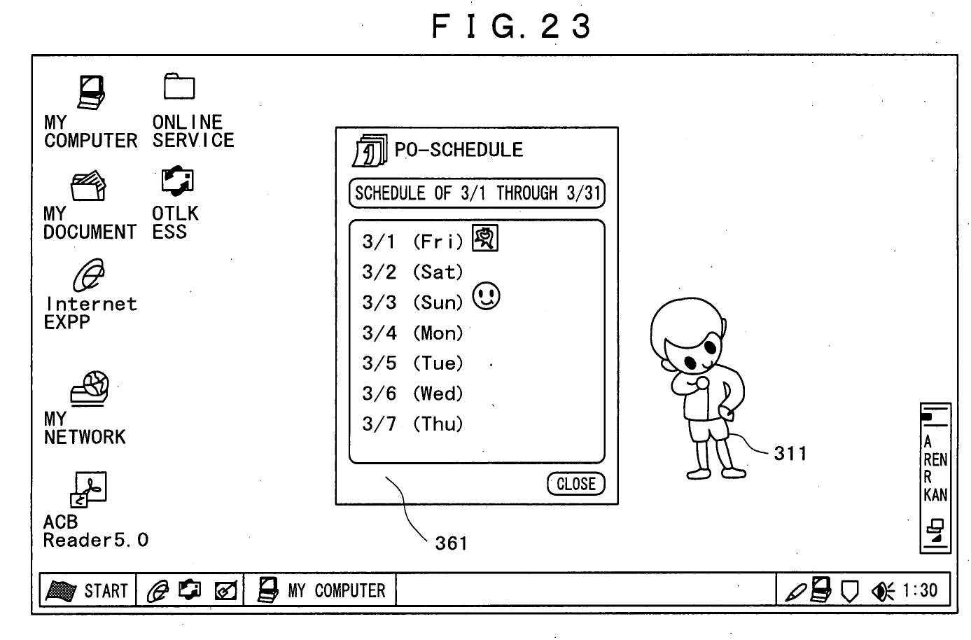

Receiving the schedule information, the CPU 221 of the personal computer 22 outputs it to the display block of the output block 227. Thus, as shown in FIG. 23 for example, the schedule of the user of the friend Pochara character 311 onto a window 361.

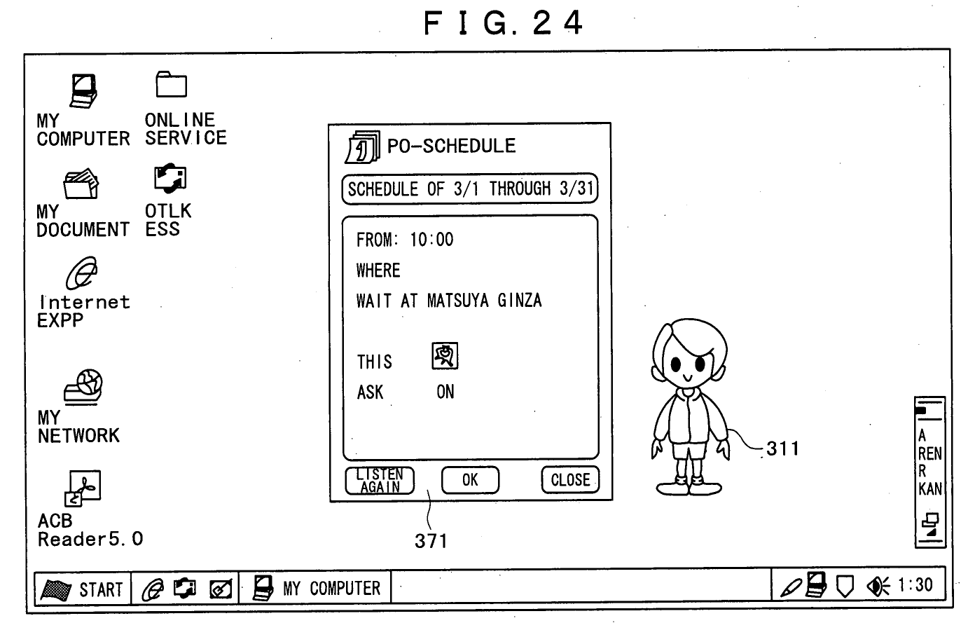

When the user clicks a desired date in the schedule shown in the window 361 by operating the mouse, the schedule of the specified date is displayed in an window 361 as shown in FIG. 24 for example.

In this display example, the schedule of the first of March is shown.

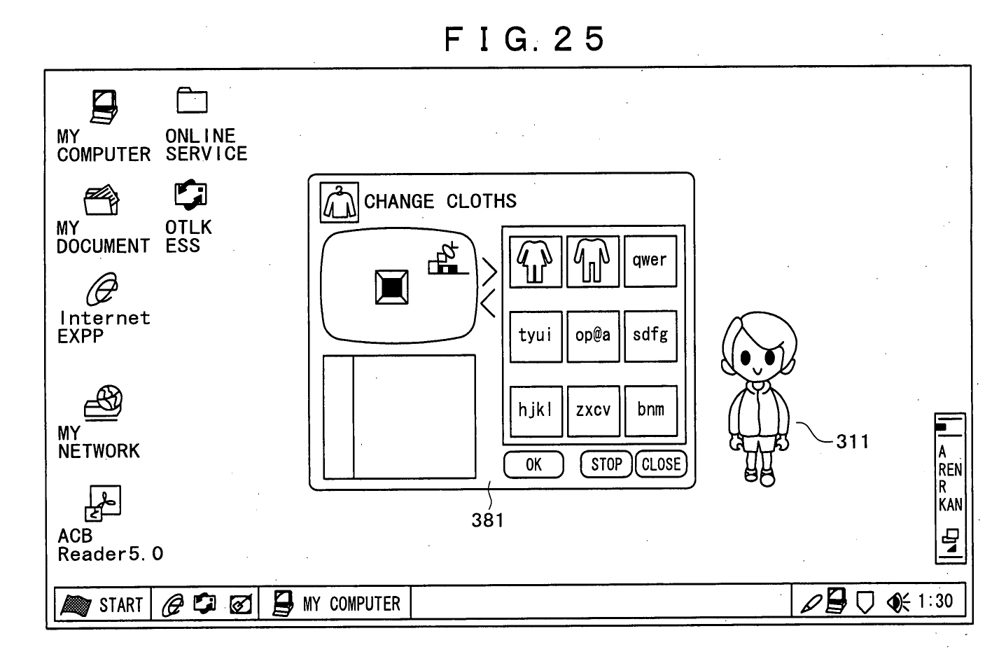

When the user selects a change-cloth icon 321-2 from the seven icons, the CPU 221 accesses the Pochara service server 9 to get the GUI necessary for cloth-change for the friend Pochara character 311 and display the GUI in a window 381 shown in FIG. 25 for example. By clicking predetermined buttons shown in the window 381, the user can change the shirt or trouser of the friend Pochara character 311 to desired one. The cloth that the friend Pochara character 311 is having is stored as a parameter. This capability can prevent the user from being bored with the friend Pochara character 311 as an avatar of the user himself.

As described above, in the processing corresponding to the selected functions shown in step S52, various processing operations are executed according to user selection. This processing will be detailed later.

Next, in step S53, the CPU 221 determines whether the friend Pochara figure 161 has been dismounted from the platform 23. If the friend Pochara figure 161 is found not dismounted, then the procedure goes to step S54, in which the CPU 221 determines whether the end of the processing associated with Pochara has been received. To end the processing associated with Pochara, the user dismounts the friend Pochara figure 161 from the platform 23 or gives a command for ending through the input block 226.

If the end of Pochara processing is found not directed in step S54, then the processing returns to step S51 to repeat the above-mentioned processing therefrom.

The CPU 221 determines that the friend Pochara figure 161 has been dismounted from the platform 23 if the data cannot be read from the IC chip 171 of the friend Pochara figure 161 mounted on the platform 23 by periodically controlling the reader/writer 241 at relatively short time intervals such as one second to give a command for data reading from the IC chip 171 of the friend Pochara figure 161.

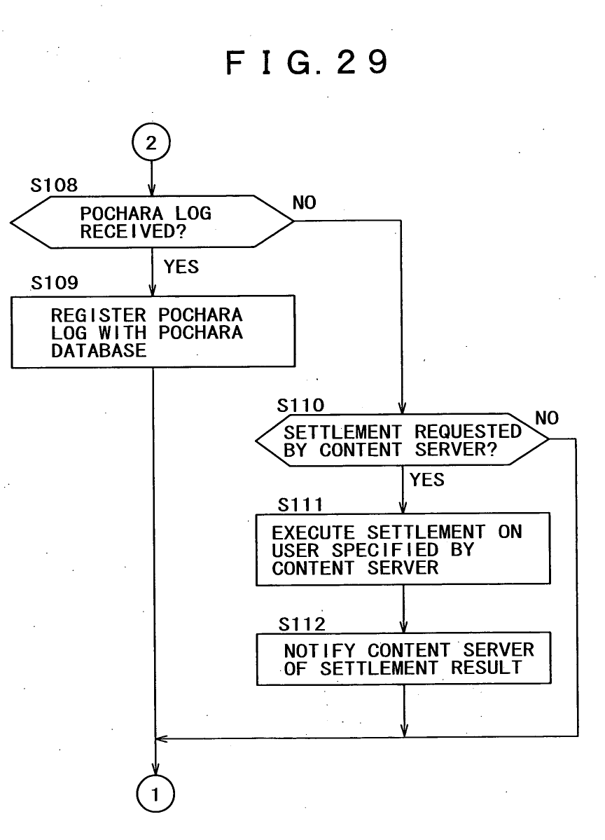

If the friend Pochara figure 161 is found dismounted from the platform 23 or if the end of Pochara processing has been directed by the user in step S54, then the CPU 221 sends a bag information change log to the Pochara service server 9 in step S55. Therefore, this log has capabilities of notifying the Pochara service server 9 of the dismounting of the friend Pochara figure 161 from the platform 23 or the command given by the user for ending Pochara processing. This log is registered in the Pochara service server 9 (step S109 shown in FIG. 29).

The above-mentioned log contains updated schedule, bookmark, character information (hair style, cloth, etc.), and user's thought information, for example. If this log is directly written to the Pochara service server 9, its update processing is executed by the Pochara service server 9 itself.

Further, in step S56, the CPU 221 displays an image in which the friend Pochara character 311 returns onto the display block of the output block 227.

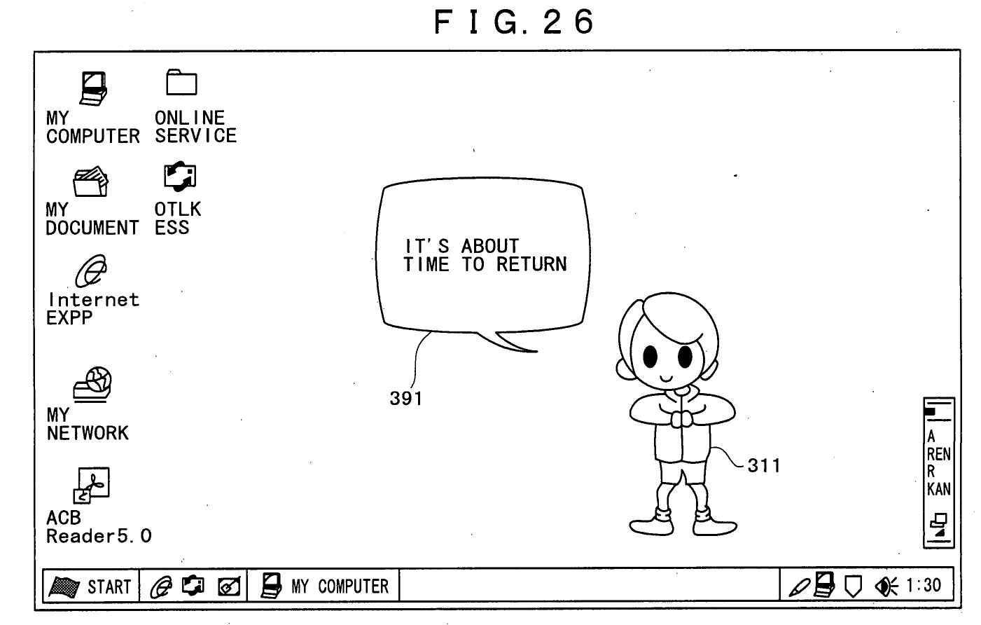

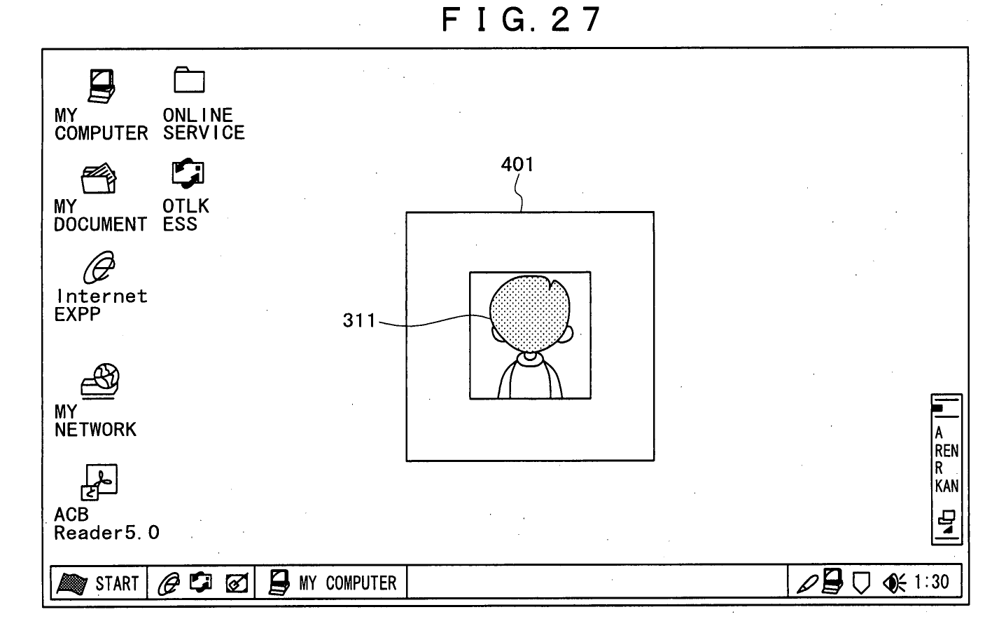

FIGS. 26 and 27 show display examples in which the friend Pochara character 311 returns.

In the display example shown in FIG. 26, a balloon 391 is shown on the upper left of the friend Pochara character 311, in which message “It's about time to return.” is displayed. Then, as shown in FIG. 27, an animation image is displayed in which an exit 401 is displayed and the friend Pochara character 311 returns through this exit 401.

Through these displays, the user can intuitively recognize the end of the processing associated with friend Pochara. Namely, if the friend Pochara figure 161 is dismounted from the platform 23, then the CPU 221 executes logout processing of clearing the connection with the Pochara service server 9 in step S54.

As described above, the Pochara (character) same as a figure is displayed at the start of the Pochara service and this display is ended at the end of the service, so that the user can easily know login and logout sequences. Therefore, this configuration prevents the user from misunderstanding that the device is malfunctioning because service cannot be used owning to the untimely inputting of operations necessary for receiving the services.

Referring to FIG. 12 again, if the figure mounted on the platform 23 is found not to be the friend Pochara figure 161 (namely, the figure is found to be the sale Pochara figure 181) in step S48, then the procedure goes to step S57, in which the CPU 221 of the personal computer 22 generates Pochara image data on the basis of the Pochara information of sale Pochara included in the bag information received in step S46 and displays the generated sale Pochara character (the virtual figure of the sale Pochara figure 181) onto the display block of the output block 227. Namely, as shown in FIGS. 30 through 32 to be described later, the Pochara database 10 stores the Pochara information and content image data of the sale Pochara and these Pochara information and content image data are sent to the Pochara service server 9 as contained in the authentication information. This sale Pochara character is also an image having substantially the same shape as the sale Pochara figure 181 (namely, the image that allows the use to intuitively recognize the virtual figure corresponding to the sale Pochara figure 181).

In step S58, the CPU 221 extracts the content image data (content use information) from the bag information received in step S46, generates a content image on the basis of the extracted content image data, and displays the generated image onto the display block of the output block 227. Consequently, the content image corresponding to the content associated with the sale Pochara figure 181 purchased by the user is displayed on the output block 227. This content image includes the description of associated content and a message “To download this music, click the access button”, for example.

Therefore, in order to get content, the user operates the access button in the displayed content image by operating the mouse for example of the input block 226.

In step S59, the CPU 221 waits until a command for accessing the content server is given (or until the access button is operated). When a command for accessing the content server is found given, the procedure goes to step S60, in which the CPU 221 reads the use condition (FIG. 11) from the IC chip 191. In step S61, the CPU 221 determines whether the use condition is satisfied. This use condition includes the expiration date of content, for example. The CPU 221 determines whether the use condition is satisfied by comparing the current date counted by the incorporated timer with the expiration date specified in the use condition. If a maximum number of times content can be used or a prepaid amount are specified in the use condition, the CPU 221 determines whether the value is 0.

If the use condition is found satisfied (for example, the current date is before the expiration date and the maximum number of times or the prepaid amount is not 0) in step S61, then the procedure goes to step S62, in which the CPU 221 accesses the content server on the basis of the access destination information stored in the IC chip 191, thereby requesting the content server for sending content data. Consequently, the content server 6 shown in FIG. 1 is requested for sending content data.

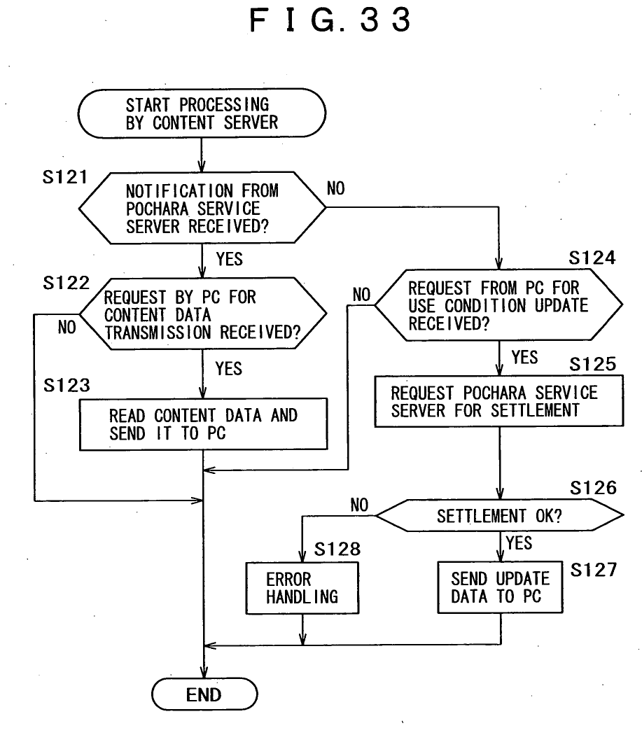

In response to this request, the content server 6 sends the content data via the Internet 1 (step S123 shown in FIG. 33 to be described later). In step S63, the CPU 221 of the personal computer 22 receives the content data from the content server 6 via the communication block 229. This content data is supplied to the storage block 228 to be stored therein.

In step S64, the CPU 221 decodes the content data received and stored in step S63 and outputs the decoded content data. Namely, the content data received from the content server 6 is encrypted and therefore the CPU 221 decodes the encrypted content data by use of crypto key included in the license information (FIG. 32) obtained from the Pochara service server 9. Then, the CPU 221 outputs the decoded content data through the output block 227.

It should be noted that, if the encrypted content and the crypto key are transmitted via the Internet 1, they may be intercepted by a third party, so that the crypto keys may be changed every time encrypted content is reproduced (or copied).

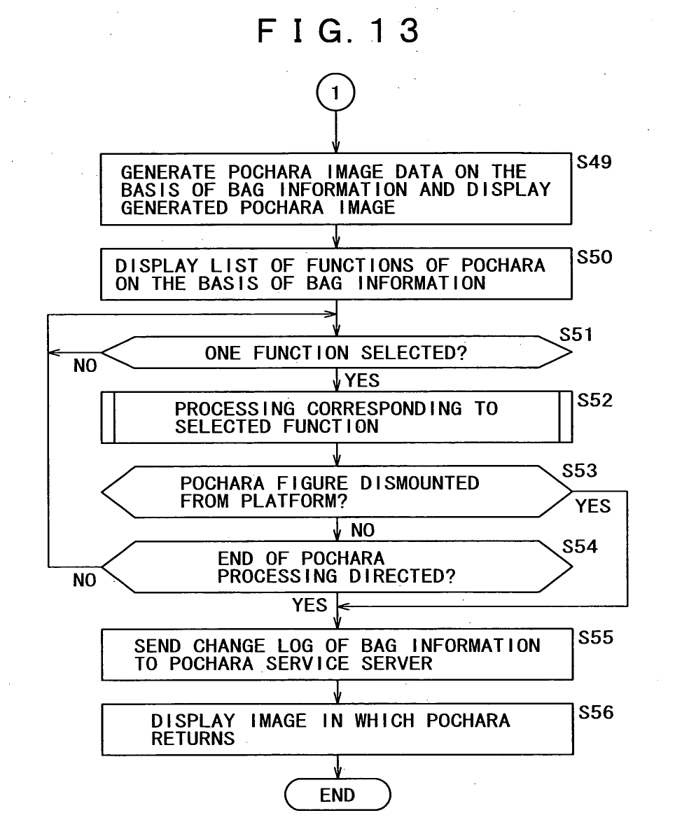

In step S65, the CPU 221 determines whether the end of content output has been entered through the input block 226 (the end of content output has been directed by the user). If the end of content output is found not directed, then the procedure goes to step S66, in which the CPU 221 determines whether the sale Pochara figure 181 has been dismounted from the platform 23. This determination processing is executed in the same manner as the processing of step S53 shown in FIG. 13.

If the sale Pochara figure 181 is found not dismounted from the platform 23 in step S66, then the procedure returns to step S65 to repeat the above-mentioned processing therefrom.

If the end of content output is found directed in step S65 or if the sale Pochara figure 181 is found dismounted from the platform 23 in step S66, then the procedure goes to step S67, in which the CPU 221 ends the content output processing.

Next, in step S68, the CPU 221 controls the reader/writer 241 to update the use condition stored in the IC chip 191 of the sale Pochara figure 181. For example, if the maximum number of times content may be used (the maximum number of times content may be reproduced) is specified, the value is decremented by one. For example, if the maximum number of times is specified to be 20, the value is decremented by one and, when the value reaches 0, the use (or reproduction) of the content is disabled.

If the prepaid amount stored in the IC chip 191 of the sale Pochara figure 181 is reduced every time content is used, the CPU 221 updates such that this prepaid amount is reduced by a predetermined amount (an amount equivalent to one reproduction of content) in step S69. Only one of the process of step S68 and the process of step S69 may be executed.

In step S70, as with the case of step S56 shown in FIG. 13, the CPU 221 displays an image in which the sale Pochara character returns onto the display block of the output block 227. Consequently, the user can dismount the sale Pochara figure 181 from the platform 23 and, after giving a command to end content output, intuitively recognize the end of content output.

If the use condition is found not satisfied (the expiration date has passed, the maximum number of times content may be used has been reached, or the prepaid amount is 0) in step S61, then the procedure goes to step S71, in which the CPU 221 generates a predetermined message and displays it onto the display block of the output block 227. Consequently, if the number of times reproduction is allowed has been reached for example, a message such as “Content has been reproduced N times. If you want to use the content more, you have to make new payment” is displayed. On the basis of this message, the user gives a command for updating the use condition through the input block 226 to use the content further.

In step S72, the CPU 221 determines whether a request for updating the use condition has been made. If the request for updating the use condition is found made, the procedure goes to step S73, in which the CPU 221 accesses the content server 6 through the Internet 1 on the basis of the access destination information (FIG. 18) included in the content information in the bag information. In step S74, the CPU 221 requests the content server 6 for updating the use condition; namely, the maximum number of times content can be used and the prepaid amount. In response to this request, the content server 6 sends the update data to the personal computer 22 when the content server 6 is notified by the Pochara service server 9 that this user can be settled in charging (step S127 shown in FIG. 33).

Therefore, in step S75, the CPU 221 determines whether the update data has sent from the content server 6. If the update data is found sent, then the procedure goes to step S76, in which the CPU 221 receives the update data from the content server 6 and supplies the received update data to the IC chip 191 via the reader/writer 241, thereby updating the maximum number of times content may be used and the prepaid amount.

As described above, by requesting the update of the maximum number of times content may be used and the prepaid amount, the user can use content any number of times by use of the sale Pochara figure 181.

It should be noted, as will be described later, that, when the prepaid amount is updated, the license server 8 executes a charging processing on the user (step S105 shown in FIG. 28) on the basis of the request by the content server 6 (step S125 shown in FIG. 33).

If the update data is found not sent in step S75, then the procedure goes to step S77, in which error handling is executed.

To be more specific, if the Pochara service server 9 determines that the user of that sale Pochara figure 181 cannot settle the prepaid amount due to the insufficient funds in user's bank account for example, the content server 6 sends an error message to the personal computer 22 (step S118 shown in FIG. 33). In this case, the CPU 221 executes error handling because no update data has been sent. To be more specific, the CPU 221 displays a message such as “You cannot use content any more” for example onto the display block of the output block 227.

If the CPU 221 determines that no request for updating the use condition is made by the user in step S72, then steps S73 through S77 are skipped.

It should be noted that a configuration may be used in which a credit card incorporating an IC chip is mounted on the platform to make the settlement of the prepaid amount from that credit card.

The following describes, with reference to the flowcharts of FIGS. 28 and 29, the processing by the Pochara service server 9 which is executed in response to the processing by the personal computer 22 indicated by the flowcharts of FIGS. 12 through 16.

In step S91, the CPU 191 of the Pochara service server 9 determines whether the Pochara ID has been received from the personal computer 22. If the Pochara ID is found not received, then the procedure goes to step S108 to determine whether a Pochara log has been received. If the Pochara log is found not received in step S108, then the procedure goes to step S110, in which the CPU 121 determines whether a settlement request has been received from the content server 6. If the settlement request is found not received, then the procedure returns to step S91 to repeat the above-mentioned processing therefrom.

If the Pochara ID is found received in step S91, then the procedure goes to step S92, in which the CPU 121 searches the Pochara database 10 for the Pochara ID (sent from the personal computer 22 in step S43 shown in FIG. 12) received from the personal computer 22.

The Pochara database 10 stores user information and Pochara information as shown in FIGS. 30 through 32 for example. The user information (FIG. 30) contains user ID for user identification, user's name, address, birthday, gender, telephone number, facsimile number, mail address, user registration date, and user's credit card number and bank account, for example.

The Pochara information is divided into the Pochara information of friend Pochara (FIG. 31) and the Pochara information of sale Pochara (FIG. 32).

The Pochara information of friend Pochara contains the Pochara ID of the friend Pochara figure of that user, user ID, the friend Pochara flag indicative whether that Pochara is friend Pochara or sale Pochara, or the Pochara character data necessary for displaying that Pochara typified by the parameter associated with the cloth of that Pochara.

For the Pochara information, the information about the functions of friend Pochara is also registered. In the example shown in FIG. 31, mail information, schedule information, preference information, work information, recommendation information, and search information are stored. The mail information contains the mail received so far by that user and the mail sent so far from that user.

The schedule information contains the current and past schedules of that user and the memos written by that user. The schedule information also contains the information about various events to be executed by the Pochara.

The preference information contains the URLs of home pages bookmarked by the user, for example.

The work information contains the information about services which can be received by registering beforehand the terminal (hardware) owned by the user. The work information also stores the data temporarily deposited by the user.

The recommendation information contains recommended content collected by the friend Pochara by analyzing user's thought.

The search information contains the information about search engines and the information about sale Pocharas of which searching was directed beforehand by the user.

The Pochara information also contains the current position indicative of the position at which the friend Pochara character is actually displayed on the network. This positional information prevents the friend Pochara character from being simultaneously displayed at more then two positions on the network (thereby realizing the exclusiveness of display). In other words, this positional information prevents other users from intercepting the information of this user by use of another friend Pochara figure which masquerades as the friend Pochara figure 161 of this user. Namely, the Pochara service server 9 executes error handling if the friend Pochara ID is transmitted from a position other than the current position. Consequently, only one friend Pochara figure is displayed on the device on the network.

In addition, the positional information prevents the loss of data integrity that is otherwise generated by accessing the Pochara service server 9 from two or more devices at the same time. In other words, moving of one Pochara between two or more devices allows the user to intuitively understand the exclusive access.

The Pochara information also contains the information about the content obtained by the user and the license information necessary for using the content. The content information includes the content ID for identifying content and the access information necessary for accessing the content. The license information includes the license ID for identifying the license, a crypto key for decoding the encrypted content, and the address of the license server which is accessed for getting the license, for example.

The Pochara information of sale Pochara contains Pochara ID, friend Pochara flag, character information, content information, license information, and content user information.

As a result of the search operation in step S92, the CPU 121 determines, in step S93, whether the Pochara ID is stored in the Pochara database 10. If the Pochara ID is found stored, then the procedure goes to step S94, in which the CPU 121 determines whether the received Pochara ID is the ID of the friend Pochara. As described above, this determination can be made by the friend Pochara flag.

If the Pochara ID is found to be the ID of the friend Pochara, then the procedure goes to step S95, in which the CPU 121 reads the Pochara information (FIG. 31) from the Pochara database 10.

In step S96, the CPU 121 determines from the current position of friend Pochara stored in the read Pochara information whether the current position of the friend Pochara is inside the Pochara service server 9. If the current position of the friend Pochara is found to be in the Pochara service server 9, then the procedure goes to step S103, in which the CPU 121 sends error information to the personal computer 22.

Namely, in this case, although the current position of the friend Pochara is inside the Pochara service server 9, the access has been made from another device on the basis of the friend Pochara figure 161, so that this access may be masquerading. Therefore, in this case, error handling is executed.

If the current position of the friend Pochara is found not to be inside the Pochara service server 9 in step S96, then the procedure goes to step S97, in which the CPU 121 reads the bag information from the Pochara database 10. Then, in step S98, the CPU 121 sends the read bag information to the personal computer 22.

In step S99, the CPU 121 determines whether Pochara arrival information has been received. As described above, when the personal computer 22 has received the bag information, the personal computer 22 sends it (step S47 shown in FIG. 12). If the Pochara arrival signal is not received although the bag information has been sent in step S98, it indicates that something abnormal has happened. Therefore, the procedure goes to step S103, in which the CPU 121 sends error information to the personal computer 22.

On the contrary, if the Pochara information is found received in step S99, then the procedure goes to step S100, in which the CPU 121 registers (or updates), on the Pochara database 10, the current position of the friend Pochara as being on the personal computer 22. Namely, because the friend Pochara has now arrived at the personal computer 22, the current position of the friend Pochara is registered as the personal computer 22.

As described above, when the user of the personal computer 22 selects one of the functions of the friend Pochara character 311, the information about the selected Pochara function is sent from the personal computer 22 (step S52 shown in FIG. 13).

In step S101, the CPU 121 of the Pochara service server 9 determines whether a function of the friend Pochara character 311 has been selected. If a function is found selected, then the procedure goes to step S102, in which the CPU 121 executes the processing corresponding to the selected function. Consequently, if the mail function has been selected for example, the information registered as the mail information is sent to the personal computer 22. If schedule function is selected for example, the registered schedule information is sent to the personal computer 22.

If no Pochara function is found selected in step S101, then the process of step S102 is skipped and the procedure returns to step S91 to repeat the above-mentioned processing therefrom.

If the obtained Pochara ID is found not to be the ID of the friend Pochara figure 161 in step S94 (or if the ID is found to be the ID of sale Pochara), then the procedure goes to step S104, in which the CPU 121 notifies the server corresponding to the sale Pochara figure (the content server 6 in the case of the ID corresponding to the sale Pochara figure 181) thereof. As will be described later, if the content server 6 receives this notification from the Pochara service server 9 and if the content server 6 receives a request for the transmission of content data from the personal computer 22, the content server 6 reads the requested content data and sends it to the personal computer 22 (steps S121 through S123 shown in FIG. 33 to be described later).

It should be noted that the Pochara service server 9 also manages the sale Pochara figures corresponding to the content provided by content providers and the services provided by service providers. Therefore, the Pochara database 10 stores Pochara IDs, content image data (content use information) necessary for displaying content images accompanying the content identified by content ID (for example, if the content is audio data of predetermined singer's songs, then music titles, lyrics, and singer's video), and content information for example, as the Pochara information necessary for displaying the characters of the virtual Pochara figures corresponding to all the sale Pochara figures 181. This content information includes an access destination (an address on the network) to which user's access is sent when the user sends that sale Pochara ID. The CPU 121 sends the notification to this access destination (the destination of notification).

Next, in step S105, the CPU 121 executes charging processing. Namely, in the present system, the user pays the price for a predetermined service every time the user mounts the sale Pochara figure 181 on the platform 23 to receive the service.

To be more specific, the CPU 121 of the Pochara service server 9 access the charging server 13 via the communication block 129 to request the charging processing on the credit card or band account of the user. In response to this request, the charging server 13 executes the charging processing of a predetermined amount.

Thus, the manager of the Pochara service server 9 can realize a profit from the use of the sale Pochara figure 181 by the user.

It should be noted that this charging processing may also be executed not on the user but on the manager who sold the sale Pochara figure 181.

Next, in step S106, the CPU 121 reads the bag information (FIG. 18) of sale Pochara from the Pochara database 10 and sends it to the personal computer 22 in step S107.

When the process of step S107 has been completed, the procedure returns to step S91 to repeat the above-mentioned processing therefrom.

It should be noted that, if the sale Pochara figure 181 is a Pochara figure associated with fortune telling for example and if the data amount of fortune telling content is not so large, then the bag information shown in FIG. 18 may also contain the fortune telling content, which is displayed at the same time the Pochara character is displayed upon its calling.

If the Pochara log is found received in step S108, then the procedure goes to step S109, in which the CPU 121 executes the processing of registering (updating) the received Pochara log on the Pochara database 10. Then, the procedure returns to step S91 to repeat the above-mentioned processing therefrom.

Thus, if the Pochara log is received from the personal computer 22 by the processing of step S55 shown in FIG. 13 for example, the Pochara database 10 is updated on the basis of the received Pochara log.

If the settlement request is found made from the content server 6 (the process of step S125 shown in FIG. 33 to be described later) in step S110, then the procedure goes to step S111, in which the CPU 121 executes the settlement processing on the user requested by the content server 6. To be more specific, the CPU 121 checks if there has been any insolvency with respect to the credit card number or bank account number of the user registered in the user information (FIG. 30) in the Pochara database 10. In step S112, the CPU 121 notifies the content server 6 of a result of the checking (a settlement result).

Then, the procedure returns to step S91 to repeat the above-mentioned processing therefrom.

The following describes, with reference to the flowchart shown in FIG. 33, the processing to be executed by the content server 6 with the sale Pochara figure 181 mounted on the platform 23 to receive the provision of content.

In step S121, the CPU 121 of the content server 6 determines whether a notification (a notification sent in step S104 shown in FIG. 28) of the access by the personal computer 22 has been received from the Pochara service server 9 via the communication block 129. If the notification is found not received from the Pochara service server 9, then the procedure goes to step S124, in which the 121 determines whether a prepaid amount (or maximum number of times content may be used) update request (step S74 shown in FIG. 16) from the personal computer 22 has been received. If the prepaid amount (or the maximum number of times content may be used) update request is found not received, this processing comes to an end.

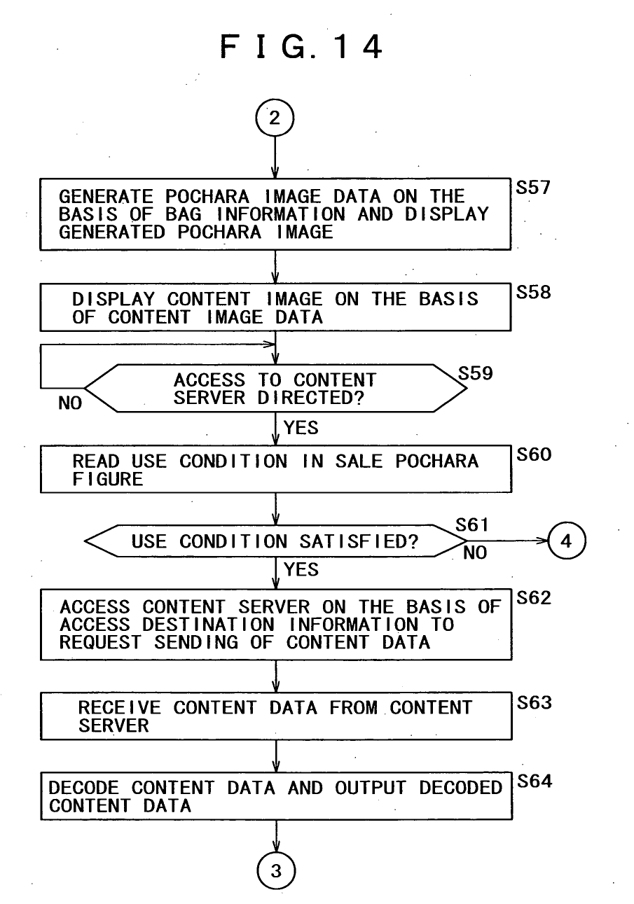

If the notification is found received from the Pochara service server 9 in step S121, then the procedure goes to step S122, in which the CPU 121 determines whether a request (step S62 shown in FIG. 14) for sending content data from the personal computer 22 described in that notification has been received. If the content data sending request from the personal computer 22 is found received, then the procedure goes to step S123, in which the CPU 121 reads the encrypted content data from the storage block 128 and sends the content data to the personal computer 22.

It should be noted that this content data may be stored in the storage block 128 as encrypted beforehand or may be encrypted every time it is sent.

The notification from the Pochara service server 9 obtained in step S121 must contain the information for identifying content. This information may be content ID or, if content and sale Pochara figure 181 correspond with each other, this information may be Pochara ID.

If the content data sending request from the personal computer 22 is found not received in step S122, then the process of step S123 is skipped.

Namely, content data is not sent if the notification is received from the Pochara service server 9 but the user of the personal computer 22 described in that notification does not request the sending of content data.

If the request for updating the prepaid amount (or the maximum number of times content may be used) from the personal computer 22 is found received in step S124, then the procedure goes to step S125, in which the CPU 121 requests the Pochara service server 9 for the settlement. In response to this request, the Pochara service server 9 executes the settlement processing on the user of the sale Pochara figure 181 and notifies the content server 6 of a result of the settlement (steps S111 and S112 shown in FIG. 29 described above).

In step S126, the CPU 121 of the content server 6 determines whether the settlement is successful on the basis of the notification received from the Pochara service server 9 on the basis of the request of step S125. If the settlement is found to be successful, then the procedure goes to step S127, in which the CPU 121 sends update data for updating the prepaid amount (or the maximum number of times content may be used) to the personal computer 22. As described above, the personal computer 22 updates the prepaid amount (or the maximum number of times content may be used) of the IC chip 191 in the sale Pochara figure 181 on the basis of the received update data (step S76 shown in FIG. 16). Consequently, the user can use the content again.

If the notification from the Pochara service server 9 indicates that the settlement is not successful in step S126, then the procedure goes to step S128, in which the CPU 121 executes error handling. Namely, at this moment, the CPU 121 outputs a message to the personal computer 22 indicative that content cannot be provided. This tells the user that the prepaid amount (or the maximum number of times content may be used) could not be updated. This message is displayed on the personal computer 22 in step S76 shown in FIG. 16.

The following describes the processing of getting the license from the license server 8 necessary for using content obtained from the content server 7 by mounting the friend Pochara figure 161 on the platform 23: This processing is executed as one of the processing operations corresponding to functions selected in step S52 shown in FIG. 13. Namely, this processing is started when the content acquisition function among the functions of the friend Pochara character 311 is selected.

In step S131, the CPU 221 of the personal computer 22 accesses the content server 7 to request the sending of content. The address to access is obtained by the user as required.

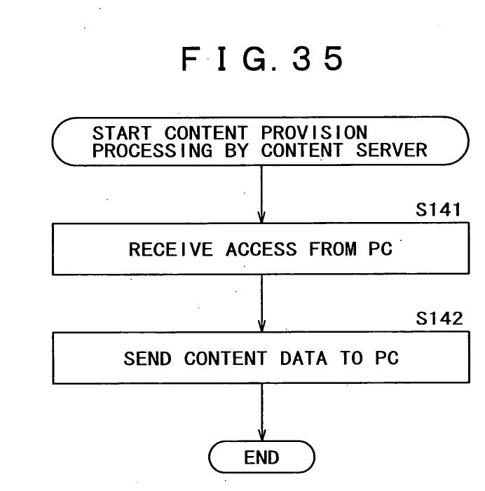

As will be described later, the content server 7 sends content data attached with content ID and license ID to the accessing personal computer 22 (step S142 shown in FIG. 35 to be described later). In step S132, the CPU 221 of the personal computer 22 receives the content data from the content server 7 via the Internet 1 and, in step S133, supplies the received content data to the storage block 228 to store it therein.

Next, in step S134, the CPU 221 sends, to the Pochara service server 9, the content ID for identifying the content obtained now, the access information for accessing the stored content data (the information necessary for reading the content data from the storage block 228), and the address on network (this address is sent from the content server 7 as attached to the content data) of the license server (the license server 8 in the case of the system shown in FIG. 1) which issues the license for the content obtained now.

In response to the access from the personal computer 22 described above, the content server 7 executes the processing indicated by the flowchart shown in FIG. 35.

To be more specific, when accessed from the personal computer 22 in step S141, the CPU 121 of the content server 7 reads the content data from the storage block 128 and sends it to the personal computer 22 in step S142. At this moment, the CPU 121 also sends the content ID and the license ID for identifying the license necessary for using that content. It should be noted that this content data is also encrypted.

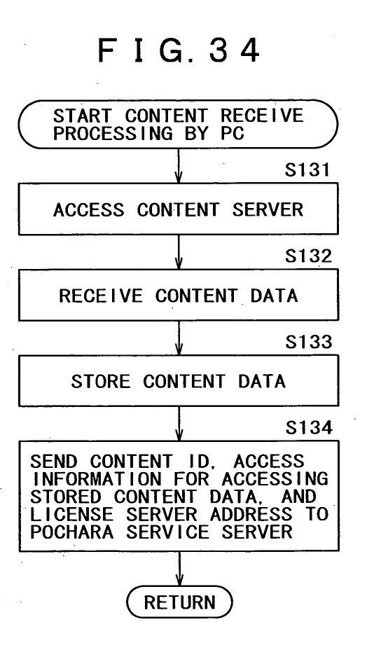

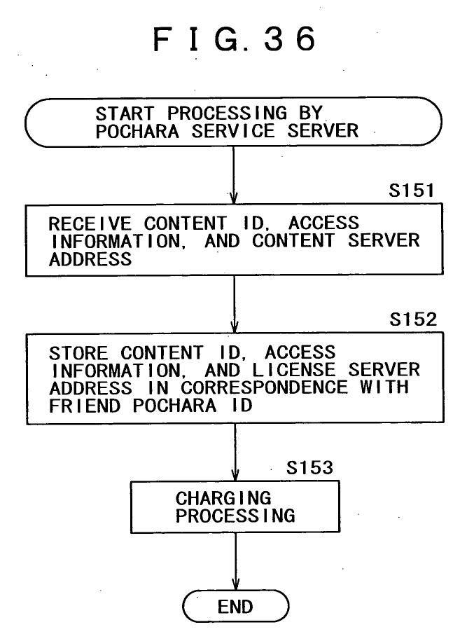

In response to the processing by the personal computer 22 of step S134 shown in FIG. 34, the Pochara service server 9 executes the processing indicated by the flowchart shown in FIG. 36.

First, in step S151, the CPU 121 of the Pochara service server 9 receives the content ID, access information, and license server address sent by the personal computer 22 in step S134. In step S152, the CPU stores the content ID, access information, and license server address received in step S151 into the Pochara database 10 in correspondence with the friend Pochara ID received together.

Next, in step S153, the CPU 121 executes the charging processing which corresponds to the processing in which the user obtained the content. Namely, the CPU 121 requests the charging server 13 for the settlement of the amount of money equivalent to the price of the content. In response to this request, the charging server 13 executes the charging processing on the user.

It should be noted that the charging processing for the provision of content may be omitted by executing the charging at the time of the provision of content. Not by executing charging for the provision of content, but by executing charging at the time of the provision of license, the user can receive and store content at any desired terminal multiple times without being concerned about the amount of money. This allows the efficient distribution of content.

Also, by storing content in reproducing devices in advance, the high quality content may be used on these devices if they are connected to the Internet 1 with narrow-band cables.

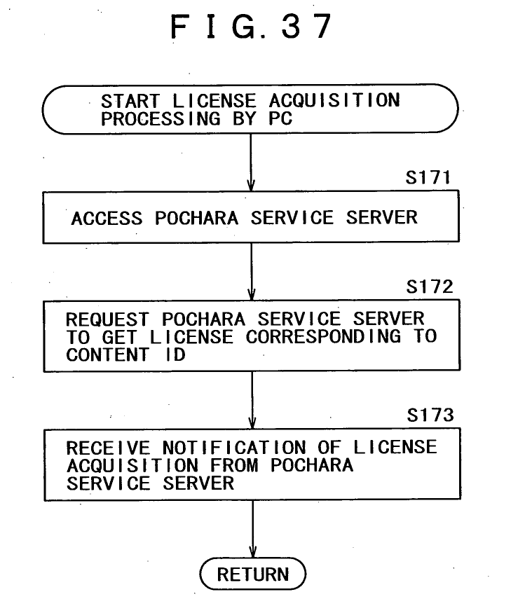

Acquisition of content as described above does not allow the user to use it. Namely, to use the acquired content, the user must get the license necessary for using the acquired content. To get this license, the personal computer 22 executes the processing indicated by the flowchart shown in FIG. 37.

This processing is also executed as one of the processing operations corresponding to the functions selected in step S52 shown in FIG. 13.

In step S171, the CPU 221 of the personal computer 22 accesses the Pochara service server 9. In step S172, the CPU 221 requests the Pochara service server 9 for getting the license corresponding to the content ID. This content ID is contained in the content data received in the process of step S132 shown in FIG. 34.

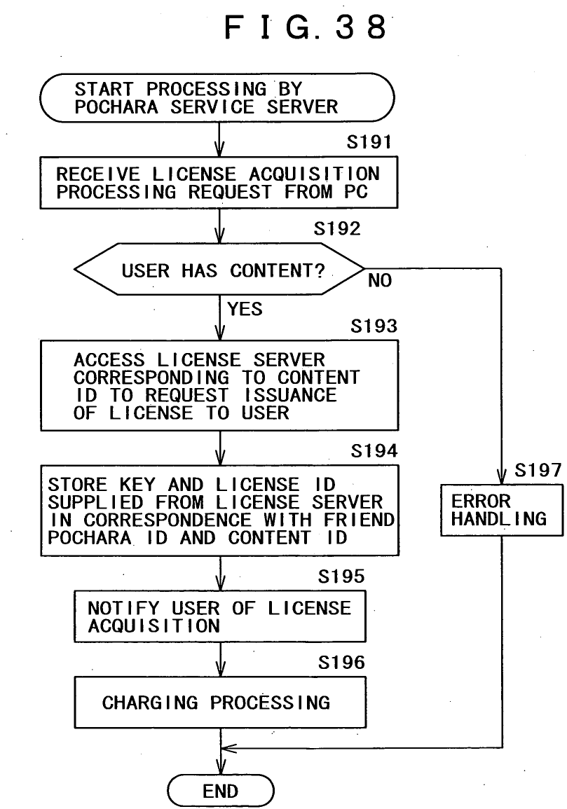

Thus, in response to the request for the license, the Pochara service server 9 accesses the license server to get the license. When the license has been acquired, the Pochara service server 9 notifies the personal computer 22 of the acquisition of the license (steps S194 and S195 shown in FIG. 38 to be described later).

In step S173, the CPU 221 receives the notification of the license acquisition from the Pochara service server 9. The CPU 221 outputs this notification onto the display block of the output block 227. Consequently, the user knows the acquisition of the license.

The following describes, with reference to the flowchart shown in FIG. 38, the processing to be executed by the Pochara service server 9 in response to the license acquisition processing executed by the personal computer 22 shown in FIG. 37.

In step S191, the CPU 121 of the Pochara service server 9 receives the request (the request outputted in step S172 shown in FIG. 37) from the personal computer 22 for license acquisition processing. In step S192, the CPU 121 determines whether the user has the content. If the user has the content, the access information for accessing this content is stored in the Pochara database 10 (step S152 shown in FIG. 36). Therefore, on the basis of this access information, the CPU 121 can determine whether the user has the content.

If the user is found having the content in step S192, then the procedure goes to step S193, in which the CPU 121 accesses the license server corresponding to the content ID to request the issuance of the license to the user. If the user is found already acquiring the content in step S152 shown in FIG. 36, the address of the license server for the use of that content is also stored in the Pochara database 10. The address of the license server for issuing the license is also registered.

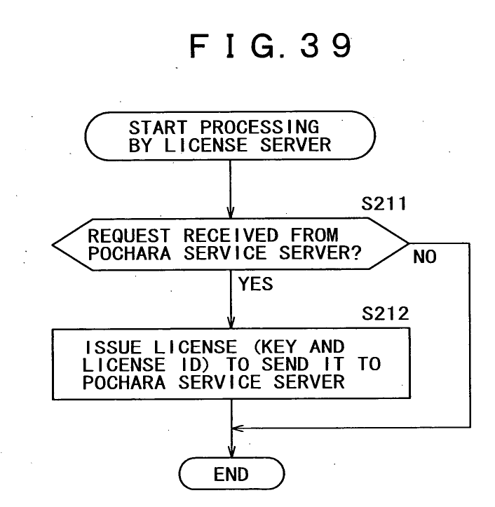

In response to the request from the Pochara service server 9 for the issuance of the license, the license server 8 issues the license and sends it to the Pochara service server 9 (step S212 shown in FIG. 39 to be described later).

In step S194, the CPU 121 stores the crypto key (the key for decoding the encrypted content) and the license ID received from the license server 8 into the Pochara database 10 in correspondence with the friend Pochara ID and the content ID.

Next, in step S195, the CPU 121 notifies the user (or the personal computer 22) of the acquisition of the license.

In step S196, the CPU 121 executes the charging processing for the license acquisition processing. Namely, the CPU 121 requests the charging server 13 for the settlement of the price of the license. In response to this request, the charging server 13 executes the settlement processing.

If the user is found not having the content in step S192, then the procedure goes to step S197, in which error handling is executed. Namely, in this case, because the user does not have the content, it is not necessary to get the license. Therefore, error handling is executed. To be more specific, the CPU 121 sends an error message to the personal computer 22. In step S173, the personal computer 22 receives the error message, not the notification of license acquisition.

In response to the access from the Pochara service server 9, the Pochara service server 9 executes the processing indicated by the flowchart shown in FIG. 39.

In step S211, the CPU 121 of the license server 8 determines whether the request for license issuance has been received from the Pochara service server 9. If the request for license issuance is found received, then the procedure goes to step S212, in which the CPU 121 reads the license (the crypto key for decoding encrypted content and the license ID) corresponding to the content ID included in the request from the storage block 128 and sends the license to the Pochara service server 9.

If the request for license issuance is found not made from the Pochara service server 9 in step S211, then the processing of step S212 is not executed.

As described above, having acquired the content and its license, the user is ready for using (or reproducing) the acquired content.

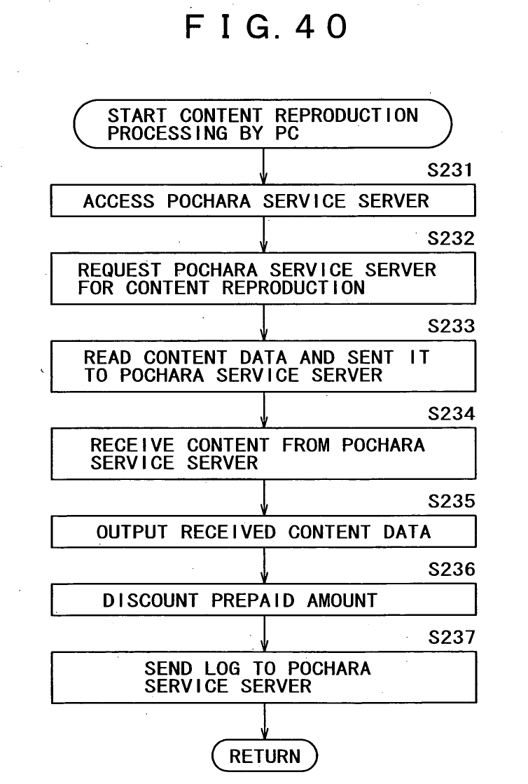

The following describes the processing of this case with reference to the flowchart shown in FIG. 40.

The processing of this case is also executed as one of the processing operations corresponding to the functions selected in step S52 shown in FIG. 13 by mounting the friend Pochara figure 161 on the platform 23.

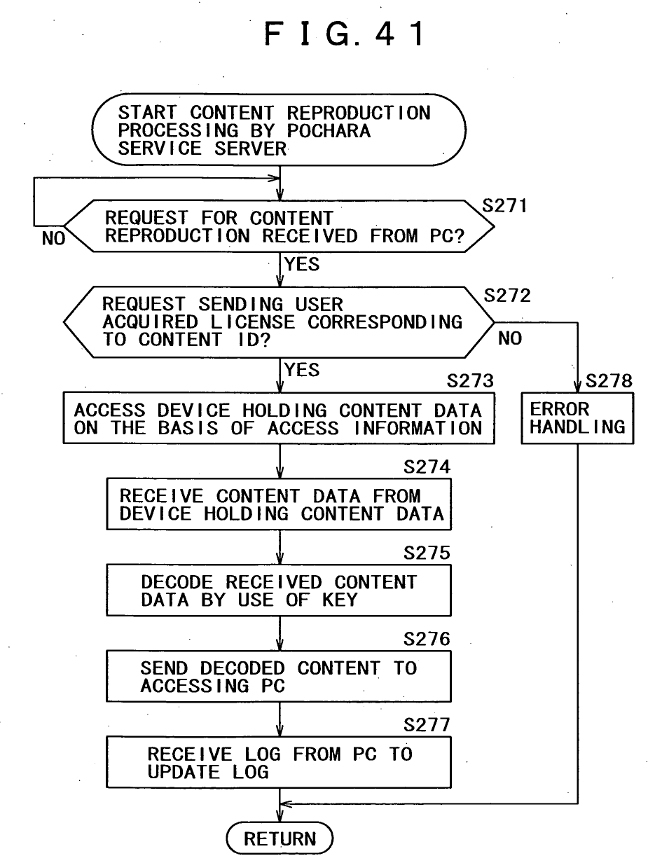

In step S231, the CPU 221 of the personal computer 22 accesses the Pochara service server 9. In step S232, the CPU 221 specifies the content ID to request the Pochara service server 9 for content reproduction. In response to this request, the Pochara service server 9 accesses the access destination holding the content data to get it if the user has the content and its license. In this example, the content data is held in the personal computer 22, so that the Pochara service server 9 requests the personal computer 22 for the transmission of the content data (step S274 shown in FIG. 41 to be described later). Receiving this request in step S233, the CPU 221 reads the content data of the specified access destination and sends the content data to the Pochara service server 9.

The Pochara service server 9 decodes the received encrypted content data by use of the crypto key and sends the decoded content data (step S275 and S276 shown in FIG. 41 to be described later).

In step S234, the CPU 221 receives the content data from the Pochara service server 9. As described above, this content data is already decoded. Therefore, the personal computer 22 need not hold the crypto key and need not execute the decode processing by use of the crypto key. As a result, the reproduction of content becomes easy with mobile devices, such as mobile phones and PDAs (Personal Digital Assistants), on which it is difficult to execute complicated processing due to the importance of mobility.

In step S235, the CPU 221 outputs the content received by the process of step S234 to the display block and speaker of the output block 227. Consequently, the user can view and listen to the content.

Next, in step S236, the CPU 221 executes the processing of reducing the prepaid amount. This processing is executed on the IC chip 171 of the friend Pochara figure 161 in the same manner as on the IC chip 191 of the sale Pochara figure 181.

If the IC chip 171 stores no prepaid amount, this processing is skipped.

In step S237, the CPU 221 sends the reduced prepaid amount and the log including the reproduction count to the Pochara service server 9. On the basis of this log, the Pochara service server 9 updates the Pochara database 10 (step S109 shown in FIG. 29 mentioned above).

In response to the processing indicated by the flowchart shown in FIG. 40 by the personal computer 22, the Pochara service server 9 executes the processing indicated by the flowchart shown in FIG. 41 as one of the processing operations corresponding to the functions selected in step S102 shown in FIG. 28.

In step S271, the CPU 121 of the Pochara service server 9 waits until the request (including the content ID) for content reproduction comes from the personal computer 22. Having receiving this request, the CPU 121 determines whether the requesting user has the license corresponding to the content ID in step S272. This determination can be made by determining whether the license ID is registered on the Pochara database 10 in correspondence with the content ID included in the request sent from the personal computer 22. Obviously, in this case, at least one of the Pochara ID and the user ID was sent from the personal computer 22 in the process of step S43 shown in FIG. 12 and has already been received by the Pochara service server 9 in step S91 of FIG. 28.

If the user has the license for the content ID, then the procedure goes to step S273, in which the CPU 121 accesses the source having the content data on the basis of the access information in step S273. As described with reference to FIG. 34, when the device (in this case, the personal computer 22) had acquired the content data by use of the friend Pochara and stored the acquired content data in its incorporated storage block, this device sent the access information for accessing the content data to the Pochara service server 9 (step S134 shown in FIG. 34) and the Pochara service server 9 registered the received access information on the Pochara database 10 (step S152 shown in FIG. 36). Therefore, the CPU 121 can get the content data on the basis of this access information. To be more specific, in this case, the CPU 121 accesses the personal computer 22 to request the reading of the content data from the storage block 228.

In response to this request, the personal computer 22 reads the content data from the position (the storage block 228 specified by the access destination information) specified by the Pochara service server 9 and sends the content data (step S233 shown in FIG. 40). In step S274, the CPU 121 receives the content data from the device having the content data. In this case, the CPU 121 receives the content data from the personal computer 22 (obviously, if the content data is held in a device other than the accessing personal computer 22, the CPU 121 accesses the device to receive the content data).

In step S275, the CPU 121 decodes the content data received from the personal computer 22 by use of the crypto key. This crypto key is obtained as a license necessary for the reproduction of the content and stored in the Pochara database 10 (step S194 shown in FIG. 38).

Next, in step S276, the CPU 121 sends the content decoded in step S275 to the accessing personal computer 22 (the device at which the friend Pochara character 311 is currently located). As described above, this content data is received by the personal computer 22 and outputted therefrom (steps S234 and S235 shown in FIG. 40).

Thus, storing the crypto key in the Pochara service server 9 prevents the crypto key from getting outside the system, so that there is a low risk for the crypto key to be stolen. As a result, it becomes difficult for the encrypted content to be decoded by the third party, thereby enhancing the security of the system.

Then, when the content reproduction ends, log information comes from the personal computer 22 (step S237 shown in FIG. 40). In step S278, the CPU 121 receives the log from the personal computer 22 to update the information in the Pochara database 10 on the basis of the received log. This log contains the number of times content may be reproduced and the prepaid amount after reduction.

If the license for the content ID is found not acquired by the user who sent the request in step S272, then the procedure goes to step S278, in which the CPU 121 executes error handling (namely, in this case, an error message is sent to the personal computer 22). The personal computer 22 receives this error message instead of the content in step S234 and outputs the received error message to the output block 227 to display it.

It should be noted that, in the above-mentioned configuration, the Pochara service server 9 decodes the encrypted content data. Alternatively, the Pochara service server 9 may send the crypto key to the personal computer 22 to make it decode the encrypted content data.

Thus, the encrypted content data can be downloaded without restriction from content servers via the friend Pochara functioning an agent of the user and the downloaded encrypted content can be copied via the friend Pochara. When content data is copied, its storage location is registered on the Pochara database 10. When the reproduction of the copy is directed, the friend Pochara references the storage location registered on the Pochara database 10 to provides the copy content to the user. Therefore, the user can view the copy content, copy it further to another device, and reproduce in a streaming manner. It should be noted that its reproduction always requires friend Pochara.

It should be noted that encryption of content with different crypto keys every time content is copied or reproduced minimizes the damage caused by a stolen crypto key. This consequently enhances the security of the system.

Logging in the Pochara service server 9 can also be made by entering the ID and password assigned to the user, rather than mounting the friend Pochara figure 161 on the platform 23. In this case, however, a third party may steal the ID and the password to masquerade as the authentic user, thereby accessing the Pochara service server 9. If this happens, when the authentic user (the user having the friend Pochara figure 161) is logging in the Pochara service server 9 from a predetermined device on the network by use of the friend Pochara figure 161, the Pochara service server 9 displays only the silhouette (the black shadow) of the friend Pochara figure 161 to the masquerading user, thereby telling him that the friend Pochara character is being used on another device. Namely, this makes the masquerading user intuitively understand that the access to the Pochara service server 9 is exclusive.

Consequently, the content reproduction by use of the friend Pochara can be executed only on one device on the network, so that the user can comply with the copyright of content without being aware of DRM (Digital Right Management).

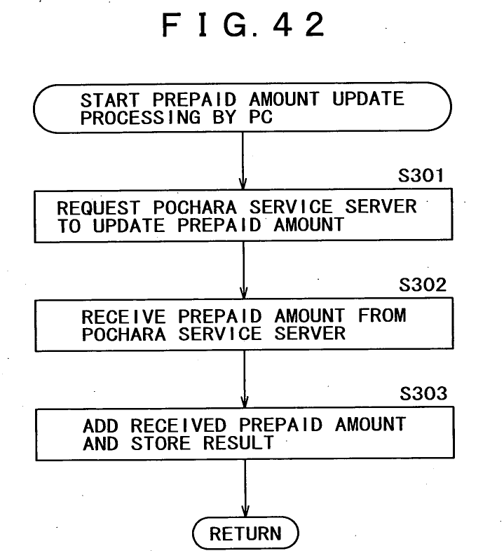

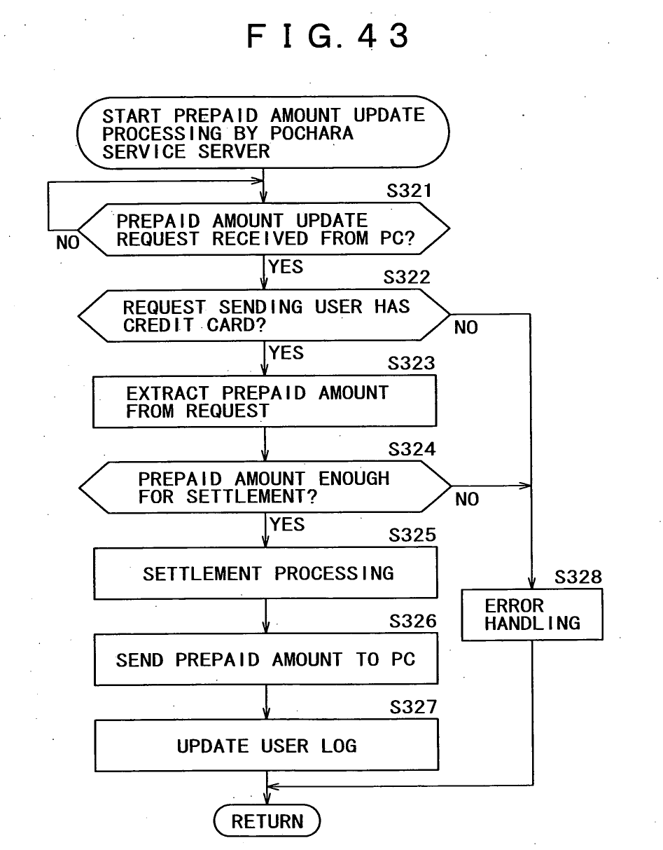

If the prepaid amount (or the reproduction count) is stored in the IC chip 171 of the friend Pochara figure 161 and the stored prepaid amount (or the reproduction count) is reduced every time content is reproduced, the user cannot reproduce (or use) content after the prepaid amount (or the reproduction count) becomes 0 next time. In this case, the user additionally can pay a predetermined amount of money to reproduce content again. The following describes the processing in this case with reference to the flowcharts shown in FIGS. 42 and 43.

The processing indicated by the flowchart shown in FIG. 42 is executed as one of the processing operations corresponding to the functions selected in step S52 shown in FIG. 13.

In step S301, the CPU 221 of personal computer 22 requests the Pochara service server 9 to update the prepaid amount (or the maximum number of times content may be used). In response to this request, the Pochara service server 9 executes the charging processing for the prepaid amount (or the maximum number of times content may be used) and then sends the resultant prepaid amount (or the resultant maximum number of times content may be used) to the personal computer 22 (steps S322 through S326 shown in FIG. 43 to be described later). In step S302, the CPU 221 receives the resultant prepaid amount (or the resultant maximum number of times content may be used). In step S303, the CPU 221 adds the received prepaid amount (or the maximum number of times content may be used) to the prepaid amount (or the maximum number of times content may be used) stored in the IC chip 171 via the reader/writer 241.

Subsequently, the user can reproduce content again within in the range of remaining prepaid amount (or the remaining maximum number of times content may be used).

The Pochara service server 9 executes the processing indicated by the flowchart shown in FIG. 43 in response to the processing by the personal computer 22 indicated by the flowchart shown in FIG. 42.

Namely, this processing is executed as one of the processing operations corresponding to Pochara functions selected in step S102 shown in FIG. 28.

In step S321, the CPU 121 of the Pochara service server 9 waits until a request comes from the personal computer 22 for updating the prepaid amount (or the maximum number of times content may be used). When this request comes, the CPU 121 determines whether the user of this request (the user corresponding to the friend Pochara character 311) uses a credit card in step S322. This determination may be made from the user information registered on the Pochara database 10.

If the user uses a credit card, then the procedure goes to step S323, in which the CPU 121 extracts the prepaid amount (or the maximum number of times content may be used). In step S325, the CPU 121 determines whether the amount of money corresponding to the prepaid amount (or the maximum number of times content may be used) extracted in step S323 is settleable. Namely, the CPU 121 determines whether the prepaid amount is settleable by the credit card. Any amount over a predetermined reference amount is determined to be unsettleable.

If the amount for the prepaid amount is found to be settleable, then the procedure goes to step S325, in which the CPU 121 executes the settlement processing on that amount. Namely, at this moment, the CPU 121 requests the charging server 13 for the charging processing for the prepaid amount. In response to this request, the charging server 13 executes the charging the prepaid amount to the user's account on the basis of the user's credit card number.

Obviously, this processing may be executed as the processing in which the prepaid amount is charged to user's bank account instead of the credit card.

In step S326, the CPU 121 sends the prepaid amount (or the maximum number of times content may be used) to the personal computer 22. As described above, receiving the prepaid amount (or the maximum number of times content may be used), the personal computer 22 updates the prepaid amount (or the maximum number of times content may be used) of the IC chip 171 of the friend Pochara figure 161 (step S303 shown in FIG. 42).

Next, in step S327, the CPU 121 updates the user log. Namely, the prepaid amount (or the maximum number of times content may be used) owned at that moment is registered on the Pochara database 10.

If the user is found not having a credit card in step S322 or if the prepaid amount is found to be unsettleable in step S324, then, the procedure goes to step S328, in which the CPU 121 executes error handling. Namely, at this moment, the CPU 121 sends a message to the personal computer 22, telling that the prepaid amount cannot be updated.

In step S302 shown in FIG. 42, the personal computer 22 receives this message instead of the prepaid amount. Then, the received message is displayed on the display block of the output block 227. Thus, the user knows that the prepaid amount could not be updated.

It should be noted that the processing for increasing (or updating) the prepaid amount may also be executed on the prepaid amount stored in the IC chip 191 of the sale Pochara figure 181.

In the processing of updating the prepaid amount stored in the IC chip 191 of the sale Pochara figure 181, it is practicable to charge to the friend Pochara. This integrates the settlement of accounts into the friend Pochara, thereby enhancing the convenience of charging.

In this case, the user accesses the Pochara service server 9 by mounting the friend Pochara figure 161 on the platform 23, for example. Then, after displaying a menu, the Pochara service server 9 makes the user select from the displayed menu an item “Pay to the sale Pochara figure (Buy coupon)” for example. When this selection is made, the Pochara service server 9 displays message “Mount the Pochara figure to which you pay on the platform” for example onto the personal computer 22. In response to this message, the user dismounts the friend Pochara figure 161 from the platform 23 and mounts the sale Pochara figure 181 instead. It should be noted that, in this case, the Pochara service server 9 continues the access (or keeps the connection) from the corresponding device.

After updating the prepaid amount for the IC chip 191 of the sale Pochara figure 181, the Pochara service server 9 (or the content server 6) displays a message “Mount the friend Pochara figure on the platform” for example again onto the personal computer 22. When the user mounts the friend Pochara figure 161 on the platform 23 in accordance with this message, the Pochara service server 9 executes, on the basis of the friend Pochara figure 161, the charging processing corresponding to the update processing for the prepaid amount executed on the IC chip 191 of the sale Pochara figure 181.

Alternatively, if content cannot be reproduced by means of the sale Pochara figure 181, the Pochara service server 9 displays a message “Do you pay (by a coupon)?” for example onto the personal computer 22. When “OK” button is operated, the Pochara service server 9 displays a message for prompting the user to replace the sale Pochara figure 181 with the friend Pochara figure 161. When the friend Pochara figure 161 is mounted on the platform 23 instead of the sale Pochara figure 181, the Pochara service server 9 executes the charging processing. Subsequently, the Pochara service server 9 displays a message for prompting the user to mount the sale Pochara figure 181 instead of the friend Pochara figure 161. In accordance with this message, the user mounts the sale Pochara figure 181 on the platform 23. At this moment, the processing for updating the prepaid amount is executed, thereby allowing the user to reproduce content again.

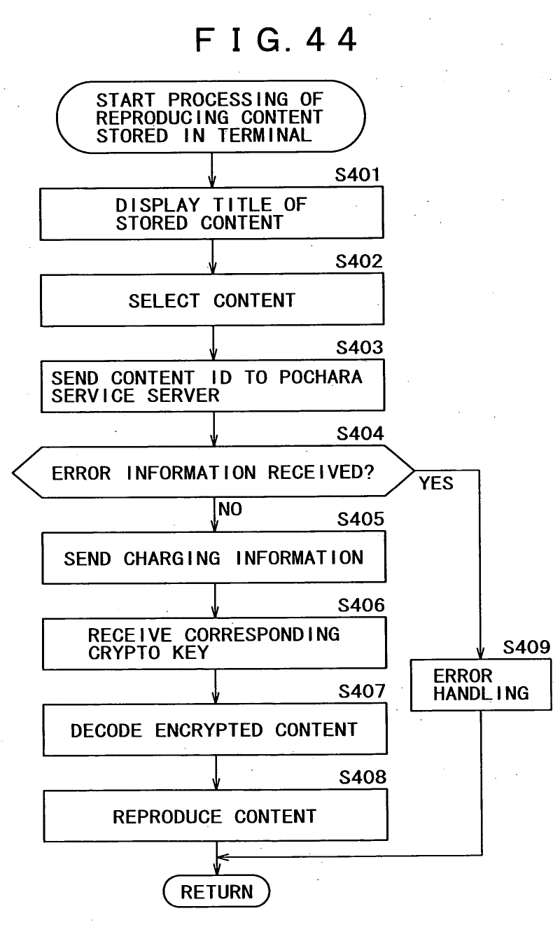

The following describes another processing example for reproducing content stored in a predetermined terminal at that terminal, with reference to the flowchart shown in FIG. 44.

It should be noted that content is assumed to have been stored in the storage block 228 of the personal computer 22 which is a terminal, by the processing indicated by the flowchart shown in FIG. 34 described above for example.

In step S401, the CPU 221 of the personal computer 22 displays the titles (or names) of the stored content onto the display block of the output block 227. Operating the input block 226, the user selects specifies, from among the displayed titles, a predetermined piece of content to be reproduced. In response, the CPU 221 selects the piece of content specified by the user on the basis of the input made through the input block 226 in step S402.

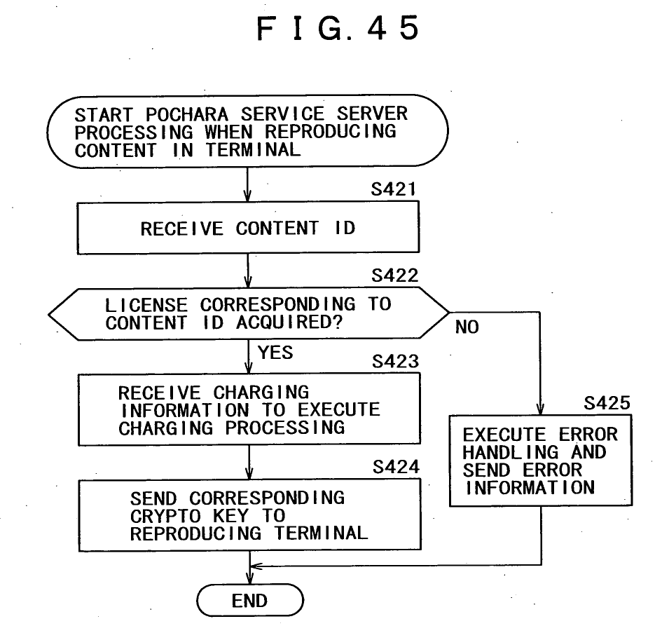

In step S403, the CPU 221 controls the communication block 229 to send the content ID of the content selected in step S402 to the Pochara service server 9. As will be described with reference to FIG. 45, the Pochara service server 9 sends error information (step S425) or a crypto key (step S424) in correspondence with this content ID.

In step S404, the CPU 221 determines whether the error information has been received. If the error information is found received, then the procedure goes to step S409, in which error handling is executed.

If the error information is found not received, then the procedure goes to step S405, in which the CPU 221 gets the charging information necessary for charging processing on the basis of the user input and sends the obtained charging information to the Pochara service server 9.

In step S406, the CPU 221 receives the crypto key (the crypto key sent in step S424) from the Pochara service server 9. In step S407, the CPU 221 decodes the content (encrypted) selected in step S402 by use of the crypto key received in step S406. In step S408, the CPU 221 outputs the content decoded in step S407 to the output block 227.

In response to the above-mentioned processing shown in FIG. 44, the Pochara service server 9 executes the processing indicated by the flowchart shown in FIG. 45.

In step S421, the CPU 121 of the Pochara service server 9 receives the content ID sent from the personal computer 22 (sent in step S403). In step S422, the CPU 121 determines whether the user has the license corresponding to the content ID received in step S421. As described with reference to FIG. 31, the content ID is registered as Pochara information of the friend Pochara and content information and the license ID is registered as license information. On the basis of the Pochara information shown in FIG. 31, the CPU 121 determines whether the license ID is registered in correspondence with the received content ID.

If the license corresponding to the content ID is found acquired in step S422, then the procedure goes to step S423, in which the CPU 121 receives the charging information sent from the personal computer 22 in step S405 to execute charging processing. In step S424, the CPU 121 reads the crypto key corresponding to the license ID and sends the crypto key to the reproducing terminal (in this case, the personal computer 22). As described above, this crypto key is received by the personal computer 22 in step S406.

If the license corresponding to the content ID is found not acquired in step S422, then the procedure goes to step S425, in which the CPU 121 executes error handling. Then, the CPU 121 sends the error information to the personal computer 22.

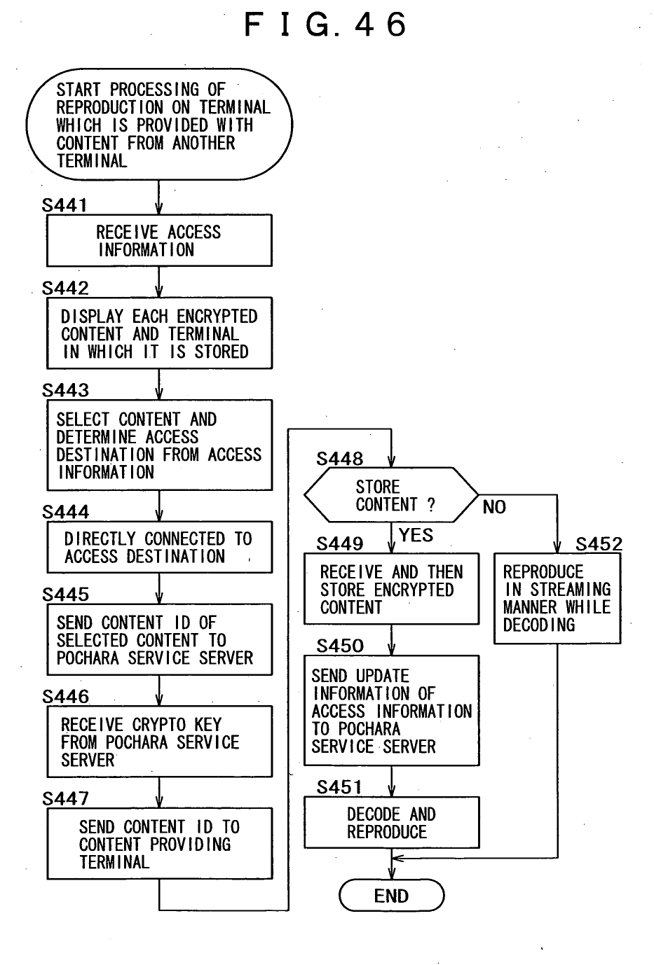

The following describes the processing in which a terminal not storing content reproduces content, with reference to the flowchart shown in FIG. 46.

It is assumed that content be stored in the personal computer 26 and the personal computer 22 reproduce this content.

In step S441, the CPU 221 of the personal computer 22 accesses the Pochara service server 9 to receive the access information of each piece of content registered on the Pochara database 10. As described above, the Pochara database 10 stores the access information as content access destinations (devices holding content). The CPU 221 receives this access information from the Pochara service server 9.

In step S442, the CPU 221 displays a list of encrypted content and terminals in which it is stored, on the basis of the received access information, onto the output block 227. Operating the input block 226, the user selects a predetermined piece of content from among the displayed content. In step S443, the CPU 221 selects the specified piece of content on the basis of the input made through the input block 226 and determines an access destination from the access information of the selected content.

In step S444, the CPU 221 executes the processing of directly connecting to the access destination determined in step S443 by controlling the communication block 229. In this case, the CPU 221 of the personal computer 22 accesses the personal computer 26 in which the content is stored.

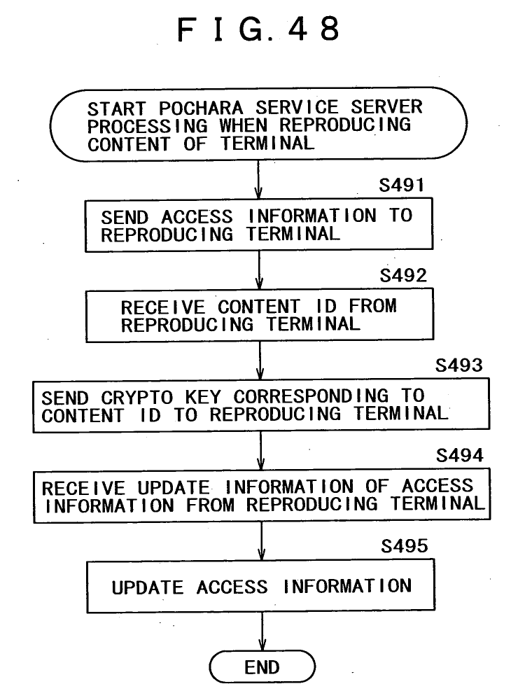

In step S445, the CPU 221 sends the content ID of the content determined (or selected) in step S443 to the Pochara service server 9. As will be described later, the Pochara service server 9 sends back the crypto key corresponding to the content ID (step S493 shown in FIG. 48 to be described later).

In step S446, the CPU 221 receives the crypto key from the Pochara service server 9. In step S447, the CPU 221 sends the content ID to the content providing terminal (in this case, the personal computer 26).

In step S448, the CPU 221 determines whether to store the content. This determination is made on the basis of user input.

If the content is to be stored, the procedure goes to step S449, in which the CPU 221, upon reception of the encrypted content from the personal computer 26, stores it in the storage block 228.

In step S450, the CPU 221 sends the update information of the access information to the Pochara service server 9. Namely, now that the content has been transferred from the personal computer 26 to the personal computer 22, so that the access destination for the content is sent to the Pochara service server 9 such that the subsequent access destination becomes the personal computer 22 (the terminal holding this content becomes the personal computer 22).

In step S451, the CPU 221 decodes the encrypted content stored in the storage block 228 by use of the crypto key received in step S446 to reproduced decoded content. The reproduction output is made through the output block 227.

If the content is not to be stored in step S448, then the CPU 221 decodes the content by use of the crypto key in step S452, reproducing the decoded content through the-output block 227 in a streaming manner.

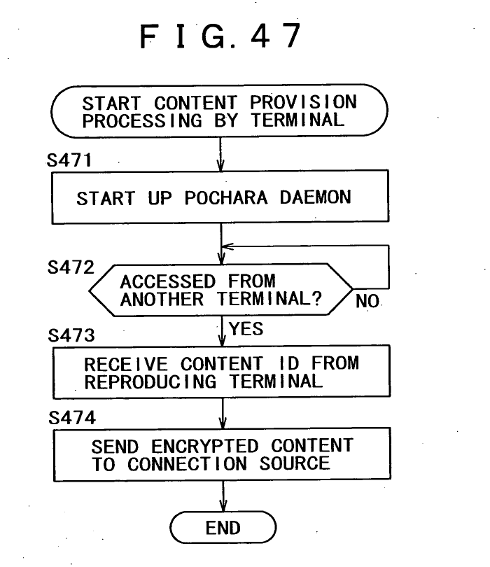

In response to the processing by the personal computer 22 indicated by the flowchart shown in FIG. 46, the personal computer 26 executes the processing indicated by the flowchart shown in FIG. 47.

First, in step S471, the CPU 221 of the personal computer 26 starts up the Pochara daemon. In step S472, the Pochara daemon waits until accessed from another terminal. When an access comes from another terminal, (in this case the access comes, from the personal computer 22), the procedure goes to step S473, in which the content ID is received from the reproducing terminal. In this case, the content ID sent by the personal computer 22 in step S447 is received. In step S474, the CPU 221 of the personal computer 26 sends the encrypted content to the connection source. In this case, the encrypted content is sent to the personal computer 22.

As described above, this encrypted content is stored in the personal computer 22 in step S449 or decoded to be reproduced in a streaming manner in step S452.

The following describes the processing by the Pochara service server 9 to be executed in response to the processing by the personal computer 22 shown in FIG. 46, with reference to FIG. 48.

In step S491, the CPU 121 of the Pochara service server 9 sends access information to a reproducing terminal. Namely, the CPU 121 reads the access information from the Pochara database 10 and sends it to the personal computer 22. As described above, the personal computer 22 receives this access information in step S441.

In step S492, the CPU 121 of the Pochara service server 9 receives the content ID from the reproducing terminal (in this case, the personal computer 22). This content ID is one that was sent from the personal computer 22 in step S445 shown in FIG. 46.

In step S493, the CPU 121 receives the update information of the access information from the reproducing terminal. This update information is one that was sent from the personal computer 22 in step S450 shown in FIG. 46.

In step S495, the CPU 121 registers (or updates) the access information received in step S494 onto the Pochara database 10. Thus, the content has been transferred, so that the access destination of the content registered as the personal computer 26 is changed to the personal computer 22.

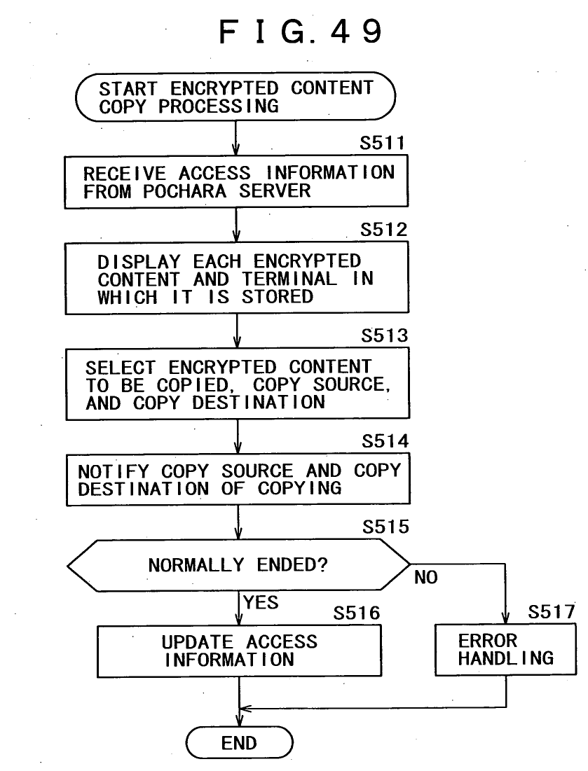

The following describes the processing of copying encrypted content to another device with reference to the flowchart shown in FIG. 49. For example, it is assumed here that the content held in the personal computer 26 be copied to the personal computer 52.

In step S511, the CPU 221 of the personal computer 22 receives access information from the Pochara service server 9. In step S512, on the basis of the access information received in step S511, the CPU 221 outputs a list of encrypted content and terminal in which it is stored onto the output block 227, displaying the list.

Checking the display list, the user specifies the copy source and the copy destination by operating the input block 226.

In step S513, on the basis of the input made through the 226, the CPU 221 selects the encrypted content to be copied and, at the same time, selects the personal computer 26 as the copy source and the personal computer 52 as the copy destination. In step S514, the CPU 221 notifies the copy source and the copy destination of a copy operation to be executed. In this case, because the copy source is the personal computer 26 and the copy destination is the personal computer 52, the notification of a copy operation is sent to both the computers.

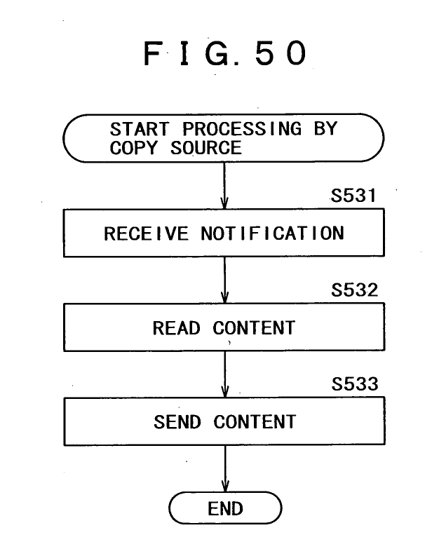

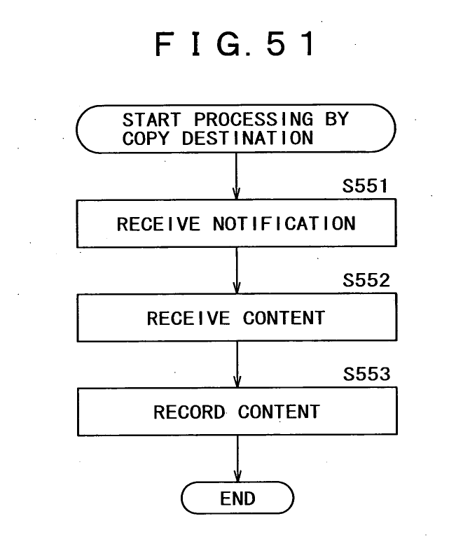

On the basis of this notification, the content is transferred from the copy source to the copy destination to be copied as will be described with reference to the flowcharts shown in FIGS. 50 and 51.

In step S515, the CPU 221 of the personal computer 22 determines whether the copy operation has been normally completed on the basis of a notification from the copy source or the copy destination. If the copy operation is found normally completed, then the procedure goes to step S516, in which the CPU 221 updates the access information. Namely, in this case, because the content has been stored in both personal computers, both the personal computer 26 and the personal computer 52 are registered as access destinations.

If the copy operation is found not normally completed in step S515, then the procedure goes to step S517, in which the CPU 221 executes error handling.

The following describes the processing by the copy source with reference to the flowchart shown in FIG. 50. This processing is executed by the personal computer 26.

In step S531, the CPU 221 of the personal computer 26 receives the notification of a copy operation (or a copy request) issued in step S514 from the personal computer 22. In response, the CPU 221 of the personal computer 26 reads the content from the storage block 228 and sends it to the personal computer 52 through the communication block 229 in step S533. When the transmission has been normally completed, the CPU 221 notifies the personal computer 22 thereof.

FIG. 51 shows the processing by the copy destination to be executed in response to the processing by the copy source. In this case, this processing of the copy destination is executed by the personal computer 52.

In step S551, the personal computer 52 receives the notification of a copy operation (or copy request) issued by the personal computer 22 in step S514. In step S552, the CPU 221 of the personal computer 52 receives the content sent from the personal computer 26 as the copy source in step S33. In step S553, the CPU 221 of the personal computer 52 records the content received in step S552 to the storage block 228. When the reception has been normally completed, the CPU 221 notifies the personal computer 22 thereof.

In the above-mentioned configuration, each processing is executed by mounting the friend Pochara figure 161 or the sale Pochara figure 181 on the platform 23 connected to the personal computer 22 in the room 31 by the user. The present invention is not restricted to this configuration. For example, the user may mount a Pochara figure on the platform connected to any device that the user wants to use. For example, if the function for controlling a television receiver is added in correspondence with the friend Pochara character 311, the user may mount the friend Pochara figure 161 on the platform 25 connected to the television receiver 24 arranged in the room 32 to control the television receiver 24.

Also, for example, it is practicable to mount the friend Pochara figure 161 on the platform 23 to use, in the room 33, the content recorded to the personal computer 22. In this case, the user mounts the friend Pochara figure 161 on the platform 27 connected to the personal computer 26 arranged in the room 33. At this moment, the Pochara service server 9, which accessed from the personal computer 26, reads the content data from the personal computer 22, decodes the content data, and sends the decoded content data to the personal computer 26. Therefore, the user can use content at any desired locations (by mounting the friend Pochara figure 161 on the platform connected to any device that the user wants to use).

For example, if the user brings the friend Pochara figure 161 to the office 5 and mounts it on the platform 53 connected to the personal computer 52 in the office 5, the personal computer 52 connects to the Internet 1 from the LAN 51 via the ISP 4 and to the Pochara service server 9. Therefore, the user can read the mail sent to his home also at the office 5. Obviously, the user can send mail from the office 5.

Thus, by bringing the friend Pochara figure 161 and mounting it on the platform connected to a device that the user wants to use, the user can get the provision of services associated with friend Pochara functioning as his agent from that device. That device may be the cellular phone 61 for example shown in FIG. 1.

It should be noted however that no platform is connected to the cellular phone 61 and it contains a reader/writer. Therefore, by arranging the friend Pochara figure 161 in the proximity of the cellular phone 61 (or by making the friend Pochara figure 161 contact with the cellular phone 61), the user can access the Pochara service server 9.

Because no platform is connected to the cellular phone 61, the friend Pochara figure 161 cannot be mounted always on the platform. Hence, when access is made from the cellular phone 61 to the Pochara service server 9, the Pochara service server 9 is accessed (or logged in) when the friend Pochara figure 161 is arranged in the proximity of the cellular phone 61; subsequently, if the friend Pochara figure 161 is brought away from the proximity of the cellular phone 61, the access (or connection) to the Pochara service server 9 is kept on.

In a logout sequence, the user displays a menu by appropriately operating buttons of the cellular phone 61, selects an logout item from the displayed menu, and gives a logout command. When this operation is executed, the logout from the Pochara service server 9 is effected.

In the use of the sale Pochara figure 181, the user also arranges the sale Pochara figure 181 in the proximity of the cellular phone 61 (makes the sale Pochara figure 181 contact with the cellular phone 61). In this case, once access (or login) has been made, the access (or connection) is also kept on until the user gives a logout command from the menu.

The CPU incorporated in the cellular phone 61 is generally lower in performance than that used in personal computers, so that the resolution, the number of colors, the number of polygons, and the number of frames for displaying the friend Pochara and sale Pochara characters are each converted to a simple format.

Pochara data may be expressed in XML-base data for example. In addition, it is practicable to display characters by use of Java (trademark). It is still practicable to display characters by use of the i-mode.

If the user carries the friend Pochara figure 161 along with the cellular phone 61, a too large friend Pochara figure 161 hampers the mobility. To circumvent this problem, the size of the friend Pochara figure 161 may be reduced to that of a key that may be held with a key holder for example. The friend Pochara figure 161 of this size may be attached to the strap of the cellular phone 61 like an accessory.

Since the IC chip can be downsized, it is accommodated in the miniaturized friend Pochara figure 161 which can be attached to the strap of the cellular phone 61.

In addition to mobile phones, it is also practicable to access the Pochara service server 9 from PDA, digital still camera, camcorder, video tape recorder, DVD recorder, hard disk recorder, car navigator, or computer game machine, for example.

In the above-mentioned descriptions, the use of content is mainly explained. The friend Pochara which functions as the agent of the user analyzes the user's preferences to generate the recommendation information described with reference to FIG. 31, thereby getting the content preferred by the user from various servers connected to the Internet 1 without waiting for the commands by the user. Consequently, the user can get the recommendation information via the friend Pochara. When a command comes for viewing the recommendation information, the friend Pochara displays the sale Pochara which introduces the content retrieved so far by the friend Pochara. The user can get the presentation of the content retrieved so far as the recommendation information via this sale Pochara. Namely, in this case, a sale Pochara is displayed without the intermediary of the sale Pochara figure 181.

This also holds true when the user accesses the portal site of sale Pochara. In these cases, charging is executed not through the sale Pochara but through the friend Pochara.

In addition, the Pochara ID of sale Pochara may be added to a bookmark to register it as the preference information described with reference to FIG. 31 for example, thereby speeding up the access to the URL of the sale Pochara.

In the above-mentioned configuration, the friend Pochara figure 161 and sale Pochara figure 181 are dolls in appearance; alternatively, they may have a shape of animal, building, or other objects.

Further, for variations to the sale Pochara figure, cover jackets of Compact Disc (CD) and DVD (Digital Versatile Disc) may be used as objects.

In this case, an IC chip is incorporated in each cover jacket (or object). Therefore, when the cover jacket is mounted on the platform, the sale Pochara character corresponding to that cover jacket is displayed on the device connected to the platform. If the cover jacket is that of a CD, the sale Pochara in this case is the character of the singer of songs recorded to the CD as content.

This sale Pochara character has a conversation with the user or introduces the home page of the corresponding singer, for example, in a mimicry manner.

Alternatively, on the basis of a coupon recorded to the IC chip accommodated in the cover jacket, the sale Pochara character lets the user preview the latest release (content) of that singer. This IC chip also stores the explanation of the content recorded to the CD and the singer's promotion information for example, which are introduced by the sale Pochara.

Still alternatively, if the cover jacket is that of a DVD, the hero character of the movie contained in the DVD appears as the sale Pochara. The IC chip of that cover jacket stores the detail information about the production of the movie and coupons for example. On the basis of these coupons, the sale Pochara sells the goods associated with the movie.

Making an object have user identification information and displaying an image corresponding to that object onto the display block allow the user to intuitively recognize the relationship between himself/herself and the object, thereby preventing the possibility of erroneously using the objects of other users.

If user identification information is managed and the user identification information sent from another information processing apparatus is received, the received user identification information can be authenticated on the basis of the managed user identification information. On the basis of an authentication result, the display information necessary for another information processing apparatus to display an image corresponding to the user identification information can be sent via a network, thereby easily and surely identify the user of this another information processing apparatus.

The user can surely authenticate himself/herself by sending the acquired user identification information to another information processing apparatus via a network, receiving the authentication result from that another information processing apparatus on the basis of that user identification information, and displaying the image corresponding to the user identification information on the basis of the authentication result.

Incorporating a memory in the figure, storing user identification memory into the memory, and shaping that figure into one corresponding to the image to be displayed allow the user to surely execute authentication processing by means of that figure.

A system capable of delivering content to each user more effectively can be realized by distributing objects in which object identification information is stored, getting the content information corresponding to the object identification information when it has been received via a network, and sending the content corresponding to the content identification information via the network.

Content can be securely provided to each user and the payment for the provided content can be surely collected by sending a notification based on the object identification information received from second another information processing apparatus to first another information processing apparatus to execute charging processing on the user of second another information processing apparatus.

By acquiring the content identification information stored in each object, sending the content identification information to another information processing apparatus via a network, receiving the corresponding content, and outputting the received content, the corresponding content can be surely used only by acquiring the object.

Storing figure identification information in the memory incorporated in a figure and shaping this figure into one that corresponds to the image associated with content allow the effective delivery of the content to each user.

Storing content identification information in the memory incorporated in a figure and providing this figure with the characteristics corresponding to the image associated with the content allow the user to better enjoy the content.

As described above, the user can use contents of audio data, video data and the like by use of the friend Pochara figure 161 and the sale Pochara figure 181 and receive various services as well.

Further, the user can call up a Pochara for music selection (hereafter appropriately referred to as a music selection Pochara) which selects optimum music content in accordance with user's preference and feelings at that moment and provides the selected content to the device operated by the user, thereby allowing the user to use the selected music content (the content associated with the music selection Pochara).

To be more specific, this function is executed as one of the functions of the friend Pochara character 311 shown in FIG. 20, in which, when the user directs, through the input block 226, the friend Pochara character 311 to call the music selection Pochara, the character of the music selection Pochara appears on the screen. Then, the music contented selected by the music selection Pochara is downloaded from the content server to be reproduced or reproduced in a streaming manner.

For example, music content (the music content selected by the music selection Pochara called by the personal computer 22) is provided to the personal computer 22 by the above-mentioned processing executed by the personal computer 22, the content server 7, and the Pochara service server 9 shown in FIGS. 34 through 36. As will be detailed later, the information about the access destination for music content is selected by the music selection Pochara (by the Pochara service server 9) and the content source is accessed on the basis of the selected information.

Besides, the license corresponding to the provided music content is provided to the personal computer 22 by the processing by the personal computer 22, the Pochara service server 9, and the license server 8 shown in FIGS. 37 through 39 and the provided music content is reproduced by the processing shown in FIGS. 40 and 41.

When the reproduction of the music content has been completed and the end of the selection by the music selection Pochara is directed, the charging processing by the personal computer 22 and the Pochara service server 9 is executed to charge the payment for the music content used by the user.

Consequently, the -user can easily use music content only by executing a simple operation of calling the music selection Pochara without executing a content acquisition operation or the corresponding license acquisition operation.

Like other sale Pocharas, the information about the music selection Pochara is provided from the device of the provider of music selection Pochara (for example, a device having the same configuration as the Pochara service server 9) (hereafter appropriately referred as a music selection Pochara provider device) connected to the Internet 1 for example and the provided information is managed by the Pochara database 10.

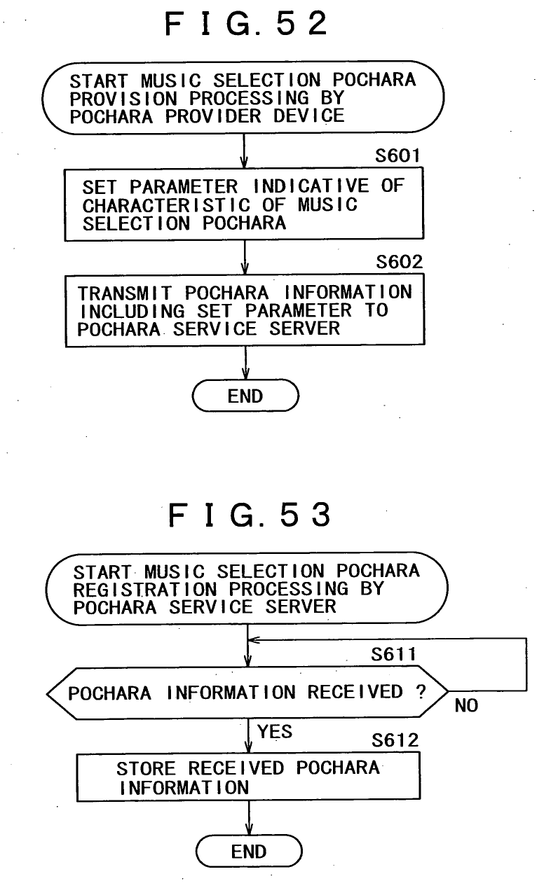

First, with reference to the flowchart shown in FIG. 52, the processing by the music selection Pochara provider device which provides the music selection Pochara.

In step S601, the CPU 121 of the music selection Pochara provider device sets parameters indicative of the feature of the music selection Pochara in response to the input made by the user (the provider of the music selection Pochara). These parameters include parameters indicative of the age group of the user corresponding to that music selection Pochara, the field of music which that music selection Pochara is good at, and the identification information (ID) of that music selection Pochara, for example.

In step S602, the CPU 121 controls the communication block 129 to transmit the Pochara information including the parameters set in step S601 to the Pochara service server 9. The Pochara information to be transmitted also includes the information about the provider of the music selection Pochara and the image data of the music selection Pochara to be displayed on the device of the user who has called that music selection Pochara. The information about the provider of the music selection Pochara includes the information such as the name and address of the user who registered the music selection Pochara.

The following describes the music selection Pochara registration processing by the Pochara service server 9 which is executed in correspondence with the processing shown in FIG. 52, with reference to the flowchart shown in FIG. 53.

In step S611, the CPU 121 of the Pochara service server 9 determines whether the Pochara information of the music selection Pochara has been transmitted from the music selection Pochara provider device and waits until this information is transmitted.

If the Pochara information is found transmitted from the music selection Pochara provider device in step S611, then the procedure goes to step S612, in which the CPU 121 receives the transmitted information and stores it into the Pochara database 10.

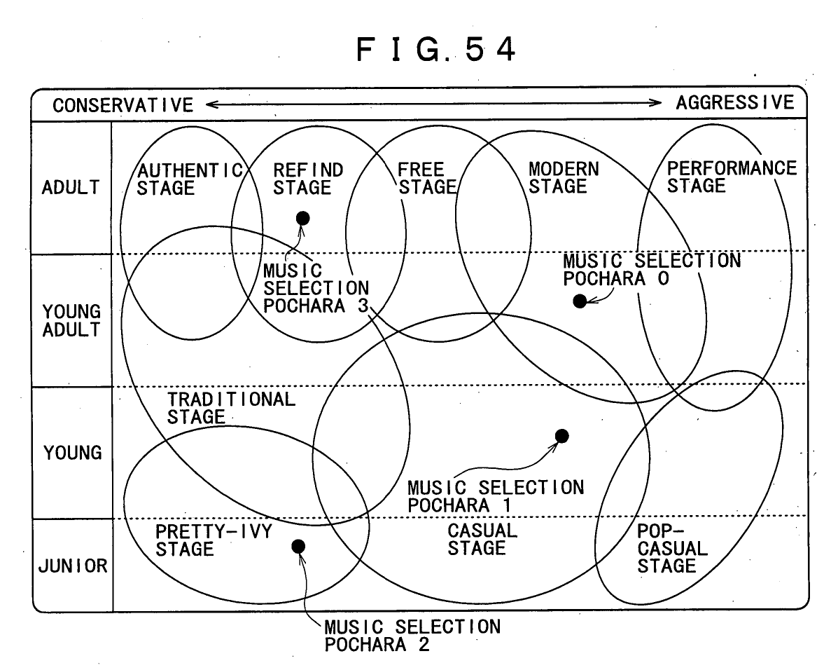

In the Pochara database 10, the music selection Pocharas (the information about the music selection Pochara) provided by the music selection Pochara provider device are classified as shown in FIG. 54 for example and registered.

The horizontal axis shown in FIG. 54 indicates the character of the user of each music selection Pochara, “conservative” toward the left and “aggressive” toward the right. That is, the “aggressive” value goes up toward the right and “Conservative” value goes up toward the left. The vertical axis shown in FIG. 54 indicates the age groups of user of music selection Pocharas; namely, “adult”, “young adult”, “young”, and “junior” from top to down.

In accordance with the parameters set by the music selection Pochara provider, each music selection Pochara is arranged at predetermined position in the coordinates shown in FIG. 54. The features of the music selection Pocharas arranged as shown in FIG. 54 are matched through collaborative filtering for example with the feature of the user requesting the provision of a music selection Pochara, thereby providing (or introducing) the music selection Pochara having the feature which is nearest to the feature of the user.

In the example shown in FIG. 54, the feature of “music selection Pochara 0” is arranged at a position slightly toward “aggressive” from the center and in “young adult” age group and the feature of “music selection Pochara 1” is arranged at a position slightly “aggressive” from the center and in “young” age group. The “conservative” from the center and in “junior” age group and the feature of “music selection Pochara 3” is arranged at a position toward “conservative” from the center and in “adult” age group.

Therefore, on the basis of the use log of a friend Pochara, to the user who is determined by the Pochara service server 9 to be slightly “aggressive” from the average and belongs to “young adult” age group, the “music selection Pochara 0” of which feature is set to the proximity of the feature of the user is selected and provided to that user.

It should be noted that, in the coordinates shown in FIG. 54, the features of music selection Pocharas and the features of users who use them are classified into 9 stages.

Referring to FIG. 54, “AUTHENTIC STAGE” is set to a range in which most “conservative” users belonging to “adult” age group fall. “REFIND STAGE” is set to a range partially overlapping “AUTHENTIC STAGE” and slightly offset toward the right. “FREE STAGE” is set to a range partially overlapping “REFIND STAGE” and slightly offset toward the right.

“MODERN STAGE” to which users of “young adult” age group also belong is set to a range partially overlapping “FREE STAGE” and slightly offset toward the right. “PERFORMANCE STAGE” is set to a range partially overlapping “MODERN STAGE” and slightly offset toward the right. “TRADITIONAL STAGE” is set to a range to which users of “AUTHENTIC STAGE” but belonging to lower age groups belong. “PRETTY-IVY STAGE” is set to a range to which users of “conservative” and the lowest age group belong. “CASUAL STAGE” is set to a range to the right of “PRETTY-IVY STAGE) to which users belong to “young adult” and “junior” belong. “POP-CASUAL STAGE” is set to a range to which “aggressive” and youngest users belong.

In matching user feature information with music selection Pochara feature information, the above-mentioned stages are appropriately taken into consideration.

The above-mentioned matching based on user's feelings for example is detailed in “EMOTIONAL PROGRAM” written by Naoki Sakai and published by Water Studio Co., Ltd. It should be noted that, in the example shown in FIG. 54, the features of music selection Pocharas 0 through 3; actually however, the features of more music selection Pocharas are displayed.

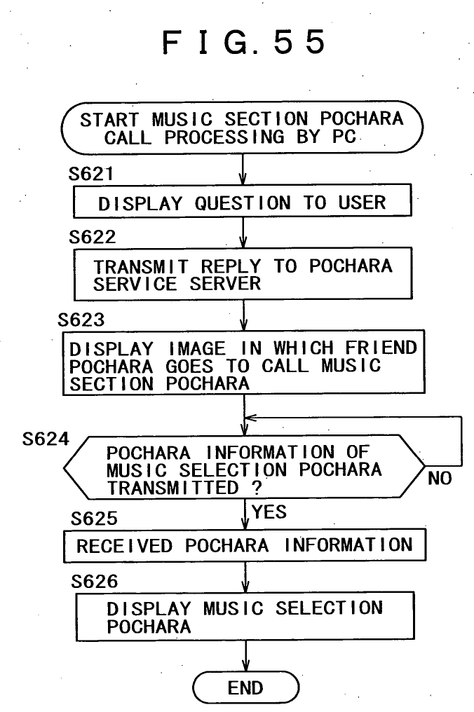

The following describes the calling of a music selection Pochara in response to a user request, which is the processing by the personal computer 22 for example, with reference to the flowchart shown in FIG. 55.

When a predetermined operation is executed on the menu screen shown in FIG. 20 to direct the calling of a music selection Pochara, the CPU 221 of the personal computer 22 displays a question to the user in step S621. On the basis of the reply by the user to this question, the Pochara service server 9 determines the feeling of the user of the computer 22 at that moment. Namely, as will be described later, the information indicative of a reply by the user to the question is transmitted from the personal computer 22 to the Pochara service server 9.

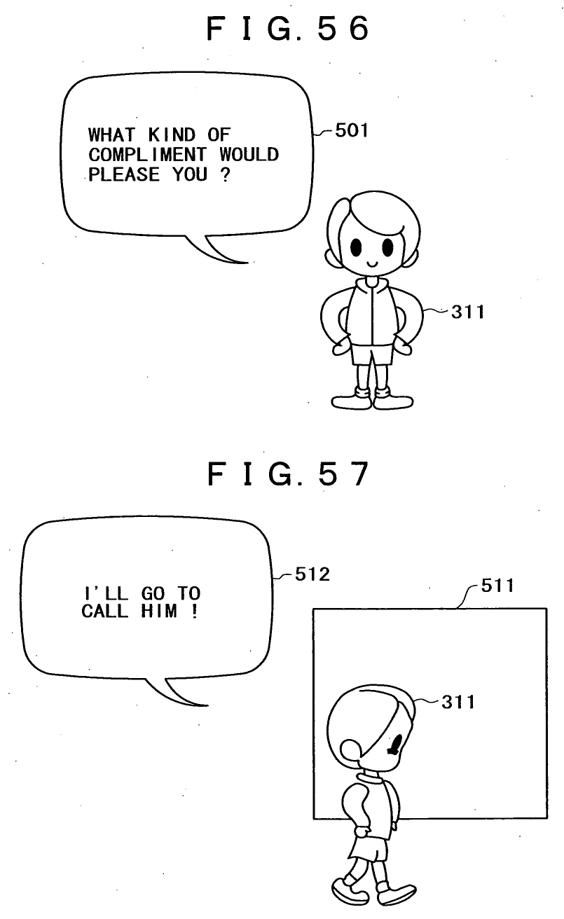

FIG. 56 shows an exemplary display of a screen in which the friend Pochara character 311 is asking a question to the user. For the sake of description, the image shown in FIG. 56 is enlarged as compared with the friend Pochara character 311 shown in FIG. 20; actually, the image shown in FIG. 56 is displayed at approximately the center of the display block of the output block 227 with other icons for example as shown in FIGS. 20 through 26. It should be noted that the images shown in FIGS. 57, 58, and 63 through 65 are also displayed by enlarging the image displayed on the display block of the output block 227.

In the example shown in FIG. 56, a question “What kind of compliment would please you?” is shown in a balloon 501 of the friend Pochara character 311. Likewise, questions “What kind of restaurants do you want to dine at?”, “What kind of packaged tours do you like?”, and so on are sequentially displayed in the balloon 501 of the friend Pochara character 311. The user answers these questions by selecting predetermined replies from among options displayed after the questions asked by the friend Pochara character 311.

When the reply to each question is entered by the user, the CPU 221 controls the communication block 229 in step S622 to transmit the user's reply to the question to the Pochara service server 9, upon which the procedure goes to step S623, in which the friend Pochara character 311 which goes to call a music selection Pochara is displayed.

FIG. 57 shows an exemplary display of the friend Pochara character 311 which goes to call a music selection Pochara. As shown in FIG. 57, message “I'll go to call him!” is displayed in a balloon 512 of the friend Pochara character 311. Also, an image in which the friend Pochara character 311 disappears from an exit 511 shown in front of the friend Pochara character 311 is displayed.

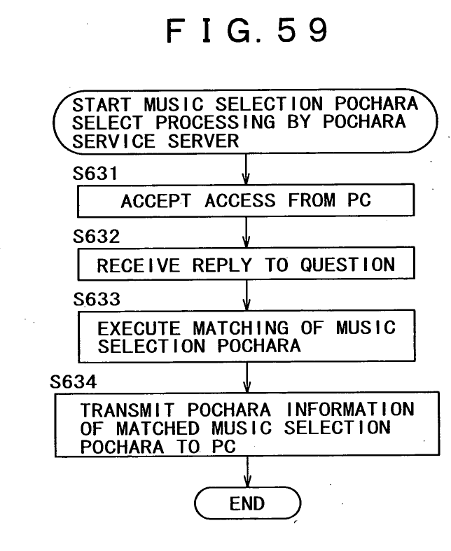

As will be detailed later, in the Pochara service server 9, the feeling of the user at that moment is determined on the basis of the reply entered by the user to each question and, on the basis of the determined feeling and the user's feature information, an optimum music selection Pochara is selected (step S633 shown in FIG. 59). Then, the Pochara information including the image data of the selected music selection Pochara is transmitted from the Pochara service server 9 to the personal computer 22 (step S634 shown in FIG. 59).

In step S624, the CPU 221 determines whether the Pochara information of the music selection Pochara has been transmitted and waits until it has been transmitted. If the Pochara information is found transmitted in step S624, then the procedure goes to step S625, in which the CPU 221 controls the communication block 229 to received the Pochara information.

In step S626, the CPU 221 displays the image of the music selection Pochara character selected by the Pochara service server 9 onto the display block of the output block 227.

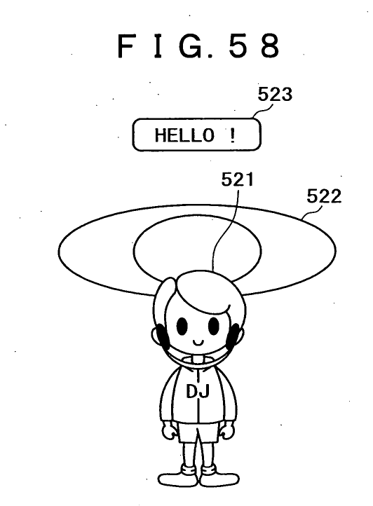

FIG. 58 shows an exemplary display of a screen on which the music selection Pochara character selected by the Pochara service server 9 appears on the display block of the output block 227.

An disk-shaped entrance 522 is displayed first and then a music selection Pochara character 521 emerges through this entrance. When the music selection Pochara character 521 has appeared, message “Hello!” in a balloon 523 is displayed.

Thus, a music selection Pochara is called to the screen of the personal computer 22 of the user to which music content is provided.

The following describes, with reference to the flowchart shown in FIG. 59, the music selection Pochara select processing by the Pochara service server 9 which is executed in response to the processing shown in FIG. 55.

In step S631, the CPU 121 of the Pochara service server 9 accepts access from the personal computer 22, upon which the procedure goes to step S632, in which a reply to each question (the question displayed by the friend Pochara character 311 of the personal computer 22 as shown in FIG. 56) is received. In the personal computer 22, the reply to the question entered by the user has been transmitted (step S622 shown in FIG. 55).

In step S633, on the basis of the reply received from the personal computer 22, the CPU 121 references the feature information of the music selection Pochara stored in the Pochara database 10 to execute a matching between the music selection Pochara and the user.

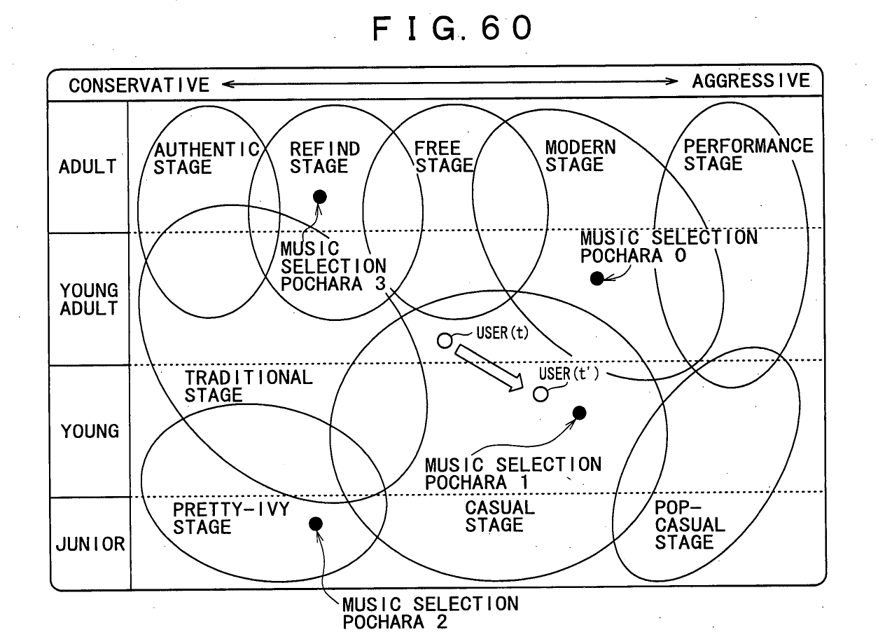

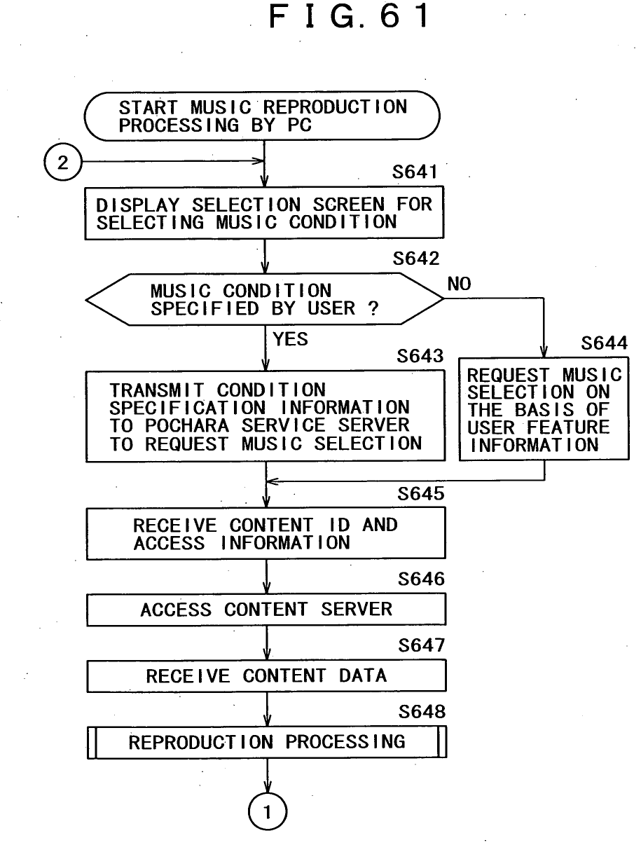

FIG. 60 shows an example of the matching to be executed by the CPU 121 of the Pochara service server 9.

For example, if the features of the music selection Pocharas 0 through 3 are set as shown in FIG. 60 (like FIG. 54) and, on the other and, the feature of the user of the personal computer 22 set on the basis of the use log of friend Pochara and sale Pochara is positioned at approximately the center of the coordinates, the position of the feature of the user is moved as indicated with an white arrow.

For example, in FIG. 60, on the basis of the reply made by the user to the question “What kind of compliment would please you?”, the feature of the user moves from the position (approximately the center of the coordinates) to a position (toward the lower right from the center) indicative of a feature of the younger age group and the more aggressive stage. Namely, the feature of the user is updated by use of the user feeling as a parameter represented by the reply to the question.

It should be noted that the circle indicated by “user (t)” represents the position of the user feature at time t and the circle indicated by “user (t′)” represents the position of the user feature at time t′. Time t′ is later than time t.

In the example shown in FIG. 60, the feature of the music selection Pochara 1 is set in the proximity of the position (the position of “user (t′)”) of the moved user feature. In this case, the “music selection Pochara 1” is selected as the optimum music selection Pochara for the user of the personal computer 22.

Referring to FIG. 59 again, in step S634, the CPU 121 reads the Pochara information of the music selection Pochara selected by the matching in step S633 from the Pochara database 10 and transmits the Pochara information to the personal computer 22. This Pochara information includes the image data and feature information of the music selection Pochara selected by the matching. On the basis of these image data and feature information, the music selection Pochara is displayed on the screen of the personal computer 22.

By the above-mentioned processing, the optimum Pochara based on the user preference and feeling is selected to be provided to each user.

The following describes the music reproduction processing by the personal computer 22 for reproducing the music selected by the music selection Pochara, with reference to the flowchart shown in FIG. 61.

In step S641, the CPU 221 displays, on the display block of the output block 227, a selection screen for selecting the conditions of the music to be reproduced.

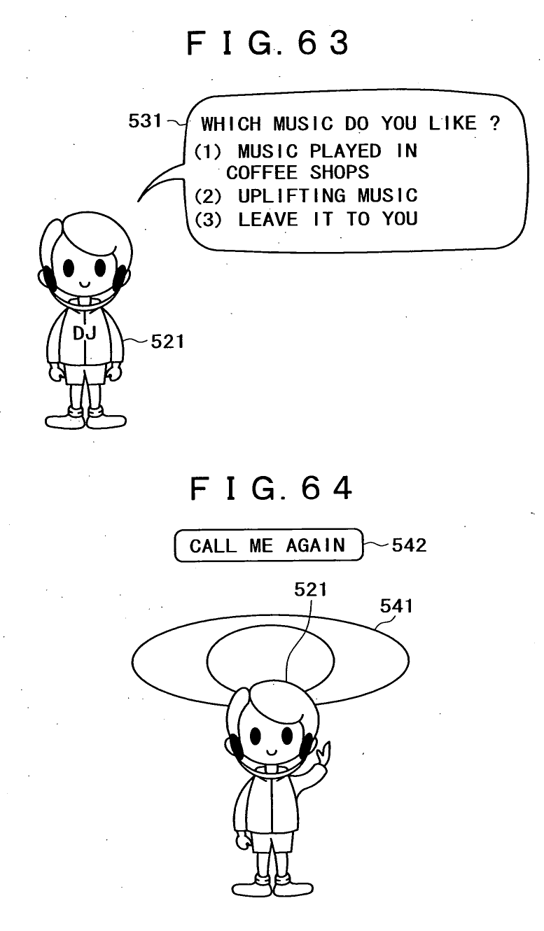

FIG. 63 shows an exemplary display of the music condition selection screen.

In the example shown in FIG. 63, message “Which music do you like?” is displayed in a balloon 531 of the music selection Pochara character 521, below which “Music played in coffee shops” is displayed as a first option, “Uplifting music” as a second option, and “Leave it to you” as a third option. In response to these options, the user can specify the condition of the music to be selected, by operating the mouse of the input block 226.

In step S642, the CPU 221 determines whether a music condition has been specified by the user. If the first option “Music played in coffee shops” displayed in the balloon 531 shown in FIG. 63 is found specified for example, then the procedure goes to step S643, in which the CPU 221 transmits the condition specification information including the information about the selected condition to the Pochara service server 9, thereby requesting it for music selection.

On the other hand, if the third option “Leave it to you” displayed in the. balloon 531 is found selected on the selection screen shown in FIG. 63 for example or if a predetermined period of time has passed without user's selecting a condition, then the CPU 221 determines in step S642 that no condition has been specified, upon which the procedure goes to step S644, in which the CPU 221 requests the Pochara service server 9 for the music selection based on the user feature.

In response to the processing request in step S643 or in response to the request made by the processing of step S644, the Pochara service server 9 selects music content on the basis of the feature of music selection Pochara and the user feature information. Then, the selected music content is provided to the personal computer 22 by basically the same processing as described with reference to FIG. 34.

To be more specific, the CPU 221 of the personal computer 22 receives the content ID of the selected music content and the address information including the address of the content server which provides that music content from the Pochara service server 9. It should be noted that, in FIG. 34, the address information and so on entered by the user are transmitted to the Pochara service server 9 (step S134 shown in FIG. 34); in the processing shown in FIG. 61, this transmission is not executed because the address information is selected and transmitted by the Pochara service server 9.

In step S646, the CPU 221 accesses the content server providing the music content selected by the Pochara service server 9 (the music selection Pochara) on the basis of the address information received from the Pochara service server 9 and notifies this content server of the content ID.

When the content ID comes from the personal computer 22, the content server reads the music content with this ID set and transmits this music content to the personal computer 22 via the Internet 1 or the like.

In step S647, the CPU 221 of the personal computer 22 receives the content data of the music content transmitted from the content server, upon which the procedure goes to step S648, in which the received content data is reproduced. To be more specific, in step S648, the license corresponding to the music content is provided to the personal computer 22 by the same processing as described above with reference to FIG. 37 and the music content is reproduced by basically the same processing (except for the charging processing of step S236) as described above with reference to FIG. 40.

Consequently, the user can use the music selected by the music selection Pochara on the basis of user's feeling and preference, namely the music optimum to the user, merely by executing a simple operation of replying to questions. It should be noted that, as the number of pieces of music content increases, it becomes difficult to search for the optimum music; however, the above-mentioned novel configuration allows the user to search for the optimum music easily and quickly by use of the music selection Pochara.

It should be noted that, while music (or music content) is reproduced, the image of the music selection Pochara character 521 performing that music or the image of the music selection Pochara character 521 turning a disk on a turn table is displayed on the display block of the personal computer 22.

In step S649, the CPU 221 determines whether the reproduction of music has been completed and waits until it has been completed. On the other hand, if the reproduction of music is found completed in step S649, then the procedure goes to step S650, in which the CPU 221 determines whether the end of the reproduction of music content, namely the end of the music selection by the music selection Pochara has been directed by the user. If the end of the reproduction is found not directed, then the procedure returns to step S641 to repeat the above-mentioned processing therefrom.

Therefore, the above-mentioned processing is repeated to select optimum music content by the music selection Pochara and the selected music content is reproduced.

On the other hand, if the end of the reproduction is found directed in step S650, then the procedure goes to step S651, in which the CPU 221 executes the charging processing on the fee of the reproduced music content. For example, as described above, the fee of the reproduced music content is calculated by the processing with the Pochara service server 9 and the money amount information stored in the IC chip 171 of the friend Pochara figure 161 mounted on the platform 23 is reduced by the amount of calculated fee. Namely, the money amount information stored in the IC chip 171 is rewritten by the Pochara service server 9 and the fee of the music content is collected as that of the manager of the Pochara service server 9. The collected fee is distributed between the manager of the Pochara service server 9 and the provider of the music selection Pochara in accordance with the agreements between both.

When the charging processing has been completed, the CPU 221 displays the image of the music selection Pochara character 521 returning to the Pochara service server 9 onto the screen of the personal computer 22 in step S652.

FIG. 64 shows an exemplary display of the music selection Pochara character 521 returning to the Pochara service server 9 from the personal computer 22.

For example, an image in which an exit 541 appears over the music selection Pochara character 521 as shown in FIG. 64 and the music selection Pochara character 521 is absorbed into the exit is displayed. In addition, message “Call me again” for example is displayed in a balloon 542 of the music selection Pochara character 521.

Consequently, the calling of the music selection Pochara comes to an end. After the music selection Pochara character 521 has disappeared (or after the use of the music selection Pochara has ended), the friend Pochara character 311 appears on the screen again.

In step S653, the CPU 221 displays a screen for evaluating the music selection made by the music selection Pochara onto the display block.

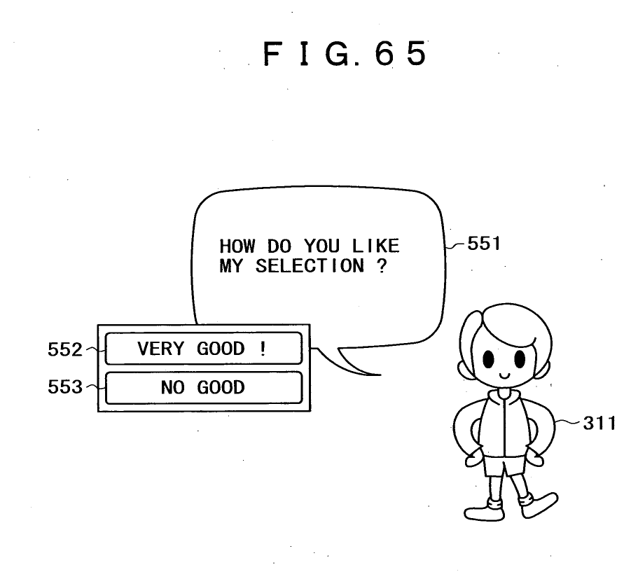

FIG. 65 shows an exemplary display of the screen for making the user evaluate the selection of music by the music selection Pochara.

For example, as shown in FIG. 65, the friend Pochara character 311 is displayed again in place of the music selection Pochara character 521 and message “How do you like my selection” is displayed in a balloon 551 of the friend Pochara character 311. In addition, a button 552 (“Very good!”) which is pressed when the user liked the selection by the music selection Pochara and a button 553 (“No good”) which is pressed when the user did not like the selection are displayed.

On the screen shown in FIG. 65, an evaluation on the music selection Pochara entered by operating the button 552 or 553 is transmitted to the Pochara service server 9 in step S654. As will be described later, in the Pochara service server 9, the feature of the music selection Pochara is updated on the basis of the user's evaluation.

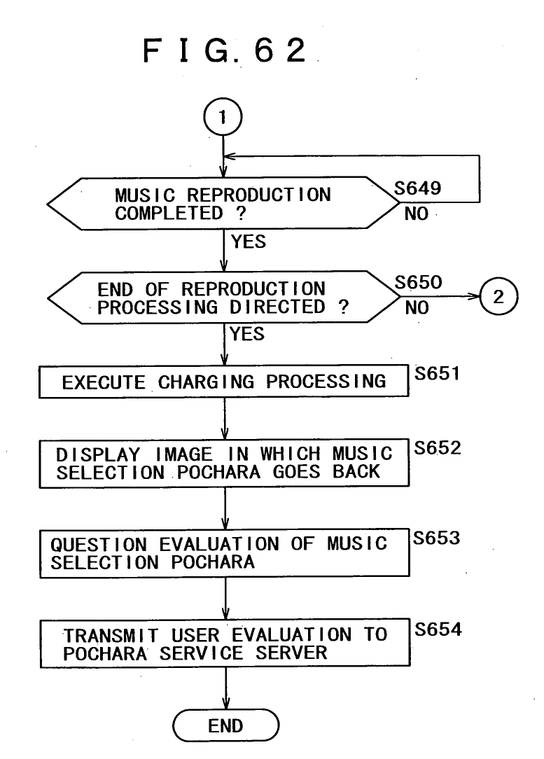

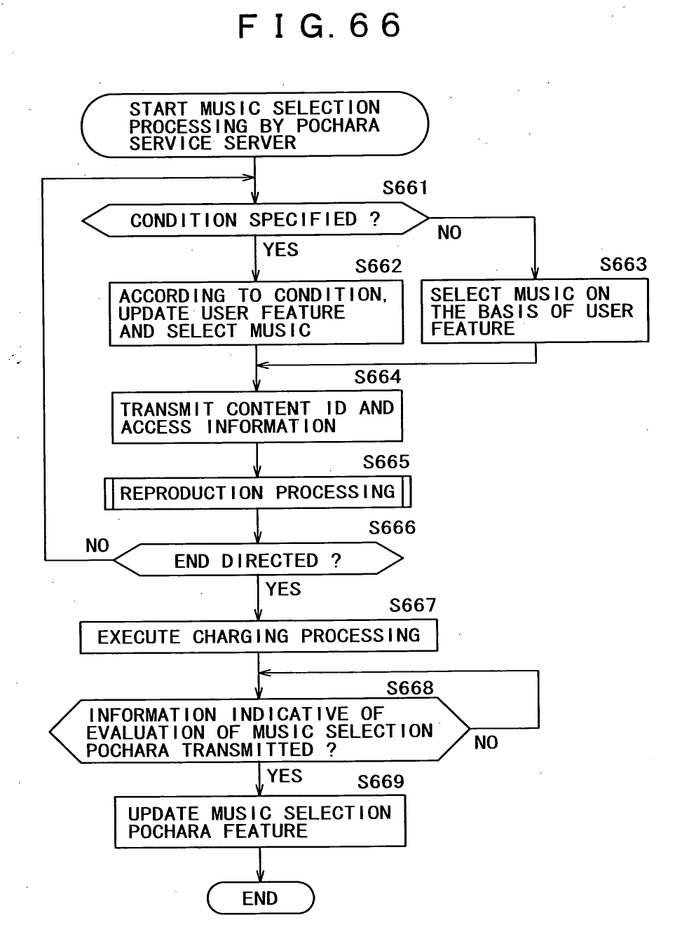

The following describes the music selection processing which is executed by the Pochara service server 9 in response to the processing shown in FIGS. 61 and 62, with reference to the flowchart shown in FIG. 66.

In step S661, the CPU 121 of the Pochara service server 9 determines whether the information for specifying music conditions has been transmitted from the personal computer 22. As described above, in the personal computer 22 to which the music selection Pochara has been called, the selection screen (FIG. 63) for selecting music conditions is displayed and, when a music condition is selected, the information for specifying the selected condition is transmitted from the personal computer 22 (step S643 shown in FIG. 61).

If the information for specifying a music condition is found transmitted from the personal computer 22 in step S661, then the procedure goes to step S662, in which the CPU 121 updates the feature information of the user in accordance with the specified condition, thereby selecting music (or music content).

As with the matching between the user feature and the music selection Pochara feature for example, the CPU 121 moves the position of the user feature in accordance with the received music condition and selects the music of which feature is set to the proximity of the position to which the user feature has been moved. Therefore, in this case, the features of the music (or the music content) at which the music selection Pochara introduced to the personal computer 22 is good are set to the coordinates positions shown in FIGS. 54 and 60.

On the other hand, if the information for specifying a music condition is found not transmitted (or no condition has been selected) in step S661, then the procedure goes to step S663, in which the CPU 121 executes music selection on the basis of the user feature. In this case, the CPU 121 determines the position of the user feature on the coordinates shown in FIGS. 54 and 60 on the basis of the log of the user who used friend Pochara or sale Pochara, thereby selecting the music of which feature is set to the proximity of the determined position.

If the music is selected in step S662 or if the music is selected in step S663, then the procedure goes to step S664, in which the CPU 121 transmits, to the personal computer 22, the content ID of the selected music and the access information including the address of the content server which provides that music content. Also, it is practicable that the Pochara service server 9 notifies the content server which provides the music content of the content ID of the selected music content and the address of the personal computer 22 and, in response to this notification, the content server transmits the music content to the personal computer 22.

In step S665, the CPU 121 executes the processing corresponding to the music content reproduction processing which is executed in the personal computer 22. Namely, the CPU 121 executes the processing shown in FIG. 38 to provide the license corresponding to the music content to the personal computer 22 and executes the processing shown in FIG. 41 to reproduce the music content on the personal computer 22.

In step S666, the CPU 121 determines whether the end of the reproduction of the music content has been directed. If the end of the reproduction is found not directed, the procedure returns to step S661 to repeat the above-mentioned processing therefrom.

On the other hand, if the end of the reproduction of the music content is found directed in step S666, then the procedure goes to step S667, in which the CPU 121 executes charging processing. Namely, the CPU 121 reduces the money amount information stored in the IC chip 171 of the friend Pochara figure 161 mounted on the platform 23 of the personal computer 22 by an amount equivalent to the fee of the music content reproduced by the personal computer 22 and gets the resultant money amount information.

In step S668, the CPU 121 determines whether the information indicative of the evaluation of the music selection Pochara has been transmitted from the personal computer 22 and waits until it is transmitted. Namely, in the personal computer 22, after the music selection Pochara character 521 disappeared from the screen, the evaluation of that music selection Pochara is entered by the user and transmitted (step S654 shown in FIG. 62).

If the information indicative of the evaluation of the music selection Pochara is found transmitted in step S668, the procedure goes to step S669, in which the CPU 121 updates the feature of the music selection Pochara in accordance with the result of the evaluation made by the user and the feature of the user.

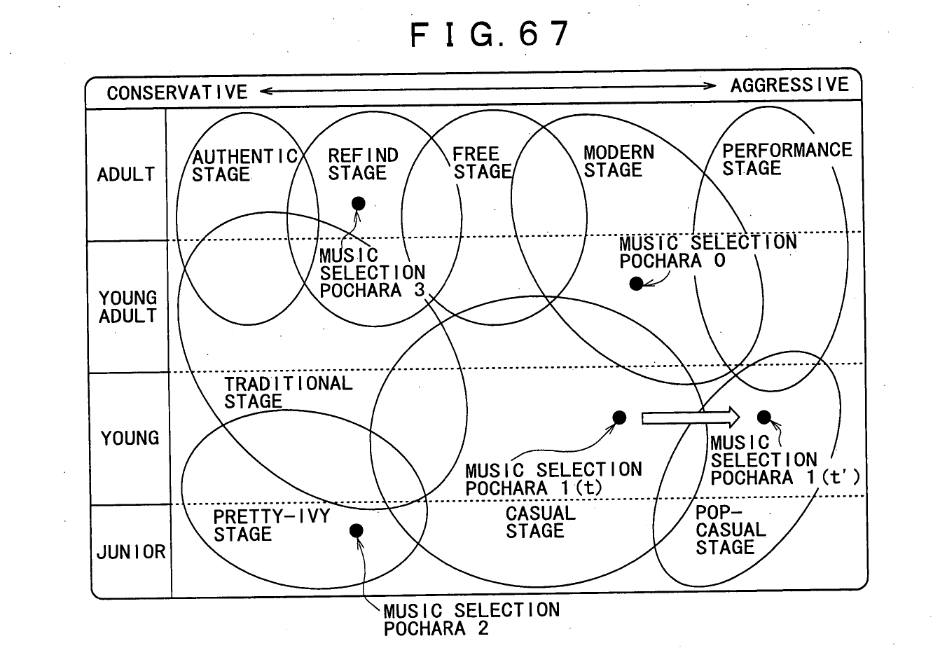

FIG. 67 shows an example of the updating of the music selection Pochara feature.

In the example shown in FIG. 67, the position of the feature of the music selection Pochara 1 (the music selection Pochara introduced to the user of the personal computer 22) indicated by “music selection Pochara 1 (t)” has been moved to the position of “music selection Pochara 1 (t′)” indicated by the white arrow. Namely, depending on the parameter set by the provider of the music selection Pochara 1, the position of the feature of the music selection Pochara 1 is set to “music selection Pochara 1 (t)”; however, in accordance with the evaluation of the user of the personal computer 22 who used the music selection made by the music selection Pochara 1, the feature position is updated to a music selection Pochara for more “aggressive” users.

Thus, by updating the music selection Pochara feature according to the evaluation by the user, the music selection Pochara feature is updated in response to the latest trends, thereby always providing an optimum matching between user and music selection Pochara. Therefore, the optimum music selection Pochara can be dynamically selected with user preference and feeling considered.

The above-mentioned processing allows the user to call the music selection Pochara optimum for his preference and feeling at that moment only by making a response to some questions asked by the friend Pochara, thereby using the optimum music content selected by the music selection Pochara.

In the above-mentioned configuration, the user can call a music selection Pochara by executing predetermined processing on the menu screen shown in FIG. 20. The present invention is not restricted to this configuration. For example, the user can buy, at a real store, a music selection Pochara figure (or a sale Pochara figure) having the same external shape as the music selection Pochara character 521 and mount the purchased figure on the platform 23, thereby calling the music selection Pochara onto the screen of the personal computer 22.

In this case, the Pochara ID of the music selection Pochara (or the sale Pochara) is read from the IC card of the music selection Pochara figure through the reader/writer 241 to be transmitted to the Pochara service server 9. In the Pochara service server 9, the Pochara information (the information including the image data for displaying, on the personal computer 22, the image of the character corresponding to the external shape of the music selection Pochara figure) corresponding to the received Pochara ID is read from the Pochara database 10 to be transmitted to the personal computer 22. Then, as with the friend Pochara and other sale Pocharas, the music selection Pochara character is displayed on the display block of the personal computer 22 on the basis of the Pochara information received from the Pochara service server 9.

In the above-mentioned configuration, optimum music content is selected by a music selection Pochara and the selected music content is provided to the user. The present invention is not restricted to this configuration. For example, various other kinds of content such as moving picture content, applications, and service content for using services may be selected by Pocharas and provided to the user.

For example, if a Pochara for selecting optimum movies is called by the personal computer 22 for example, optimum movie content is selected in accordance with the replies to questions to the user and the selected content is provided to the user of the personal computer 22.

The above-mentioned sequence of processing operations may be executed by software as well as hardware. When the above-mentioned sequence of processing operations is executed by software, the programs constituting the software are installed in a computer which is built in dedicated hardware equipment or installed, from a network or recording media, into a general-purpose personal computer for example in which various programs may be installed for the execution of various functions.

As shown in FIGS. 2 or 3, these recording media are constituted by not only a package media made up of the magnetic disk 141 or 251 (including flexible disks), the optical disk 142 or 252 (including CD-ROM (Compact Disk Read Only Memory) and DVD (Digital Versatile Disk)), the magneto-optical disk 143 or 253 (including MD (trademark) (Mini Disk)), or the semiconductor memory 144 or 254 which is distributed separately from the apparatus itself, but also the ROM 122 or 222 or the storage unit 128 or 228 which stores programs and is provided to users as incorporated in the apparatus itself.

It should be noted herein that the steps for describing each program recorded in recording media include not only the processing operations which are sequentially executed in a time-dependent manner but also the processing operations which are executed concurrently or discretely.

It should also be noted that term “system” as used herein denotes an entire apparatus configured by a plurality of component units.

According to an embodiment of the invention, content can be provided.

Further, according to the invention, optimum content corresponding to user's preference and feeling at that time can be provided to each individual user.

It should be understood that various changes and modifications to the presently preferred embodiments described herein will be apparent to those skilled in the art. Such changes and modifications can be made without departing from the spirit and scope of the present invention and without diminishing its intended advantages. It is therefore intended that such changes and modifications be covered by the appended claims.

1-18. (canceled)

19. An information management device for managing content provision to an information processing device connected to said information management device via a network, comprising:
storage means for storing image data for displaying an image of a character and character feature information indicative of said character;
character selection means for selecting said character from among characters of which image data is stored in said storage means based on user feature information indicative of a user of said information processing device and said character feature information;
image data transmission means for transmitting, to said information processing device, said image data of said character selected by said character selection means; and
content transmission means for transmitting content associated with said character selected by said character selection means to said information processing device.

20. The information management device according to claim 19, further comprising:
content selection means for selecting said content associated with said character selected by said character selection means on the basis of said user feature information.

21. The information management device according to claim 19, further comprising:
evaluation information acquisition means for acquiring evaluation information indicative of an evaluation of said content used on said information processing device;
wherein said character selection means updates said user feature information in accordance with said evaluation information acquired by said evaluation information acquisition means, thereby selecting said character on the basis of said updated user feature information and said character feature information.

22. The information management device according to claim 19, further comprising:
charging means for charging, to said information processing device, a fee of said content transmitted by said content transmission means.

23. The information management device according to claim 19, further comprising:
identification information reception means for receiving, from said information processing device, identification information held in an object read by said information processing device;
wherein said character selection means selects a character which is represented by an image in accordance with an external shape of said object on the basis of said identification information received by said identification information reception means.

24. The information management device according to claim 19, further comprising:
transmission management means for managing the transmission of said content to said information processing device by transmitting information about access to another information processing device to which said content is provided and identification information of said content to said information processing device.

25. The information management device according to claim 19, further comprising:
user feature information extraction means for extracting said user feature information based on an input by said user of said information processing device, said input being transmitted from said information processing device.

26. The information management device according to claim 19, further comprising:
input information acquisition means for acquiring input information of said user including said user feature information indicative of a feature of a user for selecting said character or said content.

27. An information managing method for an information management device for managing content provision to an information processing device connected to said information management device via a network, comprising:
storing image data for displaying an image of a character and character feature information indicative of said character;
selecting said character from among characters of which image data is stored in said storage step base don user feature information indicative of a user of said information processing device and said character feature information;
transmitting, to said information processing device, said image data of said character selected by said character selection step; and
transmitting content associated with said character selected by said character selection step to said information processing device.

28. A recording medium recording a computer-readable program for an information management device for managing content provision to an information processing device connected to said information management device via a network, said computer-readable program comprising:
controlling storage of image data for displaying an image of a character and character feature information indicative of said character;
selecting said character from among characters of which image data is stored in said storage control step on the basis of user feature information indicative of a user of said information processing device and said character feature information;
controlling transmission of, to said information processing device, said image data of said character selected by said character selection step; and
controlling transmission of content associated with said character selected by said character selection step to said information processing device.

29. A program for making a computer for controlling an information management device for managing content provision to an information processing device connected to said information management device via a network execute the steps of:
controlling storage of image data for displaying an image of a character and character feature information indicative of said character;
selecting said character from among characters of which image data is stored in said storage control step on the basis of user feature information indicative of a user of said information processing device and said character feature information;
controlling transmission of, to said information processing device, said image data of said character selected by said character selection step; and
controlling transmission of content associated with said character selected by said character selection step to said information processing device.

30. An information processing device connected, via a network, to an information management device for managing content provision, comprising:
image data reception means for receiving image data of a predetermined character transmitted from said information management device;
display means for displaying said predetermined character based on said image data received by said image data reception means;
content acquisition means for acquiring content associated with said predetermined character displayed by said display means; and
output means for outputting said content acquired by said content acquisition means.

31. The information processing device according to claim 30, farther comprising:
evaluation information transmission means for accepting input of an evaluation associated with said content outputted by said output means and transmitting evaluation information indicative of said evaluation to said information management device.

32. The information processing device according to claim 30, further comprising:
read means for reading identification information from an object in which said identification information is held; and
identification information transmission means for transmitting said identification information read by said read means to said information management device;
wherein said image data reception means receives image data for displaying an image corresponding to an external shape of said object selected by said information management device on the basis of said identification information.

33. The information processing device according to claim 30, wherein, based on information about access to another information processing device to which said content is provided and identification information of said content, said information being transmitted from said information management device, said content acquisition means acquires said content from said another information processing device.

34. An information processing method for an information processing device connected, via a network, to an information management device for managing content provision, comprising:
receiving image data of a predetermined character transmitted from said information management device;
displaying said predetermined character based on said image data received by said image data reception step;
acquiring content associated with said predetermined character displayed by said display step; and
outputting said content acquired by said content acquisition step.

35. A recording medium recording a computer-readable program for an information processing device connected, via a network, to an information management device for managing content provision, said computer-readable program comprising:
controlling reception of image data of a predetermined character transmitted from said information management device;
controlling display of said predetermined character on the basis of said image data received by said image data reception control step;
controlling acquisition of content associated with said predetermined character displayed by said display control step; and
controlling output of said content acquired by said content acquisition control step.

36. A program for making a computer for controlling an information processing device connected, via a network, to an information management device for managing content provision execute the steps of:
controlling reception of image data of a predetermined character transmitted from said information management device;
controlling display of said predetermined character on the basis of said image data received by said image data reception control step;
controlling acquisition of content associated with said predetermined character displayed by said display control step; and
controlling output of said content acquired by said content acquisition control step.
